(19) United States
(12) Patent Application Publication
(10) Pub. No.: US 2018/0356501 A1
(43) Pub. Date: Dec. 13, 2018

(54) DETECTOR FOR OPTICALLY DETECTING AT LEAST ONE OBJECT

(71) Applicant: trinamiX GmbH, Ludwigshafen am Rhein (DE)

(72) Inventors: Robert SEND, Ludwigshafen (DE); Ingmar BRUDER, Ludwigshafen (DE); Sebastian VALOUCH, Ludwigshafen (DE)

(73) Assignee: trinamiX GmbH, Ludwigshafen am Rhein (DE)

(21) Appl. No.: 15/778,454

(22) PCT Filed: Dec. 2, 2016
(86) PCT No.: PCT/EP2016/079529

§ 371 Date: May 23, 2018

(30) Foreign Application Priority Data
Dec. 3, 2015 (EP) 15197744.4

(51) Int. Cl. G01S 7/481; G01S 11/12; G01S 17/66

(52) U.S. Cl. CPC G01S 7/4816; H01L 27/14643; G01S 17/66; G01S 11/12

(57) ABSTRACT

A detector for an optical detection of at least one object is disclosed. The detector contains at least one longitudinal optical sensor and at least one evaluation device. The longitudinal optical sensor has at least one sensor region and is designed to generate at least one longitudinal sensor signal in a manner dependent on an illumination of the sensor region by a light beam. The longitudinal sensor signal, given the same total power of the illumination, is dependent on a beam cross-section of the light beam in the sensor region and further dependent on at least one adjustable property of the longitudinal optical sensor. The evaluation device is designed to generate at least one item of information on a longitudinal position of the object by evaluating the longitudinal sensor signal of the longitudinal optical sensor.

### FIELD OF THE INVENTION

The invention relates to a detector, a detector system and a method for determining a position of at least one object. The invention further relates to a human-machine interface for exchanging at least one item of information between a user and a machine, an entertainment device, a tracking system, a camera, a scanning system and various uses of the detector device. The devices, systems, methods and uses according to the present invention specifically may be employed for example in various areas of daily life, gaming, traffic technology, production technology, security technology, photography such as digital photography or video photography for arts, documentation or technical purposes, medical technology or in the sciences. However, other applications are also possible.

### PRIOR ART

A large number of optical sensors and photovoltaic devices are known from the prior art. While photovoltaic devices are generally used to convert electromagnetic radiation, for example, ultraviolet, visible or infrared light, into electrical signals or electrical energy, optical detectors are generally used for picking up image information and/or for detecting at least one optical parameter, for example, a brightness.

A large number of optical sensors which can be based generally on the use of inorganic and/or organic sensor materials are known from the prior art. Examples of such sensors are disclosed in US 2007/0176165 A1, U.S. Pat. No. 6,995,445 B2, DE 2501124 A1, DE 3225372 A1 or else in numerous other prior art documents. To an increasing extent, in particular for cost reasons and for reasons of large-area processing, sensors comprising at least one organic sensor material are being used, as described for example in US 2007/0176165 A1. In particular, so-called dye solar cells are increasingly of importance here, which are described generally, for example in WO 2009/013282 A1. The present invention, however, is not restricted to the use of organic devices. Thus, specifically, also inorganic devices such as CCD sensors and/or CMOS sensors, specifically pixelated sensors, may be employed.

A large number of detectors for detecting at least one object are known on the basis of such optical sensors. Such detectors can be embodied in diverse ways, depending on the respective purpose of use. Examples of such detectors are imaging devices, for example, cameras and/or microscopes. High-resolution confocal microscopes are known, for example, which can be used in particular in the field of medical technology and biology in order to examine biological samples with high optical resolution. Further examples of detectors for optically detecting at least one object are distance measuring devices based, for example, on propagation time methods of corresponding optical signals, for example laser pulses. Further examples of detectors for optically detecting objects are triangulation systems, by means of which distance measurements can likewise be carried out.

In WO 2012/110924 A1, the content of which is herewith included by reference, a detector for optically detecting at least one object is proposed. The detector comprises at least one optical sensor. The optical sensor has at least one sensor region. The optical sensor is designed to generate at least one sensor signal in a manner dependent on an illumination of the sensor region. The sensor signal, given the same total power of the illumination, is dependent on a geometry of the illumination, in particular on a beam cross section of the illumination on the sensor area. The detector furthermore has at least one evaluation device. The evaluation device is designed to generate at least one item of geometrical information from the sensor signal, in particular at least one item of geometrical information about the illumination and/or the object.

WO 2014/097181 A1, the full content of which is herewith included by reference, discloses a method and a detector for determining a position of at least one object, by using at least one transversal optical sensor and at least one optical sensor. Specifically, the use of sensor stacks is disclosed, in order to determine a longitudinal position of the object with a high degree of accuracy and without ambiguity.

WO 2015/024871 A1, the full content of which is herewith included by reference, discloses an optical detector, comprising:
at least one spatial light modulator being adapted to modify at least one property of a light beam in a spatially resolved fashion, having a matrix of pixels, each pixel being controllable to individually modify the at least one optical property of a portion of the light beam passing the pixel;
at least one optical sensor adapted to detect the light beam after passing the matrix of pixels of the spatial light modulator and to generate at least one sensor signal;
at least one modulator device adapted for periodically controlling at least two of the pixels with different modulation frequencies; and
at least one evaluation device adapted for performing a frequency analysis in order to determine signal components of the sensor signal for the modulation frequencies.

WO 2014/198629 A1, the full content of which is herewith included by reference, discloses a detector for determining a position of at least one object, comprising:
at least one optical sensor, the optical sensor being adapted to detect a light beam propagating from the object towards the detector, the optical sensor having at least one matrix of pixels; and
at least one evaluation device, the evaluation device being adapted to determine a number N of pixels of the optical sensor which are illuminated by the light beam, the evaluation device further being adapted to determine at least one longitudinal coordinate of the object by using the number N of pixels which are illuminated by the light beam.

Further, generally, for various other detector concepts, reference may be made to WO 2014/198626 A1, WO 2014/198629 A1 and WO 2014/198625 A1, the full content of which is herewith included by reference. Further, referring to potential materials and optical sensors which may also be employed in the context of the present invention, reference may be made to European patent applications No. EP 15 153 215.7, filed on Jan. 30, 2015, EP 15 157 363.1, filed on Mar. 3, 2015, EP 15 164 653.6, filed on Apr. 22, 2015, EP 15177275.3, filed on Jul. 17, 2015, EP 15180354.1 and EP 15180353.3, both filed on Aug. 10, 2015, and EP 15 185 005.4, filed on Sep. 14, 2015, the full content of all of which is herewith also included by reference.

Despite the advantages implied by the above-mentioned devices and detectors, several technical challenges remain. Thus, generally, a need exists for detectors for detecting a position of an object in space which is both reliable and may be manufactured at low cost. Specifically, a need exists for 3D-sensing concepts. Various known concepts are at least partially based on using so-called FiP sensors, such as several of the above-mentioned concepts. 3D-sensing concepts using FiP-sensors typically rely on using one detector comprising at least one FiP-sensor and another non-FiP-detector. For example, the FiP-detector and the non-FiP-detector may be arranged stacked behind each other. Alternatively, the FiP-detector and the non-FiP-detector may be arranged such that light of a light beam splitted, e.g. by a beam splitter, impinges both the FiP-detector and the non-FiP-detector. Thus, transparent detectors or an expensive beam splitter are necessary.

This discussion of known concepts, such as the concepts of several of the above-mentioned prior art documents, clearly shows that some technical challenges remain. Despite the advantages implied by the above-mentioned devices and detectors, specifically by the detector disclosed in WO 2012/110924 A1, there still is a need for improvements with respect to a simple, cost-efficient and, still, reliable spatial detector.

### Problem Addressed by the Invention

It is therefore an object of the present invention to provide devices and methods facing the above-mentioned technical challenges of known devices and methods. Specifically, it is an object of the present invention to provide devices and methods which reliably may determine a position of an object in space, preferably with a low technical effort and with low requirements in terms of technical resources and cost.

### SUMMARY OF THE INVENTION

This problem is solved by the invention with the features of the independent patent claims. Advantageous developments of the invention, which can be realized individually or in combination, are presented in the dependent claims and/or in the following specification and detailed embodiments.

As used in the following, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, it shall be noted that the terms “at least one”, “one or more” or similar expressions indicating that a feature or element may be present once or more than once typically will be used only once when introducing the respective feature or element. In the following, in most cases, when referring to the respective feature or element, the expressions “at least one” or “one or more” will not be repeated, non-withstanding the fact that the respective feature or element may be present once or more than once.

Further, as used in the following, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restrictions regarding the scope of the invention and without any restriction regarding the possibility of combining the features introduced in such a way with other optional or non-optional features of the invention.

In a first aspect of the present invention, a detector for an optical detection of at least one object, in particular for determining a position of at least one object, specifically with regard to a depth or to both the depth and a width of the at least one object, is disclosed.

The “object” generally may be an arbitrary object, chosen from a living object and a non-living object. Thus, as an example, the at least one object may comprise one or more articles and/or one or more parts of an article. Additionally or alternatively, the object may be or may comprise one or more living beings and/or one or more parts thereof, such as one or more body parts of a human being, e.g. a user, and/or an animal.

As used herein, the term “position” refers to at least one item of information regarding a location and/or orientation of the object and/or at least one part of the object in space. Thus, the at least one item of information may imply at least one distance between at least one point of the object and the at least one detector. As will be outlined in further detail below, the distance may be a longitudinal coordinate or may contribute to determining a longitudinal coordinate of the point of the object. Additionally or alternatively, one or more other items of information regarding the location and/or orientation of the object and/or at least one part of the object may be determined. As an example, at least one transversal coordinate of the object and/or at least one part of the object may be determined. Thus, the position of the object may imply at least one longitudinal coordinate of the object and/or at least one part of the object. Additionally or alternatively, the position of the object may imply at least one transversal coordinate of the object and/or at least one part of the object. Additionally or alternatively, the position of the object may imply at least one orientation information of the object, indicating an orientation of the object in space.

For this purpose, as an example, one or more coordinate systems may be used, and the position of the object may be determined by using one, two, three or more coordinates. As an example, one or more Cartesian coordinate systems and/or other types of coordinate systems may be used. In one example, the coordinate system may be a coordinate system of the detector in which the detector has a predetermined position and/or orientation. As will be outlined in further detail below, the detector may have an optical axis, which may constitute a main direction of view of the detector. The optical axis may form an axis of the coordinate system, such as a z-axis. Further, one or more additional axes may be provided, preferably perpendicular to the z-axis.

Thus, as an example, the detector may constitute a coordinate system in which the optical axis forms the z-axis and in which, additionally, an x-axis and a y-axis may be provided which are perpendicular to the z-axis and which are perpendicular to each other. As an example, the detector and/or a part of the detector may rest at a specific point in this coordinate system, such as at the origin of this coordinate system. In this coordinate system, a direction parallel or antiparallel to the z-axis may be regarded as a longitudinal direction, and a coordinate along the z-axis may be considered a longitudinal coordinate. An arbitrary direction perpendicular to the longitudinal direction may be considered a transversal direction, and an x- and/or y-coordinate may be considered a transversal coordinate.

Alternatively, other types of coordinate systems may be used. Thus, as an example, a polar coordinate system may be used in which the optical axis forms a z-axis and in which a distance from the z-axis and a polar angle may be used as additional coordinates. Again, a direction parallel or antiparallel to the z-axis may be considered a longitudinal direction, and a coordinate along the z-axis may be considered a longitudinal coordinate. Any direction perpendicular to the z-axis may be considered a transversal direction, and the polar coordinate and/or the polar angle may be considered a transversal coordinate.

As used herein, the detector for optical detection generally is a device which is adapted for providing at least one item of information on the position of the at least one object. The detector may be a stationary device or a mobile device. Further, the detector may be a stand-alone device or may form part of another device, such as a computer, a vehicle or any other device. Further, the detector may be a hand-held device. Other embodiments of the detector are feasible.

The detector may be adapted to provide the at least one item of information on the position of the at least one object in any feasible way. Thus, the information may e.g. be provided electronically, visually, acoustically or in any arbitrary combination thereof. The information may further be stored in a data storage of the detector or a separate device and/or may be provided via at least one interface, such as a wireless interface and/or a wire-bound interface.

The detector for an optical detection of at least one object according to the present invention comprises:
at least one longitudinal optical sensor, wherein the longitudinal optical sensor has at least one sensor region, wherein the longitudinal optical sensor is designed to generate at least one longitudinal sensor signal in a manner dependent on an illumination of the sensor region by a light beam, wherein the longitudinal sensor signal, given the same total power of the illumination, is dependent on a beam cross-section of the light beam in the sensor region,
wherein the longitudinal sensor signal is further dependent on at least one property of the longitudinal optical sensor, wherein the property of the longitudinal optical sensor is adjustable; and
at least one evaluation device, wherein the evaluation device is designed to generate at least one item of information on a longitudinal position of the object by evaluating the longitudinal sensor signal of the longitudinal optical sensor.

Herein, the components listed above may be separate components. Alternatively, two or more of the components as listed above may be integrated into one component. Further, the at least one evaluation device may be formed as a separate evaluation device independent from the transfer device and the longitudinal optical sensors, but may preferably be connected to the longitudinal optical sensors in order to receive the longitudinal sensor signal. Alternatively, the at least one evaluation device may fully or partially be integrated into the longitudinal optical sensors.

As used herein, an optical sensor generally refers to a light-sensitive device for detecting a light beam, such as for detecting an illumination and/or a light spot generated by a light beam. The optical sensor may be adapted, as outlined in further detail below, to determine at least one longitudinal coordinate of the object and/or of at least one part of the object, such as at least one part of the object from which the at least one light beam travels towards the detector.

As used herein, the “longitudinal optical sensor” is generally a device which is designed to generate at least one longitudinal sensor signal in a manner dependent on an illumination of the sensor region by the light beam, wherein the longitudinal sensor signal, given the same total power of the illumination, is dependent, according to the so-called “FiP effect” on a beam cross-section of the light beam in the sensor region. As used herein, the term “sensor signal” generally refers to an arbitrary memorable and transferable signal which is generated by longitudinal optical sensor, in response to the illumination. The longitudinal sensor signal may generally be an arbitrary signal indicative of the longitudinal position, which may also be denoted as a depth. As an example, the longitudinal sensor signal may be or may comprise a digital and/or an analog signal. As an example, the longitudinal sensor signal may be or may comprise a voltage signal and/or a current signal. Additionally or alternatively, the longitudinal sensor signal may be or may comprise digital data. As an example, the sensor signal may be or may comprise at least one electronic signal, which may be or may comprise a digital electronic signal and/or an analogue electronic signal. The longitudinal sensor signal may comprise a single signal value and/or a series of signal values. The longitudinal sensor signal may further comprise an arbitrary signal which is derived by combining two or more individual signals, such as by averaging two or more signals and/or by forming a quotient of two or more signals. For potential embodiments of the longitudinal optical sensor and the longitudinal sensor signal, reference may be made to the optical sensor as disclosed in WO 2012/110924 A1. Further, either raw sensor signals may be used, or the detector, the optical sensor or any other element may be adapted to process or preprocess the sensor signal, thereby generating secondary sensor signals, which may also be used as sensor signals, such as preprocessing by filtering or the like.

As used herein, the term “light” generally refers to electromagnetic radiation in one or more of the visible spectral range, the ultraviolet spectral range and the infrared spectral range. Therein, in partial accordance with ISO standard ISO-21348, the term visible spectral range generally refers to a spectral range of 380 nm to 760 nm. The term infrared (IR) spectral range generally refers to electromagnetic radiation in the range of 760 nm to 1000 μm, wherein the range of 760 nm to 1.4 μm is usually denominated as the near infrared (NIR) spectral range, and the range from 15 μm to 1000 μm as the far infrared (FIR) spectral range. The term ultraviolet spectral range generally refers to electromagnetic radiation in the range of 1 nm to 380 nm, preferably in the range of 100 nm to 380 nm. Preferably, light as used within the present invention is visible light, i.e. light in the visible spectral range.

The term “light beam” generally refers to an amount of light emitted into a specific direction, specifically an amount of light traveling essentially in the same direction, including the possibility of the light beam having a spreading angle or widening angle. Thus, the light beam may be a bundle of the light rays having a predetermined extension in a direction perpendicular to a direction of propagation of the light beam. Preferably, the light beam may be or may comprise one or more Gaussian light beams which may be characterized by one or more Gaussian beam parameters, such as one or more of a beam waist, a Rayleigh-length or any other beam parameter or combination of beam parameters suited to characterize a development of a beam diameter and/or a beam propagation in space. The light beam propagates from the object towards the detector.

The light beam might be admitted by the object itself, i.e. might originate from the object. Additionally or alternatively, another origin of the light beam is feasible. Thus, as will be outlined in further detail below, one or more illumination sources might be provided which illuminate the object, such as by using one or more primary rays or beams, such as one or more primary rays or beams having a predetermined characteristic. In the latter case, the light beam propagating from the object to the detector might be a light beam which is reflected by the object and/or a reflection device connected to the object.

The at least one longitudinal sensor signal, given the same total power of the illumination by the light beam, is, according to the FiP effect, dependent on a beam cross-section of the light beam in the sensor region of the at least one longitudinal optical sensor.

As used herein, the term “sensor region” generally refers to a two-dimensional or three-dimensional region which preferably, but not necessarily, is continuous and can form a continuous region, wherein the sensor region is designed to vary at least one measurable property, in a manner dependent on the illumination. By way of example, said at least one property can comprise an electrical property, for example, by the sensor region being designed to generate, solely or in interaction with other elements of the optical sensor, a photovoltage and/or a photocurrent and/or some other type of signal. In particular the sensor region can be embodied in such a way that it generates a uniform, preferably a single, signal in a manner dependent on the illumination of the sensor region. The sensor region can thus be the smallest unit of the longitudinal optical sensor for which a uniform signal, for example, an electrical signal, is generated, which preferably can no longer be subdivided to partial signals, for example for partial regions of the sensor region. The longitudinal optical sensor can have one or else a plurality of such sensor regions, the latter case for example by a plurality of such sensor regions being arranged in a two-dimensional and/or three-dimensional matrix arrangement.

The detector according to the present invention as well as the other devices and the method proposed in the context of the present invention, specifically, may be considered as implementing a similar idea as the so-called “FiP” effect which is explained in further detail in WO 2012/110924 A1 and/or in WO 2014/097181 A1. Therein, “FiP” alludes to the effect that a signal i may be generated which, given the same total power P of the illumination, depends on the photon density, the photon flux and, thus, on the cross-section (F) of the incident beam.

As used herein, the term “beam cross-section” generally refers to a lateral extension of the light beam or a light spot generated by the light beam at a specific location. As further used herein, a light spot generally refers to a visible or detectable round or non-round illumination at a specific location by a light beam. In the light spot, the light may fully or partially be scattered or may simply be transmitted. In case a circular light spot is generated, a radius, a diameter or a Gaussian beam waist or twice the Gaussian beam waist may function as a measure of the beam cross-section. In case non-circular light-spots are generated, the cross-section may be determined in any other feasible way, such as by determining the cross-section of a circle having the same area as the non-circular light spot, which is also referred to as the equivalent beam cross-section. Within this regard, it may be possible to employ the observation of an extremum, i.e. a maximum or a minimum, of the longitudinal sensor signal, in particular a global extremum, under a condition in which the sensor region may be impinged by a light beam with the smallest possible cross-section, such as when the sensor region may be located at or near a focal point as affected by an optical lens. In case the extremum is a maximum, this observation may be denominated as the positive FiP-effect, while in case the extremum is a minimum, this observation may be denominated as the negative FiP-effect.

Given the same total power of the illumination of the sensor region by the light beam, a light beam having a first beam diameter or beam cross-section may generate a first longitudinal sensor signal, whereas a light beam having a second beam diameter or beam-cross section being different from the first beam diameter or beam cross-section generates a second longitudinal sensor signal being different from the first longitudinal sensor signal. Thus, by comparing the longitudinal sensor signals, at least one item of information on the beam cross-section, specifically on the beam diameter, may be generated. For details of this effect, reference may be made to WO 2012/110924 A1. Accordingly, the longitudinal sensor signals generated by the longitudinal optical sensors may be compared, in order to gain information on the total power and/or intensity of the light beam and/or in order to normalize the longitudinal sensor signals and/or the at least one item of information on the longitudinal position of the object for the total power and/or total intensity of the light beam. Thus, as an example, a maximum value of the longitudinal optical sensor signals may be detected, and all longitudinal sensor signals may be divided by this maximum value, thereby generating normalized longitudinal optical sensor signals, which, then, may be transformed by using the above-mentioned known relationship, into the at least one item of longitudinal information on the object. Other ways of normalization are feasible, such as a normalization using a mean value of the longitudinal sensor signals and dividing all longitudinal sensor signals by the mean value. Other options are possible. Each of these options may be appropriate to render the transformation independent from the total power and/or intensity of the light beam. In addition, information on the total power and/or intensity of the light beam might, thus, be generated.

Specifically in case one or more beam properties of the light beam propagating from the object to the detector are known, the at least one item of information on the longitudinal position of the object may thus be derived from a known relationship between the at least one longitudinal sensor signal and a longitudinal position of the object. The known relationship may be stored in the evaluation device as an algorithm and/or as one or more calibration curves. As an example, specifically for Gaussian beams, a relationship between a beam diameter or beam waist and a position of the object may easily be derived by using the Gaussian relationship between the beam waist and a longitudinal coordinate.

The longitudinal sensor signal is further dependent on at least one property of the longitudinal optical sensor, wherein the property of the longitudinal optical sensor is adjustable. As used herein, the term “property of the longitudinal optical sensor” generally refers to an arbitrary property of the longitudinal sensor which affects a response behavior of the longitudinal optical sensor in response to the illumination. For example, the property may be a material property of the longitudinal optical sensor, specifically of the sensor region. In particular, the property may be an electrical property and/or electrical characteristic of the material of the longitudinal optical sensor, in particular of the sensor region. Thus, the property may be electrical conductivity of the material of the longitudinal optical sensor, in particular of the sensor region. As used herein, the term “adjustable” generally refers to affecting the longitudinal optical sensor for the purpose of at least one of configuring, changing, modifying, varying the property of the longitudinal optical sensor. The property may be intentionally adjustable. Specifically the property of the longitudinal optical sensor may be adjustable by a user and/or by an external influence. The property may be predetermined and/or preset. The property may be adjustable in dependence on a desired application. The detector may comprise at least one switching device configured to exert at least one external influence and/or at least one internal influence. As used herein, the term “switching device” generally refers to an arbitrary device designed to adjust the property of the longitudinal optical sensor. As used herein, the term “internal influence” generally refers to adjusting the property of the longitudinal optical sensor by configuration of the longitudinal optical sensor. As will be outlined in further detail below, the detector may comprise at least one voltage source configured to apply at least one voltage to the longitudinal optical sensor. The switching device may be configured to exert an influence on the voltage source such that the voltage applied to the longitudinal optical sensor is modified. Further as used herein, the term “external influence” generally refers to adjusting the property of the longitudinal optical sensor by configuring an external device. As will be outlined in further detail below, the detector may comprise at least one illumination source configured to emit at least one light beam. The switching device may be configured to exert an influence on the illumination source, for example at least one electronic signal and/or at least one data signal, such that the illumination source is modified. For example, at least one property of the light beam emitted by the illumination source is modified due to the influence of the switching device.

As used herein, the term “evaluation device” generally refers to an arbitrary device designed to generate the items of information, i.e. the at least one item of information on the position of the object. As an example, the evaluation device may be or may comprise one or more integrated circuits, such as one or more application-specific integrated circuits (ASICs), and/or one or more data processing devices, such as one or more computers, preferably one or more microcomputers and/or microcontrollers. Additional components may be comprised, such as one or more preprocessing devices and/or data acquisition devices, such as one or more devices for receiving and/or preprocessing of the sensor signals, such as one or more AD-converters and/or one or more filters. As used herein, the sensor signal may generally refer to one of the longitudinal sensor signal and, if applicable, to a transversal sensor signal. Further, the evaluation device may comprise one or more data storage devices. Further, as outlined above, the evaluation device may comprise one or more interfaces, such as one or more wireless interfaces and/or one or more wire-bound interfaces.

The at least one evaluation device may be adapted to perform at least one computer program, such as at least one computer program performing or supporting the step of generating the items of information. As an example, one or more algorithms may be implemented which, by using the sensor signals as input variables, may perform a predetermined transformation into the position of the object.

The evaluation device may particularly comprise at least one data processing device, in particular an electronic data processing device, which can be designed to generate the items of information by evaluating the sensor signals. Thus, the evaluation device is designed to use the sensor signals as input variables and to generate the items of information on the transversal position and the longitudinal position of the object by processing these input variables. The processing can be done in parallel, subsequently or even in a combined manner. The evaluation device may use an arbitrary process for generating these items of information, such as by calculation and/or using at least one stored and/or known relationship. Besides the sensor signals, one or a plurality of further parameters and/or items of information can influence said relationship, for example at least one item of information about a modulation frequency. The relationship can be determined or determinable empirically, analytically or else semi-empirically. Particularly preferably, the relationship comprises at least one calibration curve, at least one set of calibration curves, at least one function or a combination of the possibilities mentioned. One or a plurality of calibration curves can be stored for example in the form of a set of values and the associated function values thereof, for example in a data storage device and/or a table. Alternatively or additionally, however, the at least one calibration curve can also be stored for example in parameterized form and/or as a functional equation. Separate relationships for processing the sensor signals into the items of information may be used. Alternatively, at least one combined relationship for processing the sensor signals is feasible. Various possibilities are conceivable and can also be combined.

By way of example, the evaluation device can be designed in terms of programming for the purpose of determining the items of information. The evaluation device can comprise in particular at least one computer, for example at least one microcomputer. Furthermore, the evaluation device can comprise one or a plurality of volatile or nonvolatile data memories. As an alternative or in addition to a data processing device, in particular at least one computer, the evaluation device can comprise one or a plurality of further electronic components which are designed for determining the items of information, for example an electronic table and in particular at least one look-up table and/or at least one application-specific integrated circuit (ASIC).

The detector has, as described above, at least one evaluation device. In particular, the at least one evaluation device can also be designed to completely or partly control or drive the detector, for example by the evaluation device being designed to control at least one illumination source and/or to control at least one modulation device of the detector. The evaluation device can be designed, in particular, to carry out at least one measurement cycle in which one or a plurality of sensor signals, such as a plurality of sensor signals, are picked up, for example a plurality of sensor signals of successively at different modulation frequencies of the illumination.

The evaluation device is designed, as described above, to generate at least one item of information on the position of the object by evaluating the at least one sensor signal. Said position of the object can be static or may even comprise at least one movement of the object, for example a relative movement between the detector or parts thereof and the object or parts thereof. In this case, a relative movement can generally comprise at least one linear movement and/or at least one rotational movement. Items of movement information can for example also be obtained by comparison of at least two items of information picked up at different times, such that for example at least one item of location information can also comprise at least one item of velocity information and/or at least one item of acceleration information, for example at least one item of information about at least one relative velocity between the object or parts thereof and the detector or parts thereof. In particular, the at least one item of location information can generally be selected from: an item of information about a distance between the object or parts thereof and the detector or parts thereof, in particular an optical path length; an item of information about a distance or an optical distance between the object or parts thereof and the optional transfer device or parts thereof; an item of information about a positioning of the object or parts thereof relative to the detector or parts thereof; an item of information about an orientation of the object and/or parts thereof relative to the detector or parts thereof; an item of information about a relative movement between the object or parts thereof and the detector or parts thereof; an item of information about a two-dimensional or three-dimensional spatial configuration of the object or of parts thereof, in particular a geometry or form of the object. Generally, the at least one item of location information can therefore be selected for example from the group consisting of: an item of information about at least one location of the object or at least one part thereof; information about at least one orientation of the object or a part thereof; an item of information about a geometry or form of the object or of a part thereof, an item of information about a velocity of the object or of a part thereof, an item of information about an acceleration of the object or of a part thereof, an item of information about a presence or absence of the object or of a part thereof in a visual range of the detector.

The at least one item of location information can be specified for example in at least one coordinate system, for example a coordinate system in which the detector or parts thereof rest. Alternatively or additionally, the location information can also simply comprise for example a distance between the detector or parts thereof and the object or parts thereof. Combinations of the possibilities mentioned are also conceivable.

The evaluation device may be adapted to generate the at least one item of information on the longitudinal position of the object by determining a diameter of the light beam from the at least one longitudinal sensor signal. For further details with regard to determining the at least one item of information on the longitudinal position of the object by employing the evaluation device according to the present invention, reference may made to the description in WO 2014/097181 A1. Thus, generally, the evaluation device may be adapted to compare the beam cross-section and/or the diameter of the light beam with known beam properties of the light beam in order to determine the at least one item of information on the longitudinal position of the object, preferably from a known dependency of a beam diameter of the light beam on at least one propagation coordinate in a direction of propagation of the light beam and/or from a known Gaussian profile of the light beam.

The evaluation device may be designed to evaluate the longitudinal optical sensor signal unambiguously. The evaluation device may be configured to resolve an ambiguity in the known relationship between a beam cross-section of the light beam and the longitudinal position of the object. Thus, even if the beam properties of the light beam propagating from the object to the detector are known fully or partially, it is known that, in many beams, the beam cross-section narrows before reaching a focal point and, afterwards, widens again. Thus, before and after the focal point in which the light beam has the narrowest beam cross-section, positions along the axis of propagation of the light beam occur in which the light beam has the same cross-section. Thus, as an example, at a distance z0 before and after the focal point, the cross-section of the light beam is identical.

In this context, reference can be made to European patent application number 15191960.2 filed on Oct. 28, 2015, the full content of which is herewith included by reference. In case only one longitudinal optical sensor with a specific spectral sensitivity is used, a specific cross-section of the light beam might be determined, in case the overall power or intensity of the light beam is known. By using this information, the distance z0 of the respective longitudinal optical sensor from the focal point might be determined. However, in order to determine whether the respective longitudinal optical sensor is located before or behind the focal point, additional information is required, such as a history of movement of the object and/or the detector and/or information on whether the detector is located before or behind the focal point. In typical situations, this additional information may not be provided. Thus, to resolve ambiguities, the detector may comprise at least two longitudinal optical sensors. In case the evaluation device, by evaluating the longitudinal sensor signals, recognizes that the beam cross-section of the light beam on a first longitudinal optical sensor is larger than the beam cross-section of the light beam on a second longitudinal optical sensor, wherein the second longitudinal optical sensor is located behind the first longitudinal optical sensor, the evaluation device may determine that the light beam is still narrowing and that the location of the first longitudinal optical sensor is situated before the focal point of the light beam. Contrarily, in case the beam cross-section of the light beam on the first longitudinal optical sensor is smaller than the beam cross-section of the light beam on the second longitudinal optical sensor, the evaluation device may determine that the light beam is widening and that the location of the second longitudinal optical sensor is situated behind the focal point. Generally, the evaluation device may be adapted to recognize whether the light beam widens or narrows, by comparing the longitudinal sensor signals of different longitudinal sensors.

However, especially in view of cost-efficiency and space requirements, it may be desirable to determine the at least one item of information on the longitudinal position of the object without ambiguities by using a single longitudinal optical sensor. Thus, the longitudinal optical sensor may be operable in at least two operational modes. As used herein, the term “operational mode” refers to a state, in particular an operating state, of the longitudinal optical sensor. The operational mode may depend on the adjustable property of the longitudinal optical sensor. In case a light beam impinges on the longitudinal optical sensor, the longitudinal optical sensor in a first operational mode may generate a different longitudinal sensor signal compared to the longitudinal sensor signal generated in a second operational mode. As used herein, the term “operable in at least two operational modes” generally refers to the longitudinal optical sensor being configured to generate a longitudinal sensor signal in each operational mode. Thus, the longitudinal optical sensor may be configured for optical detection of the at least one object in at least two operational modes.

The detector may be configured to enable switching and/or changing between operational modes by adjusting the property of the longitudinal optical sensor. Specifically, the switching device may be configured to switch between at least two operational modes of the longitudinal optical sensor. The switching device may be configured to switch between operational states of the FiP based detector, in particular between an operational state, wherein the FiP detector is able to perform a FiP-based detection, and a state wherein the FiP detector is not able to perform a FiP-based detection.

For example, in at least one positive operational mode depending on the property of the longitudinal optical sensor an amplitude of the longitudinal sensor signal may increase with decreasing cross-section of a light spot generated by the light beam in the sensor region. As outlined above, the at least one longitudinal sensor signal, given the same total power of the illumination by the light beam, is dependent on a beam cross-section of the light beam in the sensor region of the at least one longitudinal optical sensor. In the positive operational mode, the longitudinal sensor signal, given the same total power, may exhibit at least one pronounced maximum for one or a plurality of focuses and/or for one or a plurality of specific sizes of the light spot on the sensor region or within the sensor region. For purposes of comparison, an observation of a maximum of the longitudinal sensor signal in a condition in which the sensor region is impinged by a light beam with the smallest possible cross-section, such as when the sensor region may be located at or near a focal point as affected by an optical lens, may be denominated as a “positive FiP-effect”.

Further, for example, in at least one negative operational mode depending on the property of the longitudinal optical sensor the amplitude of the longitudinal sensor signal may decrease with decreasing cross-section of a light spot generated by the light beam in the sensor region. As outlined above, the at least one longitudinal sensor signal, given the same total power of the illumination by the light beam, is dependent on a beam cross-section of the light beam in the sensor region of the at least one longitudinal optical sensor. In the negative operational mode, the longitudinal sensor signal, given the same total power, may exhibit at least one pronounced minimum for one or a plurality of focuses and/or for one or a plurality of specific sizes of the light spot on the sensor region or within the sensor region. For purposes of comparison, an observation of a minimum of the longitudinal sensor signal in a condition in which the sensor region is impinged by a light beam with the smallest possible cross-section, such as when the sensor region may be located at or near a focal point as affected by an optical lens, may be denominated as a “negative FiP-effect”.

Further for example, in at least one neutral operational mode depending on the property of the longitudinal sensor, the amplitude of the longitudinal sensor signal may be essentially independent from a variation of the cross-section of a light spot generated by the light beam in the sensor region. In particular, the longitudinal sensor signal may be essentially focus-independent. As used herein, the term “essentially independent from a variation of the cross-section” refers to the longitudinal sensor signal being independent from a variation of the cross-section, wherein deviations in amplitude of at least ±10%, preferably of ±5%, most preferably of ±1% of the longitudinal sensor signal may occur. In particular, in the neutral mode no global extremum may be observed.

The detector may be configured to enable switching and/or changing between at least two operational modes of the group consisting of: the positive operational mode; the negative operational mode; and the neutral operational mode. Thus, for example, the longitudinal optical sensor may be in the positive operational mode. The switching device may be configured to exert the at least one external influence and/or the at least one internal influence such that the operational mode of longitudinal optical sensor changes, for example to the negative operational mode or the neutral operational mode. For example, the longitudinal optical sensor may be in the negative operational mode. The switching device may be configured to exert the at least one external influence and/or the at least one internal influence such that the operational mode of longitudinal optical sensor changes, for example to the positive operational mode or the neutral operational mode. For example, the longitudinal optical sensor may be in the neutral operational mode. The switching device may be configured to exert the at least one external influence and/or the at least one internal influence such that the operational mode of longitudinal optical sensor changes, for example to the positive operational mode or the negative operational mode.

The evaluation device may be designed to determine the operational mode of the longitudinal optical sensor. The evaluation device may be configured to classify the operational mode of the longitudinal optical sensor. In particular, the evaluation device may be configured to observe and/or to identify a global extremum, e.g. a global minimum or a global maximum. In case no extremum is observed or identified, the evaluation device may classify the operational mode as neutral operational mode. The evaluation device may be configured to perform an analysis of the longitudinal sensor signal, in particular a curve analysis of the longitudinal sensor signal.

The evaluation device may be configured to determine the amplitude of the longitudinal sensor signal. The evaluation device may be designed to determine the longitudinal sensor signal one or both of sequentially or simultaneously in at least two operational modes. Thus, the evaluation device may be configured to evaluate at least two longitudinal sensor signals simultaneously. The evaluation device may be designed to resolve ambiguities by considering at least two longitudinal sensor signals determined in at least two different operational modes. Thus, at least two longitudinal sensor signals may be evaluated, wherein a first longitudinal sensor signal may be evaluated in a first operational mode and a second longitudinal sensor signal may be evaluated in a second operational mode. The evaluation device may be configured to resolve ambiguities by comparing the first longitudinal sensor signal and the second longitudinal sensor signal. The evaluation device may be adapted to normalize the longitudinal sensor signals and to generate the information on the longitudinal position of the object independent from an intensity of the light beam. For example, one of the first or second longitudinal sensor signals may be selected as reference signal. For example, the longitudinal sensor signal evaluated in the neutral operational mode may be selected as reference signal. For example, at least one of the longitudinal sensor signals evaluated in the positive operational mode or the negative operational mode may be selected as reference signal. By comparison of the selected reference signal and the other longitudinal signal, ambiguities may be eliminated. The longitudinal sensor signals may be compared, in order to gain information on the total power and/or intensity of the light beam and/or in order to normalize the longitudinal sensor signals and/or the at least one item of information on the longitudinal position of the object for the total power and/or total intensity of the light beam. For example, the longitudinal sensor signal may be normalized by division by the selected reference longitudinal sensor signal, in particular the longitudinal sensor signal evaluated in the neutral operational mode, thereby generating a normalized longitudinal optical sensor signal which, then, may be transformed by using the above-mentioned known relationship, into the at least one item of longitudinal information on the object. Thus, the transformation may be independent from the total power and/or intensity of the light beam. For example, at least one longitudinal sensor signal evaluated in one of the positive operational mode or the negative operational mode may be divided by the longitudinal sensor signal evaluated in the other one of the positive operational mode or the negative operational mode. Thus, by division, ambiguities may be eliminated.

The property of the longitudinal optical sensor may be electrically and/or optically adjustable.

The detector may comprise at least one biasing device. As used herein, the term “biasing device” generally refers to a device configured to apply a bias voltage across a material of the longitudinal optical sensor. The property of the longitudinal optical sensor may be electrically adjustable by the biasing device. The biasing device may be configured to apply at least one bias voltage to the longitudinal optical sensor. As will be outlined in further detail below, the property of the longitudinal optical sensor may be adjustable by using different bias voltages.

The longitudinal optical sensor may comprise at least one photodiode driven in a photoconductive mode, wherein the photoconductive mode refers to an electrical circuit employing a photodiode, wherein the at least one photodiode is comprised in a reverse biased mode, wherein the cathode of the photodiode is driven by a positive voltage with respect to the anode. According to the present invention, the at least one longitudinal optical sensor may exhibit at least one sensor region, wherein the sensor region may comprise at least one photoconductive material. As used herein, the term “photoconductive material” refers to a material which is capable of sustaining an electrical current and, therefore, exhibits a specific electrical conductivity, wherein, specifically, the electrical conductivity is dependent on the illumination of the material. Since an electrical resistivity is defined as the reciprocal value of the electrical conductivity, alternatively, the term “photoresistive material” may also be used to denominate the same kind of material. In this kind of material, the electrical current may be guided via at least one first electrical contact through the material to at least one second electrical contact, wherein the first electrical contact may be isolated from the second electrical contact while both the first electrical contact and the second electrical contact are in direct connection with the material. For this purpose, the direct connection may be provided by any known measure known from the state of the art, such as plating, welding, soldering, or depositing electrically highly conductive substances, in particular metals like gold, silver, platinum or palladium as well as alloys comprising at least one of the mentioned metals, at the contact zones.

Further, the sensor region of the longitudinal optical sensor may be illuminated by at the least one light beam. Given the same total power of the illumination, the electrical conductivity of the sensor region, therefore, may depend on the beam cross-section of the light beam in the sensor region, be denominated as a “spot size” generated by the incident beam within the sensor region. Thus, the observable property that the electrical conductivity of the photoconductive material depends on an extent of the illumination of the sensor region comprising the photoconductive material by an incident light beam particularly accomplishes that two light beams comprising the same total power but generating different spot sizes on the sensor region provide different values for the electrical conductivity of the photoconductive material in the sensor region and are, consequently, distinguishable with respect to each other.

Further, since the longitudinal sensor signal may be determined by applying an electrical signal, such as a voltage signal and/or a current signal, the electrical conductivity of the material which is traversed by the electrical signal may be, therefore, taken into account when determining the longitudinal sensor signal. As will be explained below in more detail, an application of a bias voltage source and of a load resistor employed in series with the longitudinal optical sensor may preferably be used here. As a result, the longitudinal optical sensor which comprises a photoconductive material within the sensor region, thus, principally allows determining the beam cross-section of the light beam in the sensor region from a recording of the longitudinal sensor signal, such as by comparing at least two longitudinal sensor signals, at least one item of information on the beam cross-section, specifically on the beam diameter.

As already known from WO 2012/110924 A1, the longitudinal optical sensor is designed to generate at least one longitudinal sensor signal in a manner dependent on an illumination of the sensor region, wherein the sensor signal, given the same total power of the illumination depends on a beam cross-section of the illumination on the sensor region. As an example, a measurement of a photocurrent I as a function of a position of a lens is provided there, wherein the lens is configured for focusing electromagnetic radiation onto the sensor region of the longitudinal optical sensor. During the measurement, the lens is displaced relative to the longitudinal optical sensor in a direction perpendicular to the sensor region in a manner that, as a result, the diameter of the light spot on the sensor region changes. In this particular example in which a photovoltaic device, in particular, a dye solar cell, is employed as the material in the sensor region, the signal of the longitudinal optical sensor, in this case a photocurrent, clearly depends on the geometry of the illumination such that, outside a maximum at the focus of the lens, the photocurrent falls to less than 10% of its maximum value.

This effect is particularly striking with respect to similar measurements performed by using silicon diodes and germanium diodes as the material in the sensor region. In this case in which optical sensors of a conventional type are used, the sensor signal, given the same total power, is substantially independent of a geometry of the illumination of the sensor region. Thus, according to the FiP-effect, the longitudinal sensor signal, given the same total power, may exhibit at least one pronounced maximum for one or a plurality of focuses and/or for one or a plurality of specific sizes of the light spot on the sensor region or within the sensor region. For purposes of comparison, an observation of a maximum of the longitudinal sensor signal in a condition in which the corresponding material is impinged by a light beam with the smallest possible cross-section, such as when the material may be located at or near a focal point as affected by an optical lens, may be denominated as a “positive FiP-effect”. As has been found so far, the above-mentioned photovoltaic device, in particular, the dye solar cell, provides a positive FiP-effect under these circumstances.

In this context, reference can be made to European patent application number 15191960.2 filed on Oct. 28, 2015, the full content of which is herewith included by reference. A photoconductive material is proposed as a further class of materials being appropriate to be employed in a longitudinal optical sensor which is designed to generate at least one longitudinal sensor signal in a manner dependent on an illumination of the sensor region, wherein the sensor signal, given the same total power of the illumination, depends on a beam cross-section of the illumination on the sensor region. This class of photoconductive materials may exhibit a “negative FiP-effect”, which, in correspondence to the definition of the positive FiP-effect, describes an observation of a minimum of the longitudinal sensor signal under a condition in which the corresponding material is impinged by a light beam with the smallest available beam cross-section, in particular, when the material may be located at or near a focal point as effected by an optical lens. Consequently, the photoconductive material may, thus, preferably be used under circumstances in which an appearance of the negative FiP-effect may be advantageous or required.

Within this regard, the difference between a photoconductive material and a photovoltaic material may be addressed here. In a longitudinal optical sensor comprising a photovoltaic material, an illumination of the respective sensor region may generate charge carriers which may provide a photoelectric current or a photoelectric voltage to be determined. As an example, when a light beam may be incident upon a photovoltaic material, the electrons which may be present in a valence band of the material may absorb energy and, thus being excited, may jump to the conduction band where they may behave as free conductive electrons. On the contrary, in a longitudinal optical sensor comprising a photoconductive material, the resistivity of the sensor region may be varied by the illumination of the corresponding sensor region, whereby the observable change in electrical conductivity of the material may be monitored by a variation in a voltage applied across the material or in an alteration of the value of a current applied through the material, such as by an application of a bias voltage across the material. For this purpose, a bias voltage source and a load resistor may, particularly, be employed in series with the longitudinal optical sensor.

This difference in behavior of the photoconductive material with respect to the photovoltaic material may be explained by a reasonable assumption that a density of the generated charge carriers may be proportional to the photon irradiance, wherein, however, at higher carrier densities, there may be a higher probability of electron-hole recombination, which may also be called “Auger recombination”. Herein, Auger recombination may be considered as a dominant loss mechanism. Therefore, as the intensity of the photon irradiance may increase, the carrier lifetime might decrease, which may result in the described effect in the photoconductive material. As a result, the longitudinal optical sensor comprising a photoconductive material may, in general, exhibit a behavior which may significantly be different and vary from the properties of the known longitudinal optical sensor which comprises a photovoltaic material.

For the purposes of the present invention, the photoconductive material as used in the sensor region of the longitudinal optical sensor may, preferably, comprise an inorganic photoconductive material, an organic photoconductive material or a combination thereof. For example, possible photoconductive materials may be described in European patent application number 15191960.2 filed on Oct. 28, 2015. Within this regard, the inorganic photoconductive material may, in particular, comprise one or more of selenium, tellurium, a selenium-tellurium alloy, a metal oxide, a group IV element or compound, i.e. an element from group IV or a chemical compound with at least one group IV element, a group III-V compound, i.e. a chemical compound with at least one group III element and at least one group V element, a group II-VI compound, i.e. a chemical compound with at least one group II element and at least one group VI element, and/or a chalcogenide, which might, preferably, be selected from a group comprising sulfide chalcogenides, selenide chalcogenides, ternary chalcogenides, quaternary and higher chalcogenides. However, other inorganic photoconductive materials may equally be appropriate.

With respect to selenium (Se), it may be mentioned that this material has long been known to exhibit photoconductive properties and has, therefore, been employed in early television, vidicon camera tubes, and xerography, and may still be used in the sensor region in photoconductive cells. Concerning selenium-tellurium alloys, P. H. Keck, Photoconductivity in Vacuum Coated Selenium Films, J. Opt. Soc. of America, 42, p.221-225, 1952, describes photoconductive selenium layers comprising an addition of 5 to 9 wt. % tellurium which, thus, is capable to increase the photoconductivity compared to a selenium layer without additional tellurium and, moreover, yields a high spectral response over the whole optical spectrum from 400 nm to 800 nm. Further, in order to provide photoconductive properties, U.S. Pat. No. 4,286,035 A discloses that the amount of tellurium in the selenium-tellurium alloy may further be increased from 5 wt. % up to 20 wt. % by simultaneously adding a concentration of at least one halogen in the photoconductive layer in a range from 5 ppm to 500 ppm, wherein the halogen is selected from the group consisting of fluorine, chlorine, bromine, and iodine.

With regard to the metal oxide, this kind of semiconducting material may be selected from a known metal oxide which may exhibit photoconductive properties, particularly from the group comprising copper (II) oxide (CuO), copper (I) oxide (CuO₂), nickel oxide (NiO), zinc oxide (ZnO), silver oxide (Ag₂O), manganese oxide (MnO), titanium dioxide (TiO₂), barium oxide (BaO), lead oxide (PbO), cerium oxide (CeO₂), bismuth oxide (Bi₂O₃), and cadmium oxide (CdO). Further ternary, quarternary or higher metal oxides may also be applicable. As will be explained later in more detail, it may be preferable to select a metal oxide which might, simultaneously, also exhibit transparent or translucent properties.

With regard to a group IV element or compound, this kind of semiconducting material may be selected from a group comprising doped diamond (C), doped silicon (Si), silicon carbide (SiC), and silicon germanium (SiGe). For providing a silicon-based photoconductor which may, especially simultaneously, exhibit a high resistivity, a high charge-carrier lifetime, and a low surface recombination rate, doped silicon comprising a low dopant concentration and a low defect density, such as existing in silicon float zone wafers, may preferably be selected. For this purpose, the silicon wafer may, in particular, exhibit
a dopant concentration of atoms of the dopant material of 10¹³ cm⁻³, 10¹² cm⁻³, 10¹¹ cm⁻³ or less;
an electrical resistivity of 10³ Ω·cm, preferred of 5·10³ Ω·cm, more preferred of 10⁴ Ω·cm, or higher; and
a thickness in a range between 500 μm, more preferred 300 μm, and 1 μm, more preferred 10 μm, for providing, on one hand, the desired high charge-carrier lifetime and, on the other hand, an amount of material sufficient for absorbing a significant amount of light at a target wavelength.

With regard to the III-V compound, this kind of semiconducting material may be selected from a group comprising indium antimonide (InSb), boron nitride (BN), boron phosphide (BP), boron arsenide (BAs), aluminum nitride (AlN), aluminum phosphide (AlP), aluminum arsenide (AlAs), aluminum antimonide (AlSb), indium nitride (InN), indium phosphide (InP), indium arsenide (InAs), indium antimonide (InSb), gallium nitride (GaN), gallium phosphide (GaP), gallium arsenide (GaAs), and gallium antimonide (GaSb).

With regard to the II-VI compound, this kind of semiconducting material may be selected from a group comprising cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), cadmium zinc telluride (CdZnTe), mercury cadmium telluride (HgCdTe), mercury zinc telluride (HgZnTe), and mercury zinc selenide (CdZnSe). However, other II-VI compounds may be feasible.

In a particularly preferred embodiment, the photoconductive material may be contacted by a so-called “ohmic contact”. As used herein, the ohmic contact may refer to an electrical junction which exhibits a linear current-voltage ratio according to Ohm's law but does not comprise any photovoltaic properties as described above. For providing the ohmic contact, gold, silver, silver-nickel, silver-iron, silver-graphite, silver-cadmium oxide, silver-tin oxide, copper, platinum, palladium, paliney alloys, indium, gallium, or indium amalgam may be employed, wherein the indium or the gallium may preferably be used in combination with cadmium sulfide (CdS) while the indium amalgam may particularly be suited for a use with other II-VI compounds.

As mentioned above, the chalcogenide, preferably selected from a group comprising sulfide chalcogenides, selenide chalcogenides, telluride chalcogenides, ternary chalcogenides, quaternary and higher chalcogenides, may preferably be appropriate to be used as the photoconductive material in the sensor region of the longitudinal optical sensor. This preference may particularly be based on a reason that this kind of material has already known to be both cost-efficient and reliable in many different areas of application, including optical detectors for the infrared spectral range.

In particular, the sulfide chalcogenide may be selected from a group comprising lead sulfide (PbS), cadmium sulfide (CdS), zinc sulfide (ZnS), mercury sulfide (HgS), silver sulfide (Ag₂S), manganese sulfide (MnS), bismuth trisulfide (Bi₂S₃), antimony trisulfide (Sb₂S₃), arsenic trisulfide (As₂S₃), tin (II) sulfide (SnS), tin (IV) disulfide (SnS₂), indium sulfide (In₂S₃), copper sulfide (CuS), cobalt sulfide (CoS), nickel sulfide (NiS), molybdenum disulfide (MoS₂), iron disulfide (FeS₂), and chromium trisulfide (CrS₃).

In particular, the selenide chalcogenide may be selected from a group comprising lead selenide (PbSe), cadmium selenide (CdSe), zinc selenide (ZnSe), bismuth triselenide (Bi₂Se₃), mercury selenide (HgSe), antimony triselenide (Sb₂Se₃), arsenic triselenide (As₂Se₃), nickel selenide (NiSe), thallium selenide (TISe), copper selenide (CuSe), molybdenum diselenide (MoSe₂), tin selenide (SnSe), and cobalt selenide (CoSe), and indium selenide (In₂Se₃).

In particular, the telluride chalcogenide may be selected from a group comprising lead telluride (PbTe), cadmium telluride (CdTe), zinc telluride (ZnTe), mercury telluride (HgTe), bismuth tritelluride (Bi₂Te₃), arsenic tritelluride (As₂Te₃), antimony tritelluride (Sb₂Te₃), nickel telluride (NiTe), thallium telluride (TITe), copper telluride (CuTe), molybdenum ditelluride (MoTe₂), tin telluride (SnTe), and cobalt telluride (CoTe), silver telluride (Ag₂Te), and indium telluride (In₂Te₃).

In particular, the ternary chalcogenide may be selected from a group comprising mercury cadmium telluride (HgCdTe), mercury zinc telluride (HgZnTe), mercury cadmium sulfide (HgCdS), lead cadmium sulfide (PbCdS), lead mercury sulfide (PbHgS), copper indium disulfide (CuInS₂), cadmium sulfoselenide (CdSSe), zinc sulfoselenide (ZnSSe), thallous sulfoselenide (TISSe), cadmium zinc sulfide (CdZnS), cadmium chromium sulfide (CdCr₂S₄), mercury chromium sulfide (HgCr₂S₄), copper chromium sulfide (CuCr₂S₄), cadmium lead selenide (CdPbSe), copper indium diselenide (CuInSe₂), indium gallium arsenide (InGaAs), lead oxide sulfide (Pb₂OS), lead oxide selenide (Pb₂OSe), lead sulfoselenide (PbSSe), arsenic selenide telluride (As₂Se₂Te), indium gallium phosphide (InGaP), gallium arsenide phosphide (GaAsP), aluminum gallium phosphide (AlGaP), cadmium selenite (CdSeO₃), cadmium zinc telluride (CdZnTe), and cadmium zinc selenide (CdZnSe), further combinations by applying compounds from the above listed binary chalcogenides and/or binary III-V-compounds.

With regard to quaternary and higher chalcogenides, this kind of material may be selected from a quaternary and higher chalcogenide which may be known to exhibit suitable photoconductive properties.

Generally, semiconductor materials with a three-dimensional crystal structure and an optical gap close to or below the spectral region of application are likely to be of interest if trap levels may be introduced either by doping with a further material or by obtaining a nanocrystalline, a microcrystalline, or an amorphous structure. Doping may, particularly, be achieved by adding metal atoms or salts to the semiconductor in a manner that the band structure of the semiconductor, preferably the conduction band, may be augmented by energy levels of the doping material, preferably with energy levels which are energetically above or below the conduction band. As a particular example, according to F. Stockmann, Superlinear photoconductivity, Phys. Stat. Solidi 34, 751-757, 1969, it may be possible that both the positive FiP-effect and the negative FiP-effect may be achieved in a photoconductive material, wherein the photoconductive material may be subject to a different position and/or concentration of traps and/or recombination centers within the selected photoconductive material.

Alternatively or in addition, the organic photoconductive material may, in particular, be or comprise an organic compound, in particular an organic compound which may be known to comprise appropriate photoconductive properties, preferably polyvinylcarbazole, a compound which is generally used in xerography. However, a large number of other organic molecules which will be described below in more detail may also be feasible.

With regard to printing and imaging systems, reference may be made to the article P. Gregory, Ed., Chemistry and Technology of printing and imaging systems, Chapman & Hall, 1996, Chap. 4, R. S. Gairns, Electrophotography, p. 76-112, wherein the technology of xerography and respective photoconductors which are used in xerography are described. Herein, as a particular example, a system first presented by R. M. Schaffert, IBM J. Res. Develop., 1971, p. 75-89, and comprising a charge-transfer complex based on polyvinylcarbazole (1) as a donor molecule with trinitrofluorenone (2) as an acceptor molecule may be used:

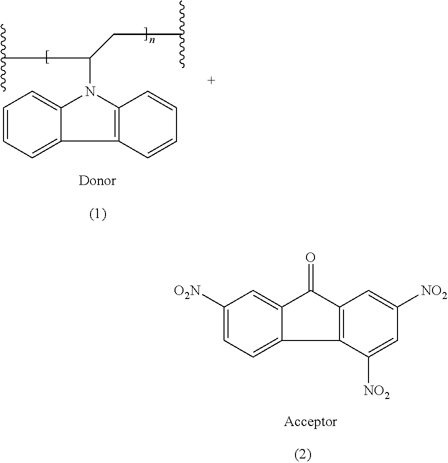 [SMILES: *CC(*)n1c2ccccc2c2ccccc21 ; O=C1c2cc([N+](=O)[O-])ccc2-c2c1cc([N+](=O)[O-])cc2[N+](=O)[O-]]

What can be derived from this example is that the organic photoconductors generally differ from their inorganic counterparts in that they may, particularly as a tribute to the nature of the corresponding photoconduction process, comprise a system of two different kinds of organic materials. The reason for this selection may be found in an observation that light striking the organic photoconductor located in an electrical field might be absorbed and may, subsequently, generate a pair of electrical charges which can, further, be transported in form of an electrical current which generates an influence on the photoconductivity of the organic photoconductor.

When using organic photoconductors, it may, thus, be feasible to separate the mentioned two kinds of processes, i.e. generating the electrical charges, on one hand, from transporting the electrical charges, on the other hand, by employing two different kinds of organic materials, which may be denoted as a donor-like “electron donor material” or “charge-generation material”, abbreviated to “CGM” and as an acceptor-like “electron acceptor material” or “charge-transport material”, abbreviated to “CTM”. As can be derived from the example as described above, the polyvinylcarbazole (1) may be considered as the charge-generation material while the trinitrofluorenone (2) may be regarded as the charge-transport material which act as the donor molecule and the acceptor molecule, respectively, in the above-mentioned system comprising the organic charge-transfer complex.

In a particularly preferred embodiment, the organic photoconductors may, thus, comprise at least one conjugated aromatic molecule, preferably a highly conjugated aromatic molecule, in particular a dye or a pigment, preferably to be employed as the charge-generation material. Within this respect, particularly preferred examples of conjugated aromatic molecules exhibiting photoconductive properties include phthalocyanines, such as metal phthalocyanines, in particular TiO-phthalocyanine; naphthalocyanines, such as metal-naphthalocyanines, in particular TiO-naphthalocyanine; subphthalocyanines, such as metal-subphthalocyanines; perylenes, anthracenes; pyrenes; oligo- and polythiophenes; fullerenes; indigoid dyes, such as thioindigos; bis-azo pigments; squarylium dyes; thiapyrilium dyes; azulenium dyes; dithioketo-pyrrolopyrroles; quinacridones; and other organic materials which may exhibit photoconductive properties, such as dibromoanthanthrone, or a derivative or a combination thereof. However, further conjugated aromatic molecules or, in addition, other kinds of organic materials, also in combination with inorganic materials, may also be feasible.

With regard to phthalocyanines, reference may be may made to Frank H. Moser and Arthur L. Thomas, Phthalocyanine Compounds, Reinhold Publishing, New York, 1963, p. 69-76, as well as to Arthur L. Thomas, Phthalocyanine Research and Applications, CRC Press, Boca Raton, 1990, p. 253-272. As presented there, dihydrogenphthalocyanine (3) or a metal phthalocyanine (4) may preferably be used in the detector according to the present invention:

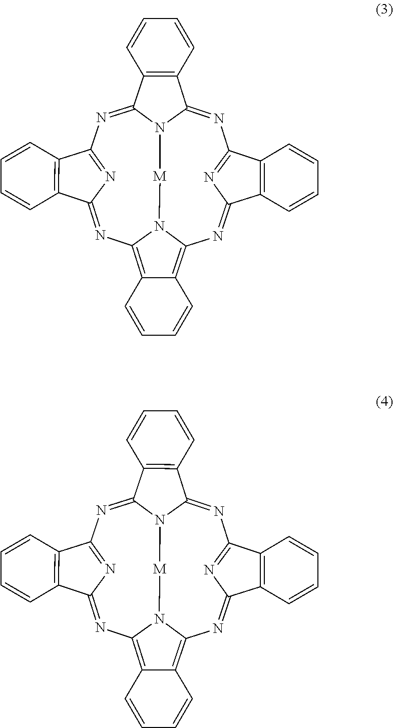

wherein the metal phthalocyanine (4) may, preferably, comprise a metal M selected from magnesium (Mg), copper (Cu), germanium (Ge), or zinc (Zn), or from a metal comprised in an inorganic compound, such as one of Al—Cl, Ga—Cl, In—Cl, TiOCl, VO, TiO, HGa, Si(OH)₂, Ge(OH)₂, Sn(OH)₂, or Ga(OH).

With respect to indigoid dyes, reference may be made to U.S. Pat. No. 4,952,472 A, in which the following three structures (5a, 5b, 5c), wherein X may equal O, S, or Se, are disclosed:

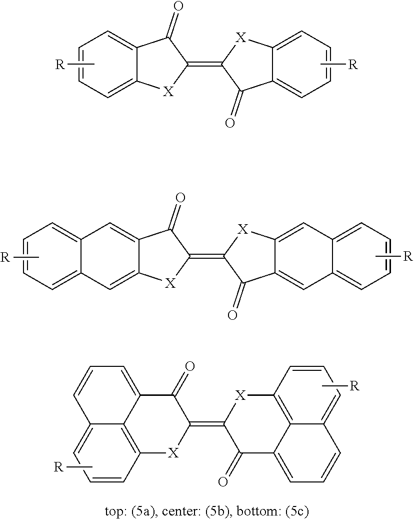

Herein, a preferred indigoid may comprise the compound 4,4′,7,7′-tetrachlorothioindigo (6) which is, for example, disclosed in K. Fukushima et al., Crystal Structures and Photocarrier Generation of Thioindigo Derivatives, J. Chem. Phys. B, 102, 1988, p. 5985-5990:

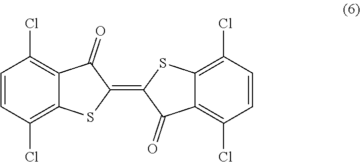 [SMILES: O=C1/C(=C2\Sc3c(Cl)ccc(Cl)c3C2=O)Sc2c(Cl)ccc(Cl)c21]

With regard to bis-azo pigments, a preferred example may be chlorodiane blue (7), which comprises the following structure:

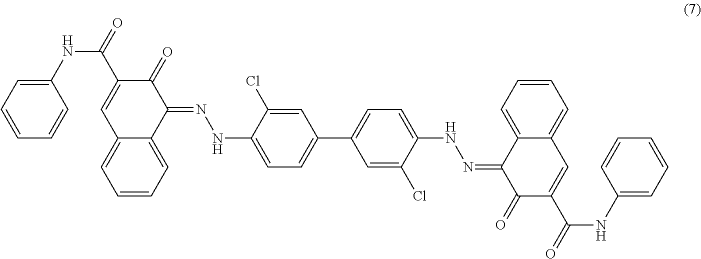 [SMILES: O=C(Nc1ccccc1)C1=Cc2ccccc2/C(=N\Nc2ccc(-c3ccc(N/N=C4/C(=O)C(C(=O)Nc5ccccc5)=Cc5ccccc54)c(Cl)c3)cc2Cl)C1=O]

With respect to perylene derivatives, preferably Perylenebisimides (8a) or Perylenemonoimides (8b), wherein R is an organic residue, preferably a branched or unbranched alkyl chain, may be used as photoconductive organic material:

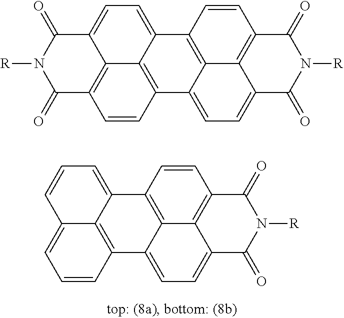

With regard to squarylium dyes, a preferred example may comprise the following molecule (9):

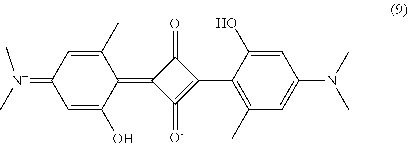

With respect to thiapyrilium dyes, a preferred example may comprise molecule (10) having the following structure:

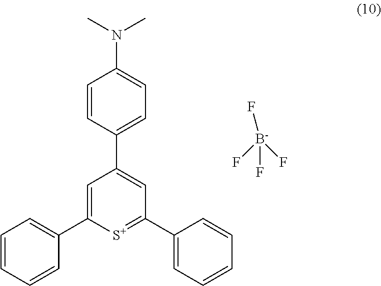 [SMILES: CN(C)c1ccc(-c2cc(-c3ccccc3)[s+]c(-c3ccccc3)c2)cc1 ; F[B-](F)(F)F]

Further, U.S. Pat. No. 4,565,761 A discloses a number of azulenium dyes, such as the following preferred compound (11):

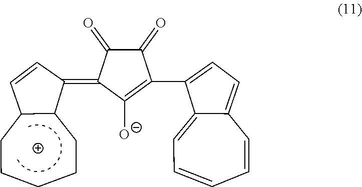 [SMILES: O=C1C(=O)/C(=C2\C=CC3CCCCCC23)C([O-])=C1c1ccc2cccccc1-2]

Concerning dithioketo-pyrrolopyrroles, U.S. Pat. No. 4,760,151 A discloses a number of compounds, such as the following preferred molecule (12):

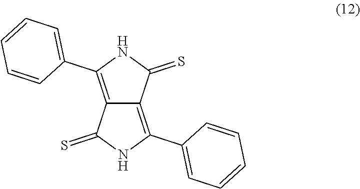 [SMILES: S=C1NC(c2ccccc2)=C2C(=S)NC(c3ccccc3)=C12]

With regard to quinacridones, U.S. Pat. No. 4,760,004 A discloses different thioquinacridones and isothioquinacridones, including the following preferred photoconductive compound (13):

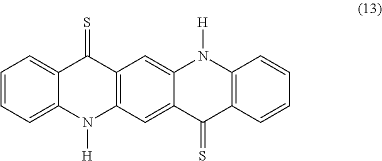 [SMILES: S=c1c2ccccc2[nH]c2cc3c(=S)c4ccccc4[nH]c3cc12]

As mentioned above, further organic materials, such as dibromoanthanthrone (14), may also exhibit photoconductive properties being sufficient for being used in the detector according to the present invention:

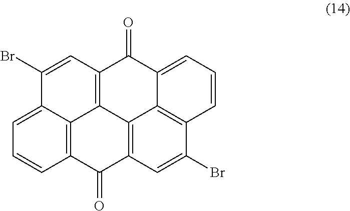 [SMILES: O=c1c2cc(Br)c3cccc4c(=O)c5cc(Br)c6cccc1c6c5-c2c34]

Furthermore, a mixture comprising at least one photoconductor and at least one sensitizer, such as further specified, for example, in U.S. Pat. No. 3,112,197 A or EP 0 112 169 A2 or in a respective reference therein, may also be suitable for being used in the detector according to the present invention. Accordingly, a photoconductive layer which comprises a dye sensitizer may be used for this purpose.

Preferably, the electron donor material and the electron acceptor material may be comprised within a layer which comprises the photoconductive material in form of a mixture. As generally used, the term “mixture” relates to a blend of two or more individual compounds, wherein the individual compounds within the mixture maintain their chemical identity. In a particularly preferred embodiment, the mixture may comprise the electron donor material and the electron acceptor material in a ratio from 1:100 to 100:1, more preferred from 1:10 to 10:1, in particular in a ratio of from 1:2 to 2:1, such as 1:1. However, other ratios of the respective compounds may also be applicable, in particular depending on the kind and number of individual compounds being involved. Preferably, the electron donor material and the electron acceptor material as comprised in form of the mixture may constitute an interpenetrating network of donor domains, in which the electron donor material may predominantly, particularly completely, be present, and of acceptor domains, in which the electron acceptor material may predominantly, in particular completely, be present, wherein interfacial areas between the donor domains and the acceptor domains may exist, and wherein as conductive paths in form of percolation pathways may connect the corresponding domains to the respective electrodes.

In a further preferred embodiment, the electron donor material in the photoconductive layer may comprise a donor polymer, in particular an organic donor polymer, whereas the electron acceptor material may comprise an acceptor small molecule, preferably selected from the group comprising a fullerene-based electron acceptor material, tetracyanoquinodimethane (TCNQ), a perylene derivate, and an acceptor polymer. Thus, the electron donor material may comprise a donor polymer while the electron acceptor material may comprise an acceptor polymer, thus providing a basis for an all-polymer photoconductive layer. In a particular embodiment, a copolymer may, simultaneously, be constituted from one of the donor polymers and from one of the acceptor polymers and which may, therefore, also be denominated as a “push-pull copolymer” based on the respective function of each of the constituents of the copolymer. As generally used, the term “polymer” refers to a macromolecular composition generally comprising a large number of molecular repeat units, which are usually denominated as “monomers” or “monomeric units”. For the purposes of the present invention, however, a synthetic organic polymer may be preferred. Within this regard, the term “organic polymer” refers to the nature of the monomeric units which may, generally, be attributed as organic chemical compounds. As used herein, the term “donor polymer” refers to a polymer which may particularly be adapted to provide electrons as the electron donor material. Analogously, the term “acceptor polymer” refers to a polymer which may particularly be adapted to receive electrons as the electron acceptor material. Preferably, the layer comprising the organic electron donor material and the organic electron acceptor material may exhibit a thickness from 100 nm to 2000 nm.

Thus, the at least one electron donor material may comprise a donor polymer, in particular an organic donor polymer. Preferably, the donor polymer may comprise a conjugated system, in which delocalized electrons may be distributed over a group of atoms being bonded together by alternating single and multiple bonds, wherein the conjugated system may be one or more of cyclic, acyclic, and linear. Thus, the organic donor polymer may, preferably, be selected from one or more of the following polymers:
poly[3-hexylthiophene-2,5.diyl] (P3HT),
poly[3-(4-n-octyl)-phenylthiophene] (POPT),
poly[3-10-n-octyl-3-phenothiazine-vinylenethiophene-co-2,5-thiophene] (PTZV-PT), poly[4,8-bis[(2-ethylhexyl)oxy]benzo[1,2-b:4,5-b]dithiophene-2,6-diyl][3-fluoro-2-[(2-ethylhexyl)carbonyl]thieno[3,4-b]thiophenediyl] (PTB7),
poly[thiophene-2,5-diyl-alt-[5,6-bis(dodecyloxy)benzo[c][1,2,5]thiadiazole]-4,7-diyl] (PBT-T1),
poly[2,6-(4,4-bis-(2-ethylhexyl)-4H-cyclopenta[2,1-b,3,4-b]dithiophene)-alt-4,7(2,1,3-benzothiadiazole)] (PCPDTBT),
poly[5,7-bis(4-decanyl-2-thienyl)-thieno(3,4-b)diathiazolethiophene-2,5] (PDDTT),
poly[N-9′-heptadecanyl-2,7-carbazole-alt-5,5-(4′,7′-di-2-thienyl-2′,1′,3′-benzothiadiazole)] (PCDTBT), or
poly[(4,4′-bis(2-ethylhexyl)dithieno[3,2-b;2′,3′-d]silole)-2,6-diyl-alt-(2,1,3-benzothiadiazole)-4,7-diyl] (PSBTBT),
poly[3-phenylhydrazone thiophene] (PPHT),
poly[2-methoxy-5-(2-ethylhexyloxy)-1,4-phenylenevinylene] (MEH-PPV),
poly[2-methoxy-5-(2′-ethylhexyloxy)-1,4-phenylene-1,2-ethenylene-2,5-dimethoxy-1,4-phenylene-1,2-ethenylene] (M3EH-PPV),
poly[2-methoxy-5-(3′,7′-dimethyloctyloxy)-1,4-phenylenevinylene] (MDMO-PPV),
poly[9,9-di-octylfluorene-co-bis-N,N-4-butylphenyl-bis-N,N-phenyl-1,4-phenylenediamine] (PFB),
   or a derivative, a modification, or a mixture thereof.

However, other kinds of donor polymers or further electron donor materials may also be suitable, in particular polymers which are sensitive in the infrared spectral range, especially above 1000 nm, preferably diketopyrrolopyrrol polymers, in particular, the polymers as described in EP 2 818 493 A1, more preferably the polymers denoted as “P-1” to “P-10” therein; benzodithiophene polymers as disclosed in WO 2014/086722 A1, especially diketopyrrolopyrrol polymers comprising benzodithiophene units; dithienobenzofuran polymers according to US 2015/0132887 A1, especially dithienobenzofuran polymers comprising diketopyrrolopyrrol units; phenantro[9, 10-B]furan polymers as described in US 2015/0111337 A1, especially phenantro[9, 10-B]furan polymers which comprise diketopyrrolopyrrol units; and polymer compositions comprising diketopyrrolopyrrol oligomers, in particular, in an oligomer-polymer ratio of 1:10 or 1:100, such as disclosed in US 2014/0217329 A1.

As further mentioned above, the electron acceptor material may, preferably, comprise a fullerene-based electron acceptor material. As generally used, the term “fullerenes” refers to cagelike molecules of pure carbon, including Buckminster fullerene (C60) and the related spherical fullerenes. In principle, the fullerenes in the range of from C20 to C2000 may be used, the range C60 to C96 being preferred, particularly C60, C70 and C84. Mostly preferred are fullerenes which are chemically modified, in particular one or more of:
[6,6]-phenyl-C61-butyric acid methyl ester (PC60BM),
[6,6]-Phenyl-C71-butyric acid methyl ester (PC70BM),
[6,6]-phenyl C84 butyric acid methyl ester (PC84BM), or
an indene-C60 bisadduct (ICBA),
   but also dimers comprising one or two C60 or C70 moieties, in particular
a diphenylmethanofullerene (DPM) moiety comprising one attached oligoether (OE) chain (C70-DPM-OE), or
a diphenylmethanofullerene (DPM) moiety comprising two attached oligoether (OE) chains (C70-DPM-OE2),
   or a derivative, a modification, or a mixture thereof. However, TCNQ, or a perylene derivative may also be suitable.

Alternatively or in addition, the electron acceptor material may, preferably, comprise an acceptor polymer. Generally, conjugated polymers based on cyanated poly(phenylenevinylene), benzothiadiazole, perylene or naphthalenediimide are preferred for this purpose. In particular, the acceptor polymer may, preferably, be selected from one or more of the following polymers:
a cyano-poly[phenylenevinylene] (CN-PPV), such as C6-CN-PPV or C8-CN-PPV,
poly[5-(2-(ethylhexyloxy)-2-methoxycyanoterephthalyliden] (MEH-CN-PPV),
poly[oxa-1,4-phenylene-1,2-(1-cyano)-ethylene-2,5-dioctyloxy-1,4-phenylene-1,2-(2-cyano)ethylene-1,4-phenylene] (CN-ether-PPV),
poly[1,4-dioctyloxyl-p-2,5-dicyanophenylenevinylene] (DOCN-PPV),
poly[9,9′-dioctylfluoreneco-benzothiadiazole] (PF8BT),
   or a derivative, a modification, or a mixture thereof. However, other kinds of acceptor polymers may also be suitable.

For more details concerning the mentioned compounds which may be used as the donor polymer or the electron acceptor material, reference may be made to the review articles by L. Biana, E. Zhua, J. Tanga, W. Tanga, and F. Zhang, Progress in Polymer Science 37, 2012, p. 1292-1331, A. Facchetti, Materials Today, Vol. 16, No. 4, 2013, p. 123-132, and S. Günes and N. S. Sariciftci, Inorganica Chimica Acta 361, 2008, p. 581-588, as well as the respective references cited therein. Further compounds are described in the dissertation of F. A. Sperlich, Electron Paramagnetic Resonance Spectroscopy of Conjugated Polymers and Fullerenes for Organic Photovoltaics, Julius-Maximilians-Universitat Würzburg, 2013, and the references cited therein.

As used herein, the “photoconductive mode” refers to an electrical circuit employing a photodiode, wherein the at least one photodiode is comprised in a reverse biased mode, i.e. wherein the cathode of the photodiode is driven with a positive voltage with respect to the anode. This is in contrast to the so-called “photovoltaic mode”, which uses a zero bias. Applying the photoconductive mode to the photodiode, generally, leads to the observation that, given the same total power of the illumination, the photocurrent is found to be dependent on the beam cross-section of the light beam in the sensor region. Consequently, since the longitudinal sensor signal is dependent on the electrical conductivity, recording the at least one longitudinal sensor signal, thus, allows determining the beam cross-section of the light beam in the sensor region and, thus, as described above, generating at least one item of information on a longitudinal position of the object.

As outlined above, applying the photoconductive mode to the photodiode, generally, leads to the observation that, given the same total power of the illumination, the photocurrent is found to be dependent on the beam cross-section of the light beam in the sensor region. The property of the longitudinal optical sensor may be electrically adjustable by applying different bias voltages to the photodiode. The biasing device may comprise a bias voltage source. The property of the longitudinal optical sensor may be electrically adjustable by the biasing device. The biasing device may be configured to apply at least two different bias voltages to the photodiode such that it may be possible to switch between operational modes of the longitudinal optical sensor. For example, a zero bias may be used, such that the photodiode may be unbiased and in the photovoltaic mode. Under this condition, the longitudinal optical sensor may be in the neutral operational mode. For example, a non-zero bias voltage may be applied to the photodiode, specifically a reverse bias, e.g. a positive voltage may be applied to the cathode. Under this condition, the longitudinal optical sensor may be in a positive or a negative operational mode. The switching device may be adapted to exert an influence on the bias voltage source in order to set the bias voltage. Adjusting the property of the longitudinal optical sensor may require a certain time period after a voltage change. However, a time period between a detection in a first operational mode and a detection in a second operational mode may be as short as possible.

The sensor region may comprise at least one material which is capable of sustaining an electrical current, such as a metal or a semiconducting material, Herein, at least one property of the material, being the electrical conductivity of the material or another material property, such as a thermal conductivity, an absorbance, a scattering property, a dielectric property, a magnetic property, or an optical property of the material, in particular a polarization, a reflectance, a refractive index, or a transmission, of the material, given the same total power of the illumination, is dependent on the beam cross-section of the light beam in the sensor region.

As a result, the longitudinal sensor signal may be dependent on the at least one property of the material as employed here for the purposes of the detector according to the present invention. Consequently, measuring the at least one property by recording the at least one longitudinal sensor signal may allow determining the beam cross-section of the light beam in the sensor region and, thus, as described above, generating at least one item of information on a longitudinal position of the object. Herein, the longitudinal signal may be an electrical signal, such as a voltage or a current, but may, first, be a physical signal of a different kind, in particular an optical signal, which may, thereafter, be transformed into an electrical signal, which may, then, be further treated as the longitudinal sensor signal. For further details concerning this aspect of the present invention, reference may be made to the description of the other aspects of the optical detector as provided above and/or below.

The material capable of sustaining an electrical current may comprise one or more of amorphous silicon, an alloy comprising amorphous silicon, microcrystalline silicon or cadmium telluride (CdTe). As generally used, the term “amorphous silicon”, also abbreviated as “a-Si”, relates to a non-crystalline allotropic form of silicon. The alloy comprising amorphous silicon may be an amorphous alloy comprising silicon and carbon or an amorphous alloy comprising silicon and germanium. As further known from the state of the art, the amorphous silicon can be obtained by depositing it as a layer, especially as a thin film, onto an appropriate substrate. However, other methods may be applicable. Further, the amorphous silicon may especially be passivated by using hydrogen, by which application a number of dangling bonds within the amorphous silicon may be reduced by several orders of magnitude. As a result, hydrogenated amorphous silicon, usually abbreviated to “a-Si:H”, may exhibit a low amount of defects, thus, allow using it for optical devices.

In this particular embodiment, the longitudinal optical sensor may be a photo detector having at least one first electrode and at least one second electrode while the amorphous silicon may, preferably, be located between the first electrode and the second electrode. In particular for a purpose of facilitating the light beam which may impinge the longitudinal optical sensor to arrive at a layer comprising the amorphous silicon, at least one of the electrodes, in particular the electrode which may be located within the path of the incident light beam, may be selected to be at least partially optically transparent. Herein, the at least partially optically transparent electrode may comprise at least one transparent conductive oxide (TCO), in particular at least one of indium-doped tin oxide (ITO), fluorine-doped tin oxide (FTO), and aluminum-doped zinc oxide (AZO). However, other kinds of optically transparent materials which may be suited as electrode material may also be applicable. The one or more remaining electrodes, also denominated as “back electrodes”, may also be optically intransparent, in particularly as long as they are located outside the path of the light beam within the longitudinal optical sensor. Herein, the at least one optically intransparent electrode may, preferably, comprise a metal electrode, in particular one or more of a silver (Ag) electrode, a platinum (Pt) electrode, an aluminum (Al) electrode, and a gold (Au) electrode. Preferably, the optically intransparent electrode may comprise a uniform metal layer. Alternatively, the optically intransparent electrode may be a split electrode being arranged as a number of partial electrodes or in form of a metallic grid.

Preferably, the amorphous silicon which is located between the first electrode and the second electrode may be arranged in form of a PIN diode. As generally used, the term “PIN diode” refers to an electronic device which comprises an i-type semiconductor layer that is located between an n-type semiconductor layer and a p-type semiconductor layer. As known from the state of the art, while in the n-type semiconducting layer charge carriers are predominantly provided by electrons, in the p-type semiconducting layer the charge carriers are predominantly provided by holes. In a preferred embodiment, the p-type semiconducting layer can partially or wholly be comprised of amorphous silicon carbide. Further, the i-type semiconducting layer comprises an undoped intrinsic amorphous silicon. In particular, in the longitudinal optical sensor according to the present invention, the i-type semiconductor layer may exhibit a thickness which may exceed the thickness of each of the n-type semiconductor layer and the p-type semiconductor layer, in particular by a factor of at least 2, preferably of at least 5, more preferred of at least 10 or more. As an example, the thickness of the i-type semiconducting layer may be from 100 nm to 3000 nm, in particular from 600 nm to 800 nm, whereas the thickness of both the n-type and the p-type semiconductor layer may be from 5 nm to 100 nm, in particular from 10 nm to 60 nm.

Photovoltaic diodes which are provided in the form of a PIN diode comprising amorphous silicon are, generally, known to exhibit a non-linear frequency response. As a result, the positive and/or the negative FiP effect may be observable in the longitudinal sensor which may, moreover, be substantially frequency-independent in a range of a modulation frequency of the light beam of 0 Hz to 50 kHz. Experimental results which demonstrate an occurrence of the mentioned features will be presented below in more detail. Further, the optical detector comprising the amorphous silicon may exhibit the particular advantages of abundance of the respective semiconducting material, of an easy production route, and of a considerably high signal-to-noise ratio compared to other known FiP devices.

Further, taking into account a behavior of an external quantum efficiency of the PIN diode vs. the wavelength of the incident beam may provide insight into a wavelength range of the incident beam for which the PIN diode may particularly be suitable. Herein, the term “external quantum efficiency” refers to a fraction of photon flux which may contribute to the photocurrent in the present sensor. As a result, the PIN diode which comprises the amorphous silicon may exhibit a particularly high value for the external quantum efficiency within the wavelength range which may extend from 380 nm to 700 nm whereas the external quantum efficiency may be lower for wavelengths outside this range, in particular for wavelengths below 380 nm, i.e. within the UV range, and for wavelengths above 700 nm, in particular within the NIR range, thereby being vanishingly small above 800 nm. Consequently, the PIN diode which the amorphous silicon in at least one of the semiconductor layers may preferably be employed in the detector according to the present invention for the optical detection of the at least one object when the incident beam has a wavelength within a range which covers most of the visual spectral range, especially from 380 nm to 700 nm.

Alternatively, a further PIN diode may be provided which could preferably be employed in the detector according to the present invention when the incident beam may have a wavelength within the UV spectral range. As used herein, the term “UV spectral range” may cover a partition of the electromagnetic spectrum from 1 nm to 400 nm, in particular from 100 nm to 400 nm, and can be subdivided into a number of ranges as recommended by the ISO standard ISO-21348, wherein the alternative PIN diode provided here may particularly be suitable for the Ultraviolet A range, abbreviated to “UVA”, from 400 nm to 315 nm and/or the Ultraviolet B range, abbreviated to “UVB” from 315 nm to 280 nm. For this purpose, the alternative PIN diode may exhibit the same or a similar arrangement as the PIN diode comprising the amorphous silicon as described above and/or below, wherein the amorphous silicon (a-Si) or the hydrogenated amorphous silicon (a-Si:H), respectively, may at least partially be replaced by an amorphous alloy of silicon and carbon (a-SiC) or, preferably, by a hydrogenated amorphous silicon carbon alloy (a-SiC:H). This kind of alternative PIN diode may exhibit a high external quantum efficiency within the UV wavelength range preferably, over the complete UVA and UVB wavelength range from 280 nm to 400 nm. Herein, the hydrogenated amorphous silicon carbon alloy (a-SiC:H) may, preferably, be produced in a plasma-enhanced deposition process, typically by using SiH4 and CH4 as process gases. However, other production methods for providing a-SiC:H may also be applicable.

As known from prior art, a layer comprising the hydrogenated amorphous silicon carbon alloy a-SiC:H may usually exhibit a hole mobility which may significantly be smaller compared to an electron mobility in a layer comprising the hydrogenated amorphous silicon a-Si:H. Thus, the layer comprising a-SiC:H may be employed as a p-doped hole extraction layer, particularly arranged on the side of a device at which the light beam may enter the device. As a result of this arrangement, a distance over which holes might have to travel in order to be able to contribute to the photocurrent can be considerably reduced. Consequently, it may, thus, be advantageous to provide a PIN diode in the detector according to the present invention in which the p-type semiconductor layer may exhibit a thickness from 2 nm to 20 nm, preferably from 4 nm to 10 nm, such as about 5 nm. Still, a particular light beam having a wavelength in the UV spectral range, especially within the UVA spectral range and/or the UVB spectral range, which may impinge on a side of the PIN diode comprising this kind of thin p-type semiconductor layer may be absorbed therein. In addition, this kind of thin layer may, further, allow electrons to traverse the layer and, thus, to enter into the adjacent i-type semiconductor layer of the PIN diode. Herein, the i-type semiconductor layer which may, preferably, also comprise a-SiC:H may, equally, exhibit a thickness from 2 nm to 20 nm, preferably from 4 nm to 10 nm, such as about 5 nm. However, other kinds of PIN diodes in which at least one of the semiconductor layers may comprise at least partially a-SiC:H may also be feasible.

As described above, non-linear effects which are involved in the production of the photocurrent may constitute a basis for the occurrence of the FiP effect in the longitudinal sensor being equipped with a PIN diode comprising these kinds of semiconductor layers. As a result, this kind of longitudinal sensors may, in particular, be used in applications in which a UV response may be required, such as for being able to observe optical phenomena in the UV spectral range, or suitable, such as when an active target which may emit at least one wavelength within the UV spectral range might be used.

Alternatively, a further PIN diode may be provided which could preferably be employed in the detector according to the present invention when the incident beam may have a wavelength within the NIR spectral range. As used herein, the term “NIR spectral range”, which may also abbreviated to “IR-A”, may cover a partition of the electromagnetic spectrum from 760 nm to 1400 nm as recommended by the ISO standard ISO-21348. For this purpose, the alternative PIN diode may exhibit the same or a similar arrangement as the PIN diode comprising the amorphous silicon as described above and/or below, wherein the amorphous silicon (a-Si) or the hydrogenated amorphous silicon (a-Si:H), respectively, may at least partially be replaced by one of a microcrystalline silicon (μc-Si), preferably a hydrogenated microcrystalline silicon (μc-Si:H), or an amorphous alloy of germanium and silicon (a-GeSi), preferably a hydrogenated amorphous germanium silicon alloy (a-GeSi:H). This further kind of PIN diode may exhibit a high external quantum efficiency over a wavelength range which may at least partially cover the NIR wavelength range from 760 nm to 1400 nm, in particular at least from 760 nm to 1000 nm. By way of example, the PIN diode comprising μc-Si has a non-negligible quantum efficiency over a wavelength range which approximately extends from 500 nm to 1100 nm.

Herein, the hydrogenated microcrystalline silicon (μc-Si:H) may, preferably, be produced from a gaseous mixture of SiH4 and CH4. As a result, a two-phase material on a substrate comprising microcrystallites having a typical size of 5 nm to 30 nm and being located between ordered columns of the substrate material spaced apart 10 nm to 200 nm with respect to each other may be obtained. However, another production method for providing μc-Si:H may also be applicable which may, however not necessarily, lead to an alternative arrangement of the μc-Si:H. Further, the hydrogenated amorphous germanium silicon alloy (a-GeSi:H) may, preferably, be produced by using SiH4, GeH4, and H2 as process gases within a common reactor. Also here, other production methods for providing a-GeSi:H may be feasible.

Comparing both μc-Si:H and a-GeSi:H to a-Si:H, the semiconductor layers comprising μc-Si:H and a-GeSi:H may have a similar or an increased disorder-induced localization of charge carriers, thus, exhibiting a considerably non-linear frequency response. As described above, this may constitute a basis for the occurrence of the FiP effect in the longitudinal sensor being equipped with a PIN diode comprising these kinds of semiconductor layers. As a result, this kind of longitudinal sensors may, in particular, be used in applications in which a NIR response may be required, such as in night vision or fog vision, or suitable, such as when an active target emitting at least one wavelength within the NIR spectral range may be used, for example, in a case in which it might be advantageous when animals or human beings may be left undisturbed by using an NIR illumination source.

The property of the longitudinal optical sensor may be adjustable, in particular changeable, by at least one property of the light beam. Herein, at least one property of the light beam, may be one or more of wavelength, modulation frequency or intensity of the light beam. The light beam may be modulated by one or more modulation frequencies. For example, a focus of the light beam may be adjustable, in particular changeable, by modulating the light beam using one or more modulation frequencies. In particular, the light beam may be focused or may be unfocussed when impinging on the longitudinal optical sensor. The at least one property of the light beam may be or may relate to a property of at least one light source, for example at least one illumination source. The property of the light beam may relate to a size of the light source. Thus, the size of the light source may be variable and/or adjustable, e.g. by one ore more of a diffusor, in particular at least one diffusor disc, at least one lens or at least one mask, in particular at least one dot pattern. For example, in one embodiment, at least one LED in combination with a diffusor may be used. The detector, furthermore, may comprise at least one illumination source. Light emerging from the object can originate in the object itself, but can also optionally have a different origin and propagate from this origin to the object and subsequently toward the optical sensors. The latter case can be affected for example by at least one illumination source being used. The illumination source can be embodied in various ways. Thus, the illumination source can be for example part of the detector in a detector housing. Alternatively or additionally, however, the at least one illumination source can also be arranged outside a detector housing, for example as a separate light source. The illumination source can be arranged separately from the object and illuminate the object from a distance. Alternatively or additionally, the illumination source can also be connected to the object or even be part of the object, such that, by way of example, the electromagnetic radiation emerging from the object can also be generated directly by the illumination source. By way of example, at least one illumination source can be arranged on and/or in the object and directly generate the electromagnetic radiation by means of which the sensor region is illuminated. This illumination source can for example be or comprise an ambient light source and/or may be or may comprise an artificial illumination source. By way of example, at least one infrared emitter and/or at least one emitter for visible light and/or at least one emitter for ultraviolet light can be arranged on the object. By way of example, at least one light emitting diode and/or at least one laser diode can be arranged on and/or in the object. The illumination source can comprise in particular one or a plurality of the following illumination sources: a laser, in particular a laser diode, although in principle, alternatively or additionally, other types of lasers can also be used; a light emitting diode; an incandescent lamp; a neon light; a flame source; a heat source; an organic light source, in particular an organic light emitting diode; a structured light source. Alternatively or additionally, other illumination sources can also be used. It is particularly preferred if the illumination source is designed to generate one or more light beams having a Gaussian beam profile, as is at least approximately the case for example in many lasers. For further potential embodiments of the optional illumination source, reference may be made to one of WO 2012/110924 A1 and WO 2014/097181 A1. Still, other embodiments are feasible.

The at least one optional illumination source generally may emit light in at least one of: the ultraviolet spectral range, preferably in the range of 200 nm to 380 nm; the visible spectral range (380 nm to 780 nm); the infrared spectral range, preferably in the range of 780 nm to 3.0 micrometers. Most preferably, the at least one illumination source is adapted to emit light in the visible spectral range, preferably in the range of 500 nm to 780 nm, most preferably at 650 nm to 750 nm or at 690 nm to 700 nm. Herein, it is particularly preferred when the illumination source may exhibit a spectral range which may be related to the spectral sensitivities of the longitudinal sensors, particularly in a manner to ensure that the longitudinal sensor which may be illuminated by the respective illumination source may provide a sensor signal with a high intensity which may, thus, enable a high-resolution evaluation with a sufficient signal-to-noise-ratio.

The illumination source may be adapted to emit light in at least two different wavelengths. The illumination source may be configured to switch between emitting light in at least one first wavelength and emitting light in at least one second wavelength. The illumination source may be designed to emit at least two light beams, wherein at least one property of a first light beam may be different from at least one property of a second light beam, wherein the property may be selected from the group consisting of wavelength, modulation frequency, or intensity of the light beam. The light beam may be modulated by one or more modulation frequencies. For example, a focus of the light beam may be adjustable, in particular changeable, by modulating the light beam using one or more modulation frequencies. In particular, the light beam may be focused or may be unfocussed when impinging on the longitudinal optical sensor. The at least one property of the light beam may be or may relate to a property of at least one light source, for example at least one illumination source. The property of the light beam may relate to a size of the light source. Thus, the size of the light source may be variable and/or adjustable, e.g. by one ore more of a diffusor, in particular at least one diffusor disc, at least one lens or at least one mask, in particular at least one dot pattern. For example, in one embodiment, at least one LED in combination with a diffusor may be used. For example, at least one external influence, such as an influence by a user and/or the evaluation device and/or the switching device may trigger the illumination device to switch between wavelengths. For example, the illumination source may comprise at least one light source adapted to emit light in different wavelengths, wherein the wavelength of the emitted light beam may be adjustable, in particular by an external influence. The switching device may be adapted to exert an influence on the illumination source in order to set the wavelength of the emitted light beam and/or the wavelengths of the emitted at least two light beams. For example, the illumination source may comprise at least two light sources, wherein the at least two light sources are configured to emit light in different wavelengths. Thus, a first light source may provide a light beam having a first wavelength and a second light source may provide a light beam having a second wavelength. The first light beam and the second light beam may be emitted simultaneously or sequentially. For example, in case the illumination source comprises two light sources, the first light source providing the first light beam may stay switched on, while the second light source may provide the second light beam. The first light beam may have a first wavelength and the second light beam may have a second wavelength, wherein the property of the longitudinal optical sensor may be adjusted, in particular changes by illumination with the first light beam and the second light beam. Illumination by the first light beam may result in adjusting the property of the longitudinal optical sensor such that the longitudinal optical sensor is in one of the neutral operational mode, the positive operational mode, or the negative operational mode. Switching from one property of the light beam to another property of the light beam, e.g. a change from one wavelength to another, can be part of a phase sensitive measurement. This may allow a direct referencing at the measurement, for example in lock-in amplifier measurements. Illumination by the second light beam may result in adjusting the property of the longitudinal optical sensor such that the longitudinal optical sensor may be in another operational mode which is different from the operational mode during illumination by the first light beam. By switching between at least two wavelengths the property of the longitudinal optical sensor may be adjusted such that the longitudinal optical sensor is operable in at least two operational modes. As outlined above, the evaluation device may be designed to resolve ambiguities by considering at least two longitudinal sensor signals determined in at least two different operational modes.

For example, the first wavelength may be a short wavelength compared to the second wavelength. In particular the first wavelength may be in the visible spectral range, preferably in the range of 380 to 450 nm, more preferably in the range of 390 to 420 nm, most preferably in the range of 400 to 410 nm. For example, the second wavelength may be in the visible spectral range as well, preferably in the range of 500 to 560 nm, more preferably in the range of 510 to 550 nm, most preferably in the range of 520 to 540 nm.

The illumination source may be selected from: an illumination source, which is at least partly connected to the object and/or is at least partly identical to the object; an illumination source which is designed to at least partly illuminate the object with a primary radiation. The light beam may be generated by a reflection of the primary radiation on the object and/or by light emission by the object itself, stimulated by the primary radiation. The spectral sensitivities of the longitudinal optical sensor may be covered by the spectral range of the illumination source.

The illumination source may comprise an artificial illumination source, in particular at least one laser source and/or at least one incandescent lamp and/or at least one semiconductor light source, for example, at least one light-emitting diode, in particular an organic and/or inorganic light-emitting diode. On account of their generally defined beam profiles and other properties of handleability, the use of at least one laser source as the illumination source is particularly preferred. For example, the illumination source may comprise a single laser source adapted to generate light beams having different wavelengths. Alternatively, in order to provide at least two light beams with different wavelengths, the illumination source may comprise two laser sources emitting light in different wavelengths. The illumination source may emit at least two laser beams. Each of the laser beams may be configured for the illumination of a single dot located on the surface of the object. By using at least one of the detectors according to the present invention, at least one item of information about the distance between the at least one dot and the scanning system may, thus, be generated. Hereby, preferably, the distance between the illumination system and the dots as generated by the illumination source may be determined, such as by employing the evaluation device as comprised by the at least one detector. Further, the illumination source, in particular the at least two laser sources, may be combined with at least one dichroic mirror and/or a dichroic mirror assembly.

Furthermore the detector may have at least one modulation device for modulating the illumination, in particular for a periodic modulation, in particular a periodic beam interrupting device. A modulation of the illumination should be understood to mean a process in which a total power of the illumination is varied, preferably periodically, in particular with one or a plurality of modulation frequencies. In particular, a periodic modulation can be effected between a maximum value and a minimum value of the total power of the illumination. The minimum value can be 0, but can also be >0, such that, by way of example, complete modulation does not have to be effected. The modulation can be effected for example in a beam path between the object and the optical sensor, for example by the at least one modulation device being arranged in said beam path. Alternatively or additionally, however, the modulation can also be effected in a beam path between an optional illumination source—described in even greater detail below—for illuminating the object and the object, for example by the at least one modulation device being arranged in said beam path. A combination of these possibilities is also conceivable. The at least one modulation device can comprise for example a beam chopper or some other type of periodic beam interrupting device, for example comprising at least one interrupter blade or interrupter wheel, which preferably rotates at constant speed and which can thus periodically interrupt the illumination. Alternatively or additionally, however, it is also possible to use one or a plurality of different types of modulation devices, for example modulation devices based on an electro-optical effect and/or an acousto-optical effect. Once again alternatively or additionally, the at least one optional illumination source itself can also be designed to generate a modulated illumination, for example by said illumination source itself having a modulated intensity and/or total power, for example a periodically modulated total power, and/or by said illumination source being embodied as a pulsed illumination source, for example as a pulsed laser. Thus, by way of example, the at least one modulation device can also be wholly or partly integrated into the illumination source. Various possibilities are conceivable.

Accordingly, the detector can be designed in particular to detect at least two longitudinal sensor signals in the case of different modulations, in particular at least two longitudinal sensor signals at respectively different modulation frequencies. The evaluation device can be designed to generate the geometrical information from the at least two longitudinal sensor signals. As described in WO 2012/110924 A1 and WO 2014/097181 A1, it is possible to resolve ambiguities and/or it is possible to take account of the fact that, for example, a total power of the illumination is generally unknown. By way of example, the detector can be designed to bring about a modulation of the illumination of the object and/or at least one sensor region of the detector, such as at least one sensor region of the at least one longitudinal optical sensor, with a frequency of 0.05 Hz to 1 MHz, such as 0.1 Hz to 10 kHz. As outlined above, for this purpose, the detector may comprise at least one modulation device, which may be integrated into the at least one optional illumination source and/or may be independent from the illumination source. Thus, at least one illumination source might, by itself, be adapted to generate the above-mentioned modulation of the illumination, and/or at least one independent modulation device may be present, such as at least one chopper and/or at least one device having a modulated transmissibility, such as at least one electro-optical device and/or at least one acousto-optical device.

For example, the light beam may be a modulated light beam. The detector may be designed to detect at least two longitudinal sensor signals in the case of different modulations, in particular at least two sensor signals at respectively different modulation frequencies, wherein the evaluation device may be designed to generate the at least one item of information on the longitudinal position of the object by evaluating the at least two longitudinal sensor signals. The longitudinal optical sensor may be furthermore designed in such a way that the longitudinal sensor signal, given the same total power of the illumination, is dependent on a modulation frequency of a modulation of the illumination. For example, the light beam may be a non-modulated continuous-wave light beam.

According to the present invention, it may be advantageous in order to apply at least one modulation frequency to the optical detector as described above. However, it may still be possible to directly determine the longitudinal sensor signal without applying a modulation frequency to the optical detector. As will be demonstrated below in more detail, an application of a modulation frequency may not be required under many relevant circumstances in order to acquire the desired longitudinal information about the object. As a result, the optical detector may, thus, not be required to comprise a modulation device which may further contribute to the simple and cost-effective setup of the spatial detector. As a further result, a spatial light modulator may be used in a time-multiplexing mode rather than a frequency-multiplexing mode or in a combination thereof.

The detector may comprise at least two longitudinal optical sensors, wherein each longitudinal optical sensor may be adapted to generate at least one longitudinal sensor signal. As an example, the sensor regions or the sensor surfaces of the longitudinal optical sensors may, thus, be oriented in parallel, wherein slight angular tolerances might be tolerable, such as angular tolerances of no more than 10°, preferably of no more than 5°. Herein, preferably all of the longitudinal optical sensors of the detector, which may, preferably, be arranged in form of a stack along the optical axis of the detector, may be transparent. Thus, the light beam may pass through a first transparent longitudinal optical sensor before impinging on the other longitudinal optical sensors, preferably subsequently. Thus, the light beam from the object may subsequently reach all longitudinal optical sensors present in the optical detector. Herein, the different longitudinal optical sensors may exhibit the same or different spectral sensitivities with respect to the incident light beam.

The detector according to the present invention may comprise a stack of longitudinal optical sensors as disclosed in WO 2014/097181 A1, particularly in combination with one or more transversal optical sensors. As an example, one or more transversal optical sensors may be located on a side of the stack of longitudinal optical sensors facing towards the object. Alternatively or additionally, one or more transversal optical sensors may be located on a side of the stack of longitudinal optical sensors facing away from the object. Again, additionally or alternatively, one or more transversal optical sensors may be interposed in between the longitudinal optical sensors of the stack. However, embodiments which may only comprise a single longitudinal optical sensor but no transversal optical sensor may still be possible, such as in a case wherein only determining the depth of the object may be desired.

Preferably, the detector further may comprise at least one transversal optical sensor, the transversal optical sensor may be adapted to determine a transversal position of the light beam traveling from the object to the detector, the transversal position being a position in at least one dimension perpendicular to an optical axis of the detector, the transversal optical sensor may be adapted to generate at least one transversal sensor signal, wherein the evaluation device may further be designed to generate at least one item of information on a transversal position of the object by evaluating the transversal sensor signal.

As used herein, the term “transversal optical sensor” generally refers to a device which is adapted to determine a transversal position of at least one light beam traveling from the object to the detector. With regard to the term position, reference may be made to the definition above. Thus, preferably, the transversal position may be or may comprise at least one coordinate in at least one dimension perpendicular to an optical axis of the detector. As an example, the transversal position may be a position of a light spot generated by the light beam in a plane perpendicular to the optical axis, such as on a light-sensitive sensor surface of the transversal optical sensor. As an example, the position in the plane may be given in Cartesian coordinates and/or polar coordinates. Other embodiments are feasible. For potential embodiments of the transversal optical sensor, reference may be made to WO 2014/097181 A1. However, other embodiments are feasible and will be outlined in further detail below.

The transversal optical sensor may provide at least one transversal sensor signal. Herein, the transversal sensor signal may generally be an arbitrary signal indicative of the transversal position. As an example, the transversal sensor signal may be or may comprise a digital and/or an analog signal. As an example, the transversal sensor signal may be or may comprise a voltage signal and/or a current signal. Additionally or alternatively, the transversal sensor signal may be or may comprise digital data. The transversal sensor signal may comprise a single signal value and/or a series of signal values. The transversal sensor signal may further comprise an arbitrary signal which may be derived by combining two or more individual signals, such as by averaging two or more signals and/or by forming a quotient of two or more signals.

In a first embodiment similar to the disclosure according to WO 2014/097181 A1, the transversal optical sensor may be a photo detector having at least one first electrode, at least one second electrode and at least one photovoltaic material, wherein the photovoltaic material may be embedded in between the first electrode and the second electrode. Thus, the transversal optical sensor may be or may comprise one or more photo detectors, such as one or more organic photodetectors and, most preferably, one or more dye-sensitized organic solar cells (DSCs, also referred to as dye solar cells), such as one or more solid dye-sensitized organic solar cells (s-DSCs). Thus, the detector may comprise one or more DSCs (such as one or more sDSCs) acting as the at least one transversal optical sensor and one or more DSCs (such as one or more sDSCs) acting as the at least one longitudinal optical sensor.

In contrast to this known embodiment, a preferred embodiment of the transversal optical sensor according to the present invention may comprise a layer of the photoconductive material, preferably an inorganic photoconductive material, such as one of the photoconductive materials as mentioned above and/or below, in particular a chalcogenide, preferably lead sulfide (PbS), lead selenide (PbSe), or a silicon-based photoconductor or another appropriate material. Herein, the layer of the photoconductive material may comprise a composition selected from a homogeneous, a crystalline, a polycrystalline, a microcrystalline, a nanocrystalline and/or an amorphous phase. Preferably, the layer of the photoconductive material may be embedded in between two layers of a transparent conducting oxide, preferably comprising indium tin oxide (ITO), fluorine doped tin oxide (FTO), or magnesium oxide (MgO). However, other material may be feasible, in particular according to the desired transparent spectral range.

Further, at least two electrodes may be present for recording the transversal optical signal. In a preferred embodiment, the at least two electrodes may actually be arranged in the form of at least two physical electrodes, wherein each physical electrode may comprise an electrically conducting material, preferably a metallically conducting material, more preferred a highly metallically conducting material such as copper, silver, gold or an alloy or a composition comprising these kinds of materials. Herein, each of the at least two physical electrodes may, preferably, be arranged in a manner that a direct electrical contact between the respective electrode and the photoconductive layer in the optical sensor may be achieved, particularly in order to acquire the longitudinal sensor signal with as little loss as possible, such as due to additional resistances in a transport path between the optical sensor and the evaluation device.

However, In a particular embodiment, one or more of the mentioned physical electrodes may be replaced at least partially by an electrically conducting beam, in particular a beam of electrically conducting particles, preferably electrons, which may be arranged in a manner that the electrically conducting beam impinges on the sensor region and, thereby, may be capable of generating a direct electrical contact between the respective electrically conducting beam and the photoconductive layer in the optical sensor. By providing this direct electrical contact to the photoconductive layer, the electrically conducting beam may, similarly, act as a means for transporting at least a part of the longitudinal sensor signal from the optical sensor to the evaluation device.

Preferably, at least one of the electrodes of the transversal optical sensor may be a split electrode having at least two partial electrodes, wherein the transversal optical sensor may have a sensor area, wherein the at least one transversal sensor signal may indicate an x- and/or a y-position of the incident light beam within the sensor area. The sensor area may be a surface of the photo detector facing towards the object. The sensor area preferably may be oriented perpendicular to the optical axis. Thus, the transversal sensor signal may indicate a position of a light spot generated by the light beam in a plane of the sensor area of the transversal optical sensor. Generally, as used herein, the term “partial electrode” refers to an electrode out of a plurality of electrodes, adapted for measuring at least one current and/or voltage signal, preferably independent from other partial electrodes. Thus, in case a plurality of partial electrodes is provided, the respective electrode is adapted to provide a plurality of electric potentials and/or electric currents and/or voltages via the at least two partial electrodes, which may be measured and/or used independently.

The transversal optical sensor may further be adapted to generate the transversal sensor signal in accordance with the electrical currents through the partial electrodes. Thus, a ratio of electric currents through two horizontal partial electrodes may be formed, thereby generating an x-coordinate, and/or a ratio of electric currents through to vertical partial electrodes may be formed, thereby generating a y-coordinate. The detector, preferably the transversal optical sensor and/or the evaluation device, may be adapted to derive the information on the transversal position of the object from at least one ratio of the currents through the partial electrodes. Other ways of generating position coordinates by comparing currents through the partial electrodes are feasible.

The partial electrodes may generally be defined in various ways, in order to determine a position of the light beam in the sensor area. Thus, two or more horizontal partial electrodes may be provided in order to determine a horizontal coordinate or x-coordinate, and two or more vertical partial electrodes may be provided in order to determine a vertical coordinate or y-coordinate. Thus, the partial electrodes may be provided at a rim of the sensor area, wherein an interior space of the sensor area remains free and may be covered by one or more additional electrode materials. As will be outlined in further detail below, the additional electrode material preferably may be a transparent additional electrode material, such as a transparent metal and/or a transparent conductive oxide and/or, most preferably, a transparent conductive polymer.

By using the transversal optical sensor, wherein one of the electrodes is a split electrode with three or more partial electrodes, currents through the partial electrodes may be dependent on a position of the light beam in the sensor area. This may generally be due to the fact that Ohmic losses or resistive losses may occur on the way from a location of generation of electrical charges due to the impinging light onto the partial electrodes. Thus, besides the partial electrodes, the split electrode may comprise one or more additional electrode materials connected to the partial electrodes, wherein the one or more additional electrode materials provide an electrical resistance. Thus, due to the Ohmic losses on the way from the location of generation of the electric charges to the partial electrodes through with the one or more additional electrode materials, the currents through the partial electrodes depend on the location of the generation of the electric charges and, thus, to the position of the light beam in the sensor area. For details of this principle of determining the position of the light beam in the sensor area, reference may be made to the preferred embodiments below and/or to the physical principles and device options as disclosed in WO 2014/097181 A1 and the respective references therein.

Accordingly, the transversal optical sensor may comprise the sensor area, which, preferably, may be transparent to the light beam travelling from the object to the detector. The transversal optical sensor may, therefore, be adapted to determine a transversal position of the light beam in one or more transversal directions, such as in the x- and/or in the y-direction. For this purpose, the at least one transversal optical sensor may further be adapted to generate at least one transversal sensor signal. Thus, the evaluation device may be designed to generate at least one item of information on a transversal position of the object by evaluating the transversal sensor signal of the longitudinal optical sensor.

In addition to the at least one longitudinal coordinate of the object, at least one transversal coordinate of the object may be determined. Thus, generally, the evaluation device may further be adapted to determine at least one transversal coordinate of the object by determining a position of the light beam on the at least one transversal optical sensor, which may be a pixelated, a segmented or a large-area transversal optical sensor, as further outlined also in WO 2014/097181 A1.

In addition, the detector may further comprise one or more additional elements such as one or more additional optical elements. Further, the detector may fully or partially be integrated into at least one housing. The detector specifically may comprise at least one transfer device, the transfer device being adapted to guide the light beam onto the optical sensor. The transfer device may comprise one or more of: at least one lens, preferably at least one focus-tunable lens; at least one beam deflection element, preferably at least one mirror; at least one beam splitting element, preferably at least one of a beam splitting cube or a beam splitting mirror; at least one multi-lens system.

As outlined above, the detector may further comprise one or more optical elements, such as one or more lenses and/or one or more refractive elements, one or more mirrors, one or more diaphragms or the like. These optical elements which are adapted to modify the light beam, such as by modifying one or more of a beam parameter of the light beam, a width of the light beam or a direction of the light beam, above and in the following, are also referred to as a “transfer element”. Thus, the detector may further comprise at least one transfer device, wherein the transfer device may be adapted to guide the light beam onto the optical sensor, such as by one or more of deflecting, focusing or defocusing the light beam. Specifically, the transfer device may comprise one or more lenses and/or one or more curved mirrors and/or one or more other types of refractive elements.

Most preferably, the light beam which emerges from the object may in this case travel first through the at least one transfer device and thereafter through the single transparent longitudinal optical sensor or a stack of the transparent longitudinal optical sensors until it may finally impinge on an imaging device. As used herein, the term “transfer device” refers to an optical element which may be configured to transfer the at least one light beam emerging from the object to optical sensors within the detector. Thus, the transfer device can be designed to feed light propagating from the object to the detector to the optical sensors, wherein this feeding can optionally be effected by means of imaging or else by means of non-imaging properties of the transfer device. In particular the transfer device can also be designed to collect the electromagnetic radiation before the latter is fed to the transversal and/or longitudinal optical sensor.

As outlined above, an unambiguous determination of at least one object may be possible by using a single longitudinal optical sensor. This simple configuration may enhance the available space behind the transfer device such that shorter focal lengths can be used compared to configurations using additional sensor devices. In addition, this configuration may allow flexibility in the optical setup, less spatial requirements and a reduction of expenses for optical elements and sensor.

In addition, the at least one transfer device may have imaging properties. Consequently, the transfer device comprises at least one imaging element, for example at least one lens and/or at least one curved mirror, since, in the case of such imaging elements, for example, a geometry of the illumination on the sensor region can be dependent on a relative positioning, for example a distance, between the transfer device and the object. As used herein, the transfer device may be designed in such a way that the electromagnetic radiation which emerges from the object is transferred completely to the sensor region, for example is focused completely onto the sensor region, in particular if the object is arranged in a visual range of the detector.

Generally, the detector may further comprise at least one imaging device, i.e. a device capable of acquiring at least one image. The imaging device can be embodied in various ways. Thus, the imaging device can be for example part of the detector in a detector housing. Alternatively or additionally, however, the imaging device can also be arranged outside the detector housing, for example as a separate imaging device. Alternatively or additionally, the imaging device can also be connected to the detector or even be part of the detector. In a preferred arrangement, the stack of the transparent longitudinal optical sensors and the imaging device are aligned along a common optical axis along which the light beam travels. Thus, it may be possible to locate an imaging device in the optical path of the light beam in a manner that the light beam travels through the stack of the transparent longitudinal optical sensors until it impinges on the imaging device. However, other arrangements are possible.

As used herein, an “imaging device” is generally understood as a device which can generate a one-dimensional, a two-dimensional, or a three-dimensional image of the object or of a part thereof. In particular, the detector, with or without the at least one optional imaging device, can be completely or partly used as a camera, such as an IR camera, or an RGB camera, i.e. a camera which is designed to deliver three basic colors which are designated as red, green, and blue, on three separate connections. Thus, as an example, the at least one imaging device may be or may comprise at least one imaging device selected from the group consisting of: a pixelated organic camera element, preferably a pixelated organic camera chip; a pixelated inorganic camera element, preferably a pixelated inorganic camera chip, more preferably a CCD- or CMOS-chip; a monochrome camera element, preferably a monochrome camera chip; a multicolor camera element, preferably a multicolor camera chip; a full-color camera element, preferably a full-color camera chip. The imaging device may be or may comprise at least one device selected from the group consisting of a monochrome imaging device, a multi-chrome imaging device and at least one full color imaging device. A multi-chrome imaging device and/or a full color imaging device may be generated by using filter techniques and/or by using intrinsic color sensitivity or other techniques, as the skilled person will recognize. Other embodiments of the imaging device are also possible.

The imaging device may be designed to image a plurality of partial regions of the object successively and/or simultaneously. By way of example, a partial region of the object can be a one-dimensional, a two-dimensional, or a three-dimensional region of the object which is delimited for example by a resolution limit of the imaging device and from which electromagnetic radiation emerges. In this context, imaging should be understood to mean that the electromagnetic radiation which emerges from the respective partial region of the object is fed into the imaging device, for example by means of the at least one optional transfer device of the detector. The electromagnetic rays can be generated by the object itself, for example in the form of a luminescent radiation. Alternatively or additionally, the at least one detector may comprise at least one illumination source for illuminating the object.

In particular, the imaging device can be designed to image sequentially, for example by means of a scanning method, in particular using at least one row scan and/or line scan, the plurality of partial regions sequentially. However, other embodiments are also possible, for example embodiments in which a plurality of partial regions is simultaneously imaged. The imaging device is designed to generate, during this imaging of the partial regions of the object, signals, preferably electronic signals, associated with the partial regions. The signal may be an analogue and/or a digital signal. By way of example, an electronic signal can be associated with each partial region. The electronic signals can accordingly be generated simultaneously or else in a temporally staggered manner. By way of example, during a row scan or line scan, it is possible to generate a sequence of electronic signals which correspond to the partial regions of the object, which are strung together in a line, for example. Further, the imaging device may comprise one or more signal processing devices, such as one or more filters and/or analogue-digital-converters for processing and/or preprocessing the electronic signals.

In a further aspect of the present invention, a detector system for determining a position of at least one object is disclosed. The detector system comprises at least one detector according to the present invention, such as according to one or more of the embodiments disclosed above or according to one or more of the embodiments disclosed in further detail below. The detector system further comprising at least one beacon device adapted to direct at least one light beam towards the detector, wherein the beacon device is at least one of attachable to the object, holdable by the object and integratable into the object.

Further details regarding the beacon device will be given below, including potential embodiments thereof. Thus, the at least one beacon device may be or may comprise at least one active beacon device, comprising one or more illumination sources such as one or more light sources like lasers, LEDs, light bulbs or the like. Additionally or alternatively, the at least one beacon device may be adapted to reflect one or more light beams towards the detector, such as by comprising one or more reflective elements. Further, the at least one beacon device may be or may comprise one or more scattering elements adapted for scattering a light beam. Therein, elastic or inelastic scattering may be used. In case the at least one beacon device is adapted to reflect and/or scatter a primary light beam towards the detector, the beacon device may be adapted to leave the spectral properties of the light beam unaffected or, alternatively, may be adapted to change the spectral properties of the light beam, such as by modifying a wavelength of the light beam.

The light emerging from the beacon devices can alternatively or additionally, from the option that said light originates in the respective beacon device itself, emerge from the illumination source and/or be excited by the illumination source. By way of example, the electromagnetic light emerging from the beacon device can be emitted by the beacon device itself and/or be reflected by the beacon device and/or be scattered by the beacon device before it is fed to the detector. In this case, emission and/or scattering of the electromagnetic radiation can be effected without spectral influencing of the electromagnetic radiation or with such influencing. Thus, by way of example, a wavelength shift can also occur during scattering, for example according to Stokes or Raman. Furthermore, emission of light can be excited, for example, by a primary illumination source, for example, by the object or a partial region of the object being excited to generate luminescence, in particular phosphorescence and/or fluorescence. Other emission processes are also possible, in principle. If a reflection occurs, then the object can have, for example, at least one reflective region, in particular at least one reflective surface. Said reflective surface can be a part of the object itself, but can also be, for example, a reflector which is connected or spatially coupled to the object, for example, a reflector plaque connected to the object. If at least one reflector is used, then it can in turn also be regarded as part of the detector which is connected to the object, for example, independently of other constituent parts of the detector.

The beacon devices and/or the at least one optional illumination source generally may emit light in at least one of: the ultraviolet spectral range, preferably in the range of 200 nm to 380 nm; the visible spectral range (380 nm to 780 nm); the infrared spectral range, preferably in the range of 780 nm to 3.0 micrometers. For thermal imaging applications, the target may emit light in the far infrared spectral range, preferably in the range of 3.0 micrometers to 20 micrometers. Most preferably, the at least one illumination source is adapted to emit light in the visible spectral range, preferably in the range of 500 nm to 780 nm, most preferably at 650 nm to 750 nm or at 690 nm to 700 nm.

The detector system may comprise at least two beacon devices, wherein at least one property of a light beam emitted by a first beacon device may be different from at least one property of a light beam emitted by a second beacon device. The light beam of the first beacon device and the light beam of the second beacon device may be emitted simultaneously or sequentially. For example, the first beacon device may stay switched on and provide a first light beam, while the second beacon device may provide the second light beam. The first light beam may have a first wavelength and the second light beam may have a second wavelength, wherein the property of the longitudinal optical sensor may be adjusted, in particular changes, by illumination with the first light beam and the second light beam. Illumination by the first light beam may result in adjusting the property of the longitudinal optical sensor such that the longitudinal optical sensor is in one of the neutral operational mode, the positive operational mode, or the negative operational mode. Illumination by the second light beam may result in adjusting the property of the longitudinal optical sensor such that the longitudinal optical sensor may be in another operational mode which is different from the operational mode during illumination by the first light beam. By switching between at least two wavelengths the property of the longitudinal optical sensor may be adjusted such that the longitudinal optical sensor is operable in at least two operational modes. As outlined above, the evaluation device may be designed to resolve ambiguities by considering at least two longitudinal sensor signals determined in at least two different operational modes. For example, the first wavelength may be a short wavelength compared to the second wavelength. In particular the first wavelength may be in the visible spectral range, preferably in the range of 380 to 450 nm, more preferably in the range of 390 to 420 nm, most preferably in the range of 400 to 410 nm. For example, the second wavelength may be in the visible spectral range as well, preferably in the range of 500 to 560 nm, more preferably in the range of 510 to 550 nm, most preferably in the range of 520 to 540 nm.

Further, the present invention discloses a method for an optical detection of at least one object, in particular using a detector, such as a detector according to the present invention, such as according to one or more of the embodiments referring to a detector as disclosed above or as disclosed in further detail below. Still, other types of detectors may be used.

The method comprises the following method steps, wherein the method steps may be performed in the given order or may be performed in a different order. Further, one or more additional method steps may be present which are not listed. Further, one, more than one or even all of the method steps may be performed repeatedly.

The method steps are as follows:
adjusting at least one property of the longitudinal optical sensor;
generating at least a first longitudinal sensor signal by using at least one longitudinal optical sensor, wherein the longitudinal sensor signal is dependent on an illumination of a sensor region of the longitudinal optical sensor by a light beam, wherein the longitudinal sensor signal, given the same total power of the illumination, is dependent on a beam cross-section of the light beam in the sensor region, wherein the longitudinal sensor signal is further dependent on at least one property of the longitudinal optical sensor; and
evaluating the longitudinal sensor signal by using at least one evaluation device and generating at least one item of information on a longitudinal position of the object.

For details, options and definitions, reference may be made to the detector as discussed above. Thus, specifically, as outlined above, the method may comprise using the detector according to the present invention, such as according to one or more of the embodiments given above or given in further detail below.

The property of the longitudinal optical sensor may be adjusted by a user and/or by an external influence. The longitudinal optical sensor signal may be evaluated unambiguously. The longitudinal optical sensor may be operated in at least two operational modes. At least two longitudinal sensor signals may be generated and evaluated, wherein a first longitudinal sensor signal may be evaluated in a first operational mode and a second longitudinal sensor signal may be evaluated in a second operational mode. The first longitudinal sensor signal may be generated in a first operational mode of the longitudinal optical sensor, such as an operational mode selected from the group consisting of: the neutral operational mode, the positive operational mode and the negative operational mode. The second longitudinal sensor signal may be generated in another operational mode of the longitudinal optical sensor as the first longitudinal sensor signal. Ambiguities may be resolved by comparing the first longitudinal sensor signal and the second longitudinal sensor signal.

The method may further comprise determining and/or classifying the operational mode of the longitudinal optical sensor. Thus, the method may comprise an analysis step, in which the longitudinal signal may be analyzed. In particular, curve characteristics and progression may be determined, more specifically a global extremum, e.g. a global minimum or a global maximum, may be determined. In case no extremum is observed or identified, the operational mode may be classified as neutral operational mode. For example, the amplitude of the longitudinal sensor signal may be determined.

The property of the longitudinal optical sensor may be adjusted repeatedly, e.g. two or three times. Thus, repeatedly switching between operational modes of the longitudinal optical sensor may be possible. For example, a switching from one of the positive operational mode or the negative operational mode to the neutral operational and a subsequent switching from the neutral mode to one of the positive operational mode or the negative operational mode may be performed.

At least two longitudinal sensor signals may be evaluated simultaneously. Ambiguities may be resolved by considering at least two longitudinal sensor signals determined in at least two different operational modes. Thus, at least two longitudinal sensor signals may be evaluated, wherein a first longitudinal sensor signal may be evaluated in a first operational mode and a second longitudinal sensor signal may be evaluated in a second operational mode. The method may furthermore comprise a comparison step, wherein the first longitudinal sensor signal and the second longitudinal sensor signal are compared. For example, in the comparison step, the longitudinal sensor signals may be normalized to generate the information on the longitudinal position of the object independent from an intensity of the light beam. For example, one of the first or second longitudinal sensor signals may be selected as reference signal. For example, the longitudinal sensor signal evaluated in the neutral operational mode may be selected as reference signal. For example, at least one of the longitudinal sensor signals evaluated in the positive operational mode or the negative operational mode may be selected as reference signal. By comparison of the selected reference signal and the other longitudinal signal, ambiguities may be eliminated. The longitudinal sensor signals may be compared, in order to gain information on the total power and/or intensity of the light beam and/or in order to normalize the longitudinal sensor signals and/or the at least one item of information on the longitudinal position of the object for the total power and/or total intensity of the light beam. For example, the longitudinal sensor signal may be normalized by division by the selected reference longitudinal sensor signal, in particular the longitudinal sensor signal evaluated in the neutral operational mode, thereby generating a normalized longitudinal optical sensor signal which, then, may be transformed by using the above-mentioned known relationship, into the at least one item of longitudinal information on the object. Thus, the transformation may be independent from the total power and/or intensity of the light beam. For example, at least one longitudinal sensor signal evaluated in one of the positive operational mode or the negative operational mode may be divided by the longitudinal sensor signal evaluated in the other one of the positive operational mode or the negative operational mode. Thus, by division, ambiguities may be eliminated.

In a further aspect of the present invention, a human-machine interface for exchanging at least one item of information between a user and a machine is proposed. The human-machine interface as proposed may make use of the fact that the above-mentioned detector in one or more of the embodiments mentioned above or as mentioned in further detail below may be used by one or more users for providing information and/or commands to a machine. Thus, preferably, the human-machine interface may be used for inputting control commands.

The human-machine interface comprises at least one detector according to the present invention, such as according to one or more of the embodiments disclosed above and/or according to one or more of the embodiments as disclosed in further detail below, wherein the human-machine interface is designed to generate at least one item of geometrical information of the user by means of the detector wherein the human-machine interface is designed to assign the geometrical information to at least one item of information, in particular to at least one control command.

In a further aspect of the present invention, an entertainment device for carrying out at least one entertainment function is disclosed. As used herein, an entertainment device is a device which may serve the purpose of leisure and/or entertainment of one or more users, in the following also referred to as one or more players. As an example, the entertainment device may serve the purpose of gaming, preferably computer gaming. Additionally or alternatively, the entertainment device may also be used for other purposes, such as for exercising, sports, physical therapy or motion tracking in general. Thus, the entertainment device may be implemented into a computer, a computer network or a computer system or may comprise a computer, a computer network or a computer system which runs one or more gaming software programs.

The entertainment device comprises at least one human-machine interface according to the present invention, such as according to one or more of the embodiments disclosed above and/or according to one or more of the embodiments disclosed below. The entertainment device is designed to enable at least one item of information to be input by a player by means of the human-machine interface. The at least one item of information may be transmitted to and/or may be used by a controller and/or a computer of the entertainment device.

In a further aspect of the present invention, a tracking system for tracking the position of at least one movable object is provided. As used herein, a tracking system is a device which is adapted to gather information on a series of past positions of the at least one object or at least one part of an object. Additionally, the tracking system may be adapted to provide information on at least one predicted future position of the at least one object or the at least one part of the object. The tracking system may have at least one track controller, which may fully or partially be embodied as an electronic device, preferably as at least one data processing device, more preferably as at least one computer or microcontroller. Again, the at least one track controller may comprise the at least one evaluation device and/or may be part of the at least one evaluation device and/or might fully or partially be identical to the at least one evaluation device.

The tracking system comprises at least one detector according to the present invention, such as at least one detector as disclosed in one or more of the embodiments listed above and/or as disclosed in one or more of the embodiments below. As outlined above, an unambiguous determination of at least one object may be possible by using a single longitudinal optical sensor. Thus, a simple and cost effective configuration of an x-y-z tracking system is possible. The tracking system further comprises at least one track controller. The tracking system may comprise one, two or more detectors, particularly two or more identical detectors, which allow for a reliable acquisition of depth information about the at least one object in an overlapping volume between the two or more detectors. The track controller is adapted to track a series of positions of the object, each position comprising at least one item of information on a position of the object at a specific point in time, such as by recording groups of data or data pairs, each group of data or data pair comprising at least one position information and at least one time information.

The tracking system may further comprise the at least one detector system according to the present invention. Thus, besides the at least one detector and the at least one evaluation device and the optional at least one beacon device, the tracking system may further comprise the object itself or a part of the object, such as at least one control element comprising the beacon devices or at least one beacon device, wherein the control element is directly or indirectly attachable to or integratable into the object to be tracked.

The tracking system may be adapted to initiate one or more actions of the tracking system itself and/or of one or more separate devices. For the latter purpose, the tracking system, preferably the track controller, may have one or more wireless and/or wire-bound interfaces and/or other types of control connections for initiating at least one action. Preferably, the at least one track controller may be adapted to initiate at least one action in accordance with at least one actual position of the object. As an example, the action may be selected from the group consisting of: a prediction of a future position of the object; pointing at least one device towards the object; pointing at least one device towards the detector; illuminating the object; illuminating the detector.

As an example of application of a tracking system, the tracking system may be used for continuously pointing at least one first object to at least one second object even though the first object and/or the second object might move. Potential examples, again, may be found in industrial applications, such as in robotics and/or for continuously working on an article even though the article is moving, such as during manufacturing in a manufacturing line or assembly line. Additionally or alternatively, the tracking system might be used for illumination purposes, such as for continuously illuminating the object by continuously pointing an illumination source to the object even though the object might be moving. Further applications might be found in communication systems, such as in order to continuously transmit information to a moving object by pointing a transmitter towards the moving object.

The tracking system may further comprise at least one beacon device connectable to the object. For a potential definition of the beacon device, reference may be made to WO 2014/097181 A1. The tracking system preferably is adapted such that the detector may generate an information on the position of the object of the at least one beacon device, in particular to generate the information on the position of the object which comprises a specific beacon device exhibiting a specific spectral sensitivity. Thus, more than one beacon exhibiting a different spectral sensitivity may be tracked by the detector of the present invention, preferably in a simultaneous manner. Herein, the beacon device may fully or partially be embodied as an active beacon device and/or as a passive beacon device. As an example, the beacon device may comprise at least one illumination source adapted to generate at least one light beam to be transmitted to the detector. Additionally or alternatively, the beacon device may comprise at least one reflector adapted to reflect light generated by an illumination source, thereby generating a reflected light beam to be transmitted to the detector.

In a further aspect of the present invention, a scanning system for determining at least one position of at least one object is provided. As used herein, the scanning system is a device which is adapted to emit at least one light beam being configured for an illumination of at least one dot located at at least one surface of the at least one object and for generating at least one item of information about the distance between the at least one dot and the scanning system. For the purpose of generating the at least one item of information about the distance between the at least one dot and the scanning system, the scanning system comprises at least one of the detectors according to the present invention, such as at least one of the detectors as disclosed in one or more of the embodiments listed above and/or as disclosed in one or more of the embodiments below.

Thus, the scanning system comprises at least one illumination source which is adapted to emit the at least one light beam being configured for the illumination of the at least one dot located at the at least one surface of the at least one object. As used herein, the term “dot” refers to a small area on a part of the surface of the object which may be selected, for example by a user of the scanning system, to be illuminated by the illumination source. Preferably, the dot may exhibit a size which may, on one hand, be as small as possible in order to allow the scanning system determining a value for the distance between the illumination source comprised by the scanning system and the part of the surface of the object on which the dot may be located as exactly as possible and which, on the other hand, may be as large as possible in order to allow the user of the scanning system or the scanning system itself, in particular by an automatic procedure, to detect a presence of the dot on the related part of the surface of the object.

For this purpose, the illumination source may comprise an artificial illumination source, in particular at least one laser source and/or at least one incandescent lamp and/or at least one semiconductor light source, for example, at least one light-emitting diode, in particular an organic and/or inorganic light-emitting diode. On account of their generally defined beam profiles and other properties of handleability, the use of at least one laser source as the illumination source is particularly preferred. Herein, the use of a single laser source may be preferred, in particular in a case in which it may be important to provide a compact scanning system that might be easily storable and transportable by the user. Preferably, the illumination source may comprise a single laser source adapted to generate light beams having different wavelengths. The illumination source may thus, preferably be a constituent part of the detector and may, therefore, in particular be integrated into the detector, such as into the housing of the detector. In a preferred embodiment, particularly the housing of the scanning system may comprise at least one display configured for providing distance-related information to the user, such as in an easy-to-read manner. In a further preferred embodiment, particularly the housing of the scanning system may, in addition, comprise at least one button which may be configured for operating at least one function related to the scanning system, such as for setting one or more operation modes. In a further preferred embodiment, particularly the housing of the scanning system may, in addition, comprise at least one fastening unit which may be configured for fastening the scanning system to a further surface, such as a rubber foot, a base plate or a wall holder, such comprising as magnetic material, in particular for increasing the accuracy of the distance measurement and/or the handleablity of the scanning system by the user.

In a particularly preferred embodiment, the illumination source of the scanning system may, thus, emit a single laser beam which may be configured for the illumination of a single dot located at the surface of the object. By using at least one of the detectors according to the present invention at least one item of information about the distance between the at least one dot and the scanning system may, thus, be generated. Hereby, preferably, the distance between the illumination system as comprised by the scanning system and the single dot as generated by the illumination source may be determined, such as by employing the evaluation device as comprised by the at least one detector. However, the scanning system may, further, comprise an additional evaluation system which may, particularly, be adapted for this purpose. Alternatively or in addition, a size of the scanning system, in particular of the housing of the scanning system, may be taken into account and, thus, the distance between a specific point on the housing of the scanning system, such as a front edge or a back edge of the housing, and the single dot may, alternatively, be determined.

Alternatively, in order to provide at least two light beams with different wavelengths, the illumination source may comprise two laser sources emitting light in different wavelengths. The illumination source may emit at least two laser beams. Each of the laser beams may be configured for the illumination of a single dot located on the surface of the object. Furthermore, the illumination source of the scanning system may emit two individual laser beams which may be configured for providing a respective angle, such as a right angle, between the directions of an emission of the beams, whereby two respective dots located at the surface of the same object or at two different surfaces at two separate objects may be illuminated. However, other values for the respective angle between the two individual laser beams may also be feasible. This feature may, in particular, be employed for indirect measuring functions, such as for deriving an indirect distance which may not be directly accessible, such as due to a presence of one or more obstacles between the scanning system and the dot or which may otherwise be hard to reach. By way of example, it may, thus, be feasible to determine a value for a height of an object by measuring two individual distances and deriving the height by using the Pythagoras formula. In particular for being able to keep a predefined level with respect to the object, the scanning system may, further, comprise at least one leveling unit, in particular an integrated bubble vial, which may be used for keeping the predefined level by the user.

As a further alternative, the illumination source of the scanning system may emit a plurality of individual laser beams, such as an array of laser beams which may exhibit a respective pitch, in particular a regular pitch, with respect to each other and which may be arranged in a manner in order to generate an array of dots located on the at least one surface of the at least one object. For this purpose, specially adapted optical elements, such as beam-splitting devices and mirrors, may be provided which may allow a generation of the described array of the laser beams.

Thus, the scanning system may provide a static arrangement of the one or more dots placed on the one or more surfaces of the one or more objects. Alternatively, illumination source of the scanning system, in particular the one or more laser beams, such as the above described array of the laser beams, may be configured for providing one or more light beams which may exhibit a varying intensity over time and/or which may be subject to an alternating direction of emission in a passage of time. Thus, the illumination source may be configured for scanning a part of the at least one surface of the at least one object as an image by using one or more light beams with alternating features as generated by the at least one illumination source of the scanning device. In particular, the scanning system may, thus, use at least one row scan and/or line scan, such as to scan the one or more surfaces of the one or more objects sequentially or simultaneously. As non-limiting examples, the scanning system may be used in safety laser scanners, e.g. in production environments, and/or in 3D-scanning devices as used for determining the shape of an object, such as in connection to 3D-printing, body scanning, quality control, in construction applications, e.g. as range meters, in logistics applications, e.g. for determining the size or volume of a parcel, in household applications, e.g. in robotic vacuum cleaners or lawn mowers, or in other kinds of applications which may include a scanning step.

In a further aspect of the present invention, a stereoscopic system for generating at least one single circular, three-dimensional image of at least one object is provided. As used herein, the stereoscopic system as disclosed above and/or below may comprise at least two of the FiP sensors as the optical sensors, wherein a first FiP sensor may be comprised in a tracking system, in particular in a tracking system according to the present invention, while a second FiP sensor may be comprised in a scanning system, in particular in a scanning system according to the present invention. Herein, the FiP sensors may, preferably, be arranged in separate beam paths in a collimated arrangement, such as by aligning the FiP sensors parallel to the optical axis and individually displaced perpendicular to the optical axis of the stereoscopic system. Thus, the FiP sensors may be able to generate or increase a perception of depth information, especially, by obtaining the depth information by a combination of the visual information derived from the individual FiP sensors which have overlapping fields of view and are, preferably, sensitive to an individual modulation frequency. For this purpose, the individual FiP sensors may, preferably, be spaced apart from each other by a distance from 1 cm to 100 cm, preferably from 10 cm to 25 cm, as determined in the direction perpendicular to the optical axis. In this preferred embodiment, the tracking system may, thus, be employed for determining a position of a modulated active target while the scanning system which is adapted to project one or more dots onto the one or more surfaces of the one or more objects may be used for generating at least one item of information about the distance between the at least one dot and the scanning system. In addition, the stereoscopic system may further comprise a separate position sensitive device being adapted for generating the item of information on the transversal position of the at least one object within the image as described elsewhere in this application.

Besides allowing stereoscopic vision, further particular advantages of the stereoscopic system which are primarily based on a use of more than one optical sensor may, in particular, include an increase of the total intensity and/or a lower detection threshold. Further, whereas in a conventional stereoscopic system which comprises at least two conventional position sensitive devices corresponding pixels in the respective images have to be determined by applying considerable computational effort, in the stereoscopic system according to the present invention which comprises at least two FiP sensors the corresponding pixels in the respective images being recorded by using the FiP sensors, wherein each of the FiP sensors may be operated with a different modulation frequency, may apparently be assigned with respect to each other. Thus, it may be emphasized that the stereoscopic system according to the present invention may allow generating the at least one item of information on the longitudinal position of the object as well as on the transversal position of the object with reduced effort.

For further details of the stereoscopic system, reference may be made to the description of the tracking system and the scanning system, respectively.

In a further aspect of the present invention, a camera for imaging at least one object is disclosed. The camera comprises at least one detector according to the present invention, such as disclosed in one or more of the embodiments given above or given in further detail below. Thus, the detector may be part of a photographic device, specifically of a digital camera. Specifically, the detector may be used for 3D photography, specifically for digital 3D photography. Thus, the detector may form a digital 3D camera or may be part of a digital 3D camera. As used herein, the term “photography” generally refers to the technology of acquiring image information of at least one object. As further used herein, a “camera” generally is a device adapted for performing photography. As further used herein, the term “digital photography” generally refers to the technology of acquiring image information of at least one object by using a plurality of light-sensitive elements adapted to generate electrical signals indicating an intensity of illumination, preferably digital electrical signals. As further used herein, the term “3D photography” generally refers to the technology of acquiring image information of at least one object in three spatial dimensions. Accordingly, a 3D camera is a device adapted for performing 3D photography. The camera generally may be adapted for acquiring a single image, such as a single 3D image, or may be adapted for acquiring a plurality of images, such as a sequence of images. Thus, the camera may also be a video camera adapted for video applications, such as for acquiring digital video sequences.

Thus, generally, the present invention further refers to a camera, specifically a digital camera, more specifically a 3D camera or digital 3D camera, for imaging at least one object. As outlined above, the term imaging, as used herein, generally refers to acquiring image information of at least one object. The camera comprises at least one detector according to the present invention. The camera, as outlined above, may be adapted for acquiring a single image or for acquiring a plurality of images, such as image sequence, preferably for acquiring digital video sequences. Thus, as an example, the camera may be or may comprise a video camera. In the latter case, the camera preferably comprises a data memory for storing the image sequence.

In a further aspect of the present invention, a use of the optical detector according to the present invention, such as disclosed in one or more of the embodiments discussed above and/or as disclosed in one or more of the embodiments given in further detail below, is disclosed, for a purpose of use, selected from the group consisting of: a position measurement in traffic technology; an entertainment application; a security application; a human-machine interface application; a tracking application; a scanning application; a photography application; a mapping application for generating maps of at least one space, such as at least one space selected from the group of a room, a building and a street; a mobile application; a webcam; an audio device; a dolby surround audio system; a computer peripheral device; a gaming application; an audio application; a camera or video application; a security application; a surveillance application; an automotive application; a transport application; a medical application; an agricultural application; an application connected to breeding plants or animals; a crop protection application; a sports application; a machine vision application; a vehicle application; an airplane application; a ship application; a spacecraft application; a building application; a construction application; a cartography application; a manufacturing application; a robotics application; a quality control application; a manufacturing application; a use in combination with a stereo camera; a quality control application; a use in combination with at least one time-of-flight detector; a use in combination with a structured illumination source; a use in combination with a stereo camera. Additionally or alternatively, applications in local and/or global positioning systems may be named, especially landmark-based positioning and/or indoor and/or outdoor navigation, specifically for use in cars or other vehicles (such as trains, motorcycles, bicycles, trucks for cargo transportation), robots or for use by pedestrians. Further, indoor positioning systems may be named as potential applications, such as for household applications and/or for robots used in manufacturing technology.

Further, the optical detector according to the present invention may be used in automatic door openers, such as in so-called smart sliding doors, such as a smart sliding door disclosed in JieCi Yang et al., Sensors 2013, 13(5), 5923-5936; doi:10.3390/s130505923. At least one optical detector according to the present invention may be used for detecting when a person or an object approaches the door, and the door may automatically open.

Further applications, as outlined above, may be global positioning systems, local positioning systems, indoor navigation systems or the like. Thus, the devices according to the present invention, i.e. one or more of the optical detector, the detector system, the human-machine interface, the entertainment device, the tracking system or the camera, specifically may be part of a local or global positioning system. Additionally or alternatively, the devices may be part of a visible light communication system. Other uses are feasible.

The devices according to the present invention, i.e. one or more of the optical detector, the detector system, the human-machine interface, the entertainment device, the tracking system, the scanning system, or the camera, further specifically may be used in combination with a local or global positioning system, such as for indoor or outdoor navigation. As an example, one or more devices according to the present invention may be combined with software/database-combinations such as Google Maps® or Google Street View®. Devices according to the present invention may further be used to analyze the distance to objects in the surrounding, the position of which can be found in the database. From the distance to the position of the known object, the local or global position of the user may be calculated.

Thus, the optical detector, the detector system, the human-machine interface, the entertainment device, the tracking system, the scanning system, or the camera according to the present invention (in the following simply referred to as “the devices according to the present invention” or—without restricting the present invention to the potential use of the FiP effect—“FiP-devices”) may be used for a plurality of application purposes, such as one or more of the purposes disclosed in further detail in the following.

Thus, firstly, the devices according to the present invention, also denominated as “FiP-devices” may be used in mobile phones, tablet computers, laptops, smart panels or other stationary or mobile computer or communication applications. Thus, the devices according to the present invention may be combined with at least one active light source, such as a light source emitting light in the visible range or infrared spectral range, in order to enhance performance. Thus, as an example, the devices according to the present invention may be used as cameras and/or sensors, such as in combination with mobile software for scanning environment, objects and living beings. The devices according to the present invention may even be combined with 2D cameras, such as conventional cameras, in order to increase imaging effects. The devices according to the present invention may further be used for surveillance and/or for recording purposes or as input devices to control mobile devices, especially in combination with gesture recognition. Thus, specifically, the devices according to the present invention acting as human-machine interfaces, also referred to as FiP input devices, may be used in mobile applications, such as for controlling other electronic devices or components via the mobile device, such as the mobile phone. As an example, the mobile application including at least one FiP-device may be used for controlling a television set, a game console, a music player or music device or other entertainment devices.

Further, the devices according to the present invention may be used in webcams or other peripheral devices for computing applications. Thus, as an example, the devices according to the present invention may be used in combination with software for imaging, recording, surveillance, scanning, or motion detection. As outlined in the context of the human-machine interface and/or the entertainment device, the devices according to the present invention are particularly useful for giving commands by facial expressions and/or body expressions. The devices according to the present invention can be combined with other input generating devices like e.g. mouse, keyboard, touchpad, etc. Further, the devices according to the present invention may be used in applications for gaming, such as by using a webcam. Further, the devices according to the present invention may be used in virtual training applications and/or video conferences. Further, the devices according to the present invention may be used to recognize or track hands, arms, or objects used in a virtual or augmented reality application, especially when wearing head mounted displays.

Further, the devices according to the present invention may be used in mobile audio devices, television devices and gaming devices, as partially explained above. Specifically, the devices according to the present invention may be used as controls or control devices for electronic devices, entertainment devices or the like. Further, the devices according to the present invention may be used for eye detection or eye tracking, such as in 2D- and 3D-display techniques, especially with transparent displays for augmented reality applications and/or for recognizing whether a display is being looked at and/or from which perspective a display is being looked at. Further, the devices according to the present invention may be used to explore a room, boundaries, obstacles, in connection with a virtual or augmented reality application, especially when wearing a head-mounted display.

Further, the devices according to the present invention may be used in or as digital cameras such as DSC cameras and/or in or as reflex cameras such as SLR cameras. For these applications, reference may be made to the use of the devices according to the present invention in mobile applications such as mobile phones, as disclosed above.

Further, the devices according to the present invention may be used for security and surveillance applications. Thus, as an example, FiP-sensors in general can be combined with one or more digital and/or analog electronics that will give a signal if an object is within or outside a predetermined area (e.g. for surveillance applications in banks or museums). Specifically, the devices according to the present invention may be used for optical encryption. FiP-based detection can be combined with other detection devices to complement wavelengths, such as with IR, x-ray, UV-VIS, radar or ultrasound detectors. The devices according to the present invention may further be combined with an active infrared light source to allow detection in low light surroundings. The devices according to the present invention such as FIP-based sensors are generally advantageous as compared to active detector systems, specifically since the devices according to the present invention avoid actively sending signals which may be detected by third parties, as is the case e.g. in radar applications, ultrasound applications, LIDAR or similar active detector device is. Thus, generally, the devices according to the present invention may be used for an unrecognized and undetectable tracking and/or scanning of moving objects. Additionally, the devices according to the present invention generally are less prone to manipulations and irritations as compared to conventional devices.

Further, given the ease and accuracy of 3D detection by using the devices according to the present invention, the devices according to the present invention generally may be used for facial, body and person recognition and identification. Therein, the devices according to the present invention may be combined with other detection means for identification or personalization purposes such as passwords, finger prints, iris detection, voice recognition or other means. Thus, generally, the devices according to the present invention may be used in security devices and other personalized applications.

Further, the devices according to the present invention may be used as 3D-barcode readers for product identification.

In addition to the security and surveillance applications mentioned above, the devices according to the present invention generally can be used for surveillance and monitoring of spaces and areas. Thus, the devices according to the present invention may be used for surveying and monitoring spaces and areas and, as an example, for triggering or executing alarms in case prohibited areas are violated. Thus, generally, the devices according to the present invention may be used for surveillance purposes in building surveillance or museums, optionally in combination with other types of sensors, such as in combination with motion or heat sensors, in combination with image intensifiers or image enhancement devices and/or photo-multipliers. Further, the devices according to the present invention may be used in public spaces or crowded spaces to detect potentially hazardous activities such as commitment of crimes such as theft in a parking lot or unattended objects such as unattended baggage in an airport.

Further, the devices according to the present invention may advantageously be applied in camera applications such as video and camcorder applications. Thus, the devices according to the present invention may be used for motion capture and 3D-movie recording. Therein, the devices according to the present invention generally provide a large number of advantages over conventional optical devices. Thus, the devices according to the present invention generally require a lower complexity with regard to optical components. Thus, as an example, the number of lenses may be reduced as compared to conventional optical devices, such as by providing the devices according to the present invention having one lens only. Due to the reduced complexity, very compact devices are possible, such as for mobile use. Conventional optical systems having two or more lenses with high quality generally are voluminous, such as due to the general need for voluminous beam-splitters. Further, the devices according to the present invention generally may be used for focus/autofocus devices, such as autofocus cameras. Further, the devices according to the present invention may also be used in optical microscopy, especially in confocal microscopy.

Further, the devices according to the present invention are applicable in the technical field of automotive technology and transport technology. Thus, as an example, the devices according to the present invention may be used as distance and surveillance sensors, such as for adaptive cruise control, emergency brake assist, lane departure warning, surround view, blind spot detection, rear cross traffic alert, and other automotive and traffic applications. Further, FiP-sensors can also be used for velocity and/or acceleration measurements, such as by analyzing a first and second time-derivative of position information gained by using the FiP-sensor. This feature generally may be applicable in automotive technology, transportation technology or general traffic technology. Applications in other fields of technology are feasible. A specific application in an indoor positioning system may be the detection of positioning of passengers in transportation, more specifically to electronically control the use of safety systems such as airbags. The use of an airbag may be prevented in case the passenger is located as such, that the use of an airbag will cause a severe injury.

In these or other applications, generally, the devices according to the present invention may be used as standalone devices or in combination with other sensor devices, such as in combination with radar and/or ultrasonic devices. Specifically, the devices according to the present invention may be used for autonomous driving and safety issues. Further, in these applications, the devices according to the present invention may be used in combination with infrared sensors, radar sensors, which are sonic sensors, two-dimensional cameras or other types of sensors. In these applications, the generally passive nature of typical the devices according to the present invention is advantageous. Thus, since the devices according to the present invention generally do not require emitting signals, the risk of interference of active sensor signals with other signal sources may be avoided. The devices according to the present invention specifically may be used in combination with recognition software, such as standard image recognition software. Thus, signals and data as provide by the devices according to the present invention typically are readily processable and, therefore, generally require lower calculation power than established stereovision systems such as LIDAR. Given the low space demand, the devices according to the present invention such as cameras using the FiP-effect may be placed at virtually any place in a vehicle, such as on a window screen, on a front hood, on bumpers, on lights, on mirrors or other places the like. Various detectors based on the FiP-effect can be combined, such as in order to allow autonomously driving vehicles or in order to increase the performance of active safety concepts. Thus, various FiP-based sensors may be combined with other FiP-based sensors and/or conventional sensors, such as in the windows like rear window, side window or front window, on the bumpers or on the lights.

A combination of at least one device according to the present invention, such as at least one detector according to the present invention, with one or more rain detection sensors is also possible. This is due to the fact that the devices according to the present invention generally are advantageous over conventional sensor techniques such as radar, specifically during heavy rain. A combination of at least one FiP-device with at least one conventional sensing technique such as radar may allow for a software to pick the right combination of signals according to the weather conditions.

Further, the devices according to the present invention generally may be used as break assist and/or parking assist and/or for speed measurements. Speed measurements can be integrated in the vehicle or may be used outside the vehicle, such as in order to measure the speed of other cars in traffic control. Further, the devices according to the present invention may be used for detecting free parking spaces in parking lots.

Further, the devices according to the present invention may be used is the fields of medical systems and sports. Thus, in the field of medical technology, surgery robotics, e.g. for use in endoscopes, may be named, since, as outlined above, the devices according to the present invention may require a low volume only and may be integrated into other devices. Specifically, the devices according to the present invention having one lens, at most, may be used for capturing 3D information in medical devices such as in endoscopes. Further, the devices according to the present invention may be combined with an appropriate monitoring software, in order to enable tracking and/or scanning and analysis of movements. This may allow an instant overlay of the position of a medical device, such as an endoscope or a scalpel, with results from medical imaging, such as obtained from magnetic resonance imaging, x-ray imaging, or ultrasound imaging. These applications are specifically valuable e.g. in medical treatments and long-distance diagnosis and tele-medicine. Further, The devices according to the present invention may be used in 3D-body scanning. Body scanning may be applied in a medical context, such as in dental surgery, plastic surgery, bariatric surgery, or cosmetic plastic surgery, or it may be applied in the context of medical diagnosis such as in the diagnosis of myofascial pain syndrome, cancer, body dysmorphic disorder, or further diseases. Body scanning may further be applied in the field of sports to assess ergonomic use or fit of sports equipment.

Body scanning may further be used in the context of clothing, such as to determine a suitable size and fitting of clothes. This technology may be used in the context of tailor-made clothes or in the context of ordering clothes or shoes from the internet or at a self-service shopping device such as a micro kiosk device or customer concierge device. Body scanning in the context of clothing is especially important for scanning fully dressed customers.

Further, the devices according to the present invention may be used in the context of people counting systems, such as to count the number of people in an elevator, a train, a bus, a car, or a plane, or to count the number of people passing a hallway, a door, an aisle, a retail store, a stadium, an entertainment venue, a museum, a library, a public location, a cinema, a theater, or the like. Further, the 3D-function in the people counting system may be used to obtain or estimate further information about the people that are counted such as height, weight, age, physical fitness, or the like. This information may be used for business intelligence metrics, and/or for further optimizing the locality where people may be counted to make it more attractive or safe. In a retail environment, the devices according to the present invention in the context of people counting may be used to recognize returning customers or cross shoppers, to assess shopping behavior, to assess the percentage of visitors that make purchases, to optimize staff shifts, or to monitor the costs of a shopping mall per visitor. Further, people counting systems may be used to assess customer pathways through a supermarket, shopping mall, or the like. Further, people counting systems may be used for anthropometric surveys. Further, the devices according to the present invention may be used in public transportation systems for automatically charging passengers depending on the length of transport. Further, the devices according to the present invention may be used in playgrounds for children, to recognize injured children or children engaged in dangerous activities, to allow additional interaction with playground toys, to ensure safe use of playground toys or the like.

Further the devices according to the present invention may be used in construction tools, such as a range meter that determines the distance to an object or to a wall, to assess whether a surface is planar, to align or objects or place objects in an ordered manner, or in inspection cameras for use in construction environments or the like.

Further, the devices according to the present invention may be applied in the field of sports and exercising, such as for training, remote instructions or competition purposes. Specifically, the devices according to the present invention may be applied in the field of dancing, aerobic, football, soccer, basketball, baseball, cricket, hockey, track and field, swimming, polo, handball, volleyball, rugby, sumo, judo, fencing, boxing etc. The devices according to the present invention can be used to detect the position of a ball, a bat, a sword, motions, etc., both in sports and in games, such as to monitor the game, support the referee or for judgment, specifically automatic judgment, of specific situations in sports, such as for judging whether a point or a goal actually was made.

The devices according to the present invention may further be used to support a practice of musical instruments, in particular remote lessons, for example lessons of string instruments, such as fiddles, violins, violas, celli, basses, harps, guitars, banjos, or ukuleles, keyboard instruments, such as pianos, organs, keyboards, harpsichords, harmoniums, or accordions, and/or percussion instruments, such as drums, timpani, marimbas, xylophones, vibraphones, bongos, congas, timbales, djembes or tablas.

The devices according to the present invention further may be used in rehabilitation and physiotherapy, in order to encourage training and/or in order to survey and correct movements. Therein, the devices according to the present invention may also be applied for distance diagnostics.

Further, the devices according to the present invention may be applied in the field of machine vision. Thus, one or more the devices according to the present invention may be used e.g. as a passive controlling unit for autonomous driving and or working of robots. In combination with moving robots, the devices according to the present invention may allow for autonomous movement and/or autonomous detection of failures in parts. The devices according to the present invention may also be used for manufacturing and safety surveillance, such as in order to avoid accidents including but not limited to collisions between robots, production parts and living beings. In robotics, the safe and direct interaction of humans and robots is often an issue, as robots may severely injure humans when they are not recognized. Devices according to the present invention may help robots to position objects and humans better and faster and allow a safe interaction. Given the passive nature of the devices according to the present invention, the devices according to the present invention may be advantageous over active devices and/or may be used complementary to existing solutions like radar, ultrasound, 2D cameras, IR detection etc. One particular advantage of the devices according to the present invention is the low likelihood of signal interference. Therefore multiple sensors can work at the same time in the same environment, without the risk of signal interference. Thus, the devices according to the present invention generally may be useful in highly automated production environments like e.g. but not limited to automotive, mining, steel, etc. The devices according to the present invention can also be used for quality control in production, e.g. in combination with other sensors like 2-D imaging, radar, ultrasound, IR etc., such as for quality control or other purposes. Further, the devices according to the present invention may be used for assessment of surface quality, such as for surveying the surface evenness of a product or the adherence to specified dimensions, from the range of micrometers to the range of meters. Other quality control applications are feasible. In a manufacturing environment, the devices according to the present invention are especially useful for processing natural products such as food or wood, with a complex 3-dimensional structure to avoid large amounts of waste material. Further, devices according to the present invention may be used to monitor the filling level of tanks, silos etc. Further, devices according to the present invention may be used to inspect complex products for missing parts, incomplete parts, loose parts, low quality parts, or the like, such as in automatic optical inspection, such as of printed circuit boards, inspection of assemblies or sub-assemblies, verification of engineered components, engine part inspections, wood quality inspection, label inspections, inspection of medical devices, inspection of product orientations, packaging inspections, food pack inspections, or the like.

In particular, the devices according to the present invention may be used in industrial quality control for identifying a property related to a manufacturing, packaging and distribution of products, in particular products which comprise a non-solid phase, particularly a fluid, such as a liquid, an emulsion, a gas, an aerosol, or a mixture thereof. These kinds products, which may, generally, be present in the chemistry, pharmaceutical, cosmetics, food and beverage industry as well as in other industrial areas, usually require a solid receptacle, which may be denoted as container, case, or bottle, wherein the receptacle may, preferably, be full or at least partially transparent. For sake of simplicity, in the following the term “bottle” may be used as a particular frequent example without intending any actual restriction, such as to the shape or the material of the receptacle. Consequently, the bottle which comprises the corresponding product may be characterized by a number of optical parameters which may be used for quality control, preferably by employing the optical detector or a system comprising the optical detector according to the present invention. Within this regard, the optical detector may, especially, be used for detecting one or more of the following optical parameters, which may comprise a filling level of the product within the bottle, a shape of the bottle, and a property of a label which may be attached to the bottle, in particular for comprising respective product information.

According to the state of the art, industrial quality control of this kind may usually be performed by using industrial cameras and subsequent image analysis in order to assess one or more of the mentioned optical parameters by recording and evaluating the respective image, whereby, since the answer as usually required by industrial quality control is a logic statement which may only attain the values TRUE (i.e. quality sufficient) or FALSE (i.e. quality insufficient), most of the acquired complex information with regard to the optical parameters may, in general, be discarded. By way of example, industrial cameras may be required for recording an image of a bottle, wherein the image may be assessed in the subsequent image analysis in order to detect a filling label, any possible deformation of the shape of the bottle and any errors and/or omissions comprised on the corresponding label as attached onto the bottle. In particular, since the deviations are usually rather small, different recorded images of the same product are all highly similar. Consequently, an image analysis which may employ simple tools, such as color levels or greyscales, is, generally, not sufficient. Further, conventional large-area image sensors yield little information, in particular due to their linear independence from the power of an incident light beam.

In contrast to this, the optical detector according to the present invention already comprises a setup with one or more optical sensors which exhibit a known dependency from the power of the incident light beam, which may, especially, result in a larger influence onto an image of the product with respect to the above mentioned optical parameters, such as the filling level of the product within the bottle, the shape of the bottle, and the at least one property of the label attached to the bottle. In particular, the optical sensors may, therefore, be adapted to directly condense complex information as comprised within the image of the product into one or more sensor signals, such as easily accessible current signals, thus avoiding the existing necessity of performing a sophisticated image analysis. Moreover, as already described above, the object of the present invention, which particularly refers to providing an autofocus device, wherein the sensor signal, such as a local maximum or minimum in the sensor current within a respective time interval, may indicate that the product under investigation is actually in focus, may further support the evaluation of the above mentioned optical parameters from the image of the corresponding product. Even in case an autofocus device may be used in cameras known from the state of the art, a lens system may, generally, only cover a limited range of distances, since the focus usually remains unchanged during the measurement. The measurement concept according to the present invention which is based on the use of a focus-tunable lens, however, may cover a much broader range, since varying the focus over a large range may be possible by employing the measurement concept as described herein. Furthermore, a use of specifically adapted transfer devices, illumination sources, such as devices configured for providing symmetry breaking and/or modulated illumination, modulation devices and/or sensor stacks may further enhance the reliability of the acquired information during the quality control.

Further, the devices according to the present invention may be used in the polls, vehicles, trains, airplanes, ships, spacecrafts and other traffic applications. Thus, besides the applications mentioned above in the context of traffic applications, passive tracking systems for aircrafts, vehicles and the like may be named. The use of at least one device according to the present invention, such as at least one detector according to the present invention, for monitoring the speed and/or the direction of moving objects is feasible. Specifically, the tracking of fast moving objects on land, sea and in the air including space may be named. The at least one FiP-detector specifically may be mounted on a still-standing and/or on a moving device. An output signal of the at least one FiP-device can be combined e.g. with a guiding mechanism for autonomous or guided movement of another object. Thus, applications for avoiding collisions or for enabling collisions between the tracked and the steered object are feasible. The devices according to the present invention generally are useful and advantageous due to the low calculation power required, the instant response and due to the passive nature of the detection system which generally is more difficult to detect and to disturb as compared to active systems, like e.g. radar. Further, the devices according to the present invention may be used to assist airplanes during landing or take-off procedure, especially in close proximity to the runway, where radar systems might not work accurately enough. Such landing or take-off assistance devices may be realized by beacon devices fixed to the ground such as the runway or fixed to the aircraft, or by an illumination and measurement devices fixed to either the aircraft or the ground, or both. The devices according to the present invention are particularly useful but not limited to e.g. speed control and air traffic control devices. Further, the devices according to the present invention may be used in automated tolling systems for road charges.

The devices according to the present invention generally may be used in passive applications. Passive applications include guidance for ships in harbors or in dangerous areas, and for aircrafts at landing or starting, wherein, fixed, known active targets may be used for precise guidance. The same can be used for vehicles driving in dangerous but well defined routes, such as mining vehicles. Further, the devices according to the present invention may be used to detect rapidly approaching objects, such as cars, trains, flying objects, animals, or the like. Further, the devices according to the present invention can be used for detecting velocities or accelerations of objects, or to predict the movement of an object by tracking one or more of its position, speed, and/or acceleration depending on time.

Further, as outlined above, the devices according to the present invention may be used in the field of gaming. Thus, the devices according to the present invention can be passive for use with multiple objects of the same or of different size, color, shape, etc., such as for movement detection in combination with software that incorporates the movement into its content. In particular, applications are feasible in implementing movements into graphical output. Further, applications of the devices according to the present invention for giving commands are feasible, such as by using one or more the devices according to the present invention for gesture or facial recognition. The devices according to the present invention may be combined with an active system in order to work under e.g. low light conditions or in other situations in which enhancement of the surrounding conditions is required. Additionally or alternatively, a combination of one or more of the devices according to the present invention with one or more IR or VIS light sources is possible, such as with a detection device based on the FiP effect. A combination of a FiP-based detector with special devices is also possible, which can be distinguished easily by the system and its software, e.g. and not limited to, a special color, shape, relative position to other devices, speed of movement, light, frequency used to modulate light sources on the device, surface properties, material used, reflection properties, transparency degree, absorption characteristics, etc. The device can, amongst other possibilities, resemble a stick, a racquet, a club, a gun, a knife, a wheel, a ring, a steering wheel, a bottle, a ball, a glass, a vase, a spoon, a fork, a cube, a dice, a figure, a puppet, a teddy, a beaker, a pedal, a switch, a glove, jewelry, a musical instrument or an auxiliary device for playing a musical instrument, such as a plectrum, a drumstick or the like. Other options are feasible.

Further, the devices according to the present invention may be used to detect and or track objects that emit light by themselves, such as due to high temperature or further light emission processes. The light emitting part may be an exhaust stream or the like. Further, the devices according to the present invention may be used to track reflecting objects and analyze the rotation or orientation of these objects.

Further, the devices according to the present invention generally may be used in the field of building, construction and cartography. Thus, generally, one or more devices according to the present invention may be used in order to measure and/or monitor environmental areas, e.g. countryside or buildings. Therein, one or more devices according to the present invention may be combined with other methods and devices or can be used solely in order to monitor progress and accuracy of building projects, changing objects, houses, etc. The devices according to the present invention can be used for generating three-dimensional models of scanned environments, in order to construct maps of rooms, streets, houses, communities or landscapes, both from ground or from air. Potential fields of application may be construction, interior architecture; indoor furniture placement; cartography, real estate management, land surveying or the like. As an example, the devices according to the present invention may be used in multicopters to monitor buildings, agricultural production environments such as fields, production plants, or landscapes, to support rescue operations, or to find or monitor one or more persons or animals, or the like. Further, devices according to the present invention may be used in production environment to measure the length of pipelines, tank volumes or further geometries related to a production plant or reactor.

Further, the devices according to the present invention may be used within an interconnecting network of home appliances such as CHAIN (Cedec Home Appliances Interoperating Network) to interconnect, automate, and control basic appliance-related services in a home, e.g. energy or load management, remote diagnostics, pet related appliances, child related appliances, child surveillance, appliances related surveillance, support or service to elderly or ill persons, home security and/or surveillance, remote control of appliance operation, and automatic maintenance support. Further, the devices according to the present invention may be used in heating or cooling systems such as an air-conditioning system, to locate which part of the room should be brought to a certain temperature or humidity, especially depending on the location of one or more persons. Further, the devices according to the present invention may be used in domestic robots, such as service or autonomous robots which may be used for household chores. The devices according to the present invention may be used for a number of different purposes, such as to avoid collisions or to map the environment, but also to identify a user, to personalize the robot's performance for a given user, for security purposes, or for gesture or facial recognition. As an example, the devices according to the present invention may be used in robotic vacuum cleaners, floor-washing robots, dry-sweeping robots, ironing robots for ironing clothes, animal litter robots, such as cat litter robots, security robots that detect intruders, robotic lawn mowers, automated pool cleaners, rain gutter cleaning robots, window washing robots, toy robots, telepresence robots, social robots providing company to less mobile people, or robots translating and speech to sign language or sign language to speech. In the context of less mobile people, such as elderly persons, household robots with the devices according to the present invention may be used for picking up objects, transporting objects, and interacting with the objects and the user in a safe way. Further the devices according to the present invention may be used in robots operating with hazardous materials or objects or in dangerous environments. As a non-limiting example, the devices according to the present invention may be used in robots or unmanned remote-controlled vehicles to operate with hazardous materials such as chemicals or radioactive materials especially after disasters, or with other hazardous or potentially hazardous objects such as mines, unexploded arms, or the like, or to operate in or to investigate insecure environments such as near burning objects or post disaster areas. Further, devices according to the present invention may be used in robots that assess health functions such as blood pressure, heart rate, temperature or the like.

Further, the devices according to the present invention may be used in household, mobile or entertainment devices, such as a refrigerator, a microwave, a washing machine, a window blind or shutter, a household alarm, an air condition devices, a heating device, a television, an audio device, a smart watch, a mobile phone, a phone, a dishwasher, a stove or the like, to detect the presence of a person, to monitor the contents or function of the device, or to interact with the person and/or share information about the person with further household, mobile or entertainment devices.

The devices according to the present invention may further be used in agriculture, for example to detect and sort out vermin, weeds, and/or infected crop plants, fully or in parts, wherein crop plants may be infected by fungus or insects. Further, for harvesting crops, the devices according to the present invention may be used to detect animals, such as deer, which may otherwise be harmed by harvesting devices. Further, the devices according to the present invention may be used to monitor the growth of plants in a field or greenhouse, in particular to adjust the amount of water or fertilizer or crop protection products for a given region in the field or greenhouse or even for a given plant. Further, in agricultural biotechnology, the devices according to the present invention may be used to monitor the size and shape of plants. Further, devices according to the present invention may be used in in farming or animal breeding environments such as to clean stables, in automated milk stanchions, in processing of weeds, hay, straw or the like, in obtaining eggs, in mowing crop, weeds or grass, in slaughtering animals, in plucking birds, or the like.

Further, the devices according to the present invention may be combined with sensors to detect chemicals or pollutants, electronic nose chips, microbe sensor chips to detect bacteria or viruses or the like, Geiger counters, tactile sensors, heat sensors, or the like. This may for example be used in constructing smart robots which are configured for handling dangerous or difficult tasks, such as in treating highly infectious patients, handling or removing highly dangerous substances, cleaning highly polluted areas, such as highly radioactive areas or chemical spills, or for pest control in agriculture.

Further, devices according to the present invention may be used in security application such as monitoring an area for suspicious objects, persons or behavior.

One or more devices according to the present invention can further be used for scanning of objects, such as in combination with CAD or similar software, such as for additive manufacturing and/or 3D printing. Therein, use may be made of the high dimensional accuracy of the devices according to the present invention, e.g. in x-, y- or z-direction or in any arbitrary combination of these directions, such as simultaneously. Further, the devices according to the present invention may be used in inspections and maintenance, such as pipeline inspection gauges. Further, in a production environment, the devices according to the present invention may be used to work with objects of a badly defined shape such as naturally grown objects, such as sorting vegetables or other natural products by shape or size or cutting products such as meat, fruit, bread, tofu, vegetables, eggs, or the like, or objects that are manufactured with a precision that is lower than the precision needed for a processing step. As a non-limiting example, devices according to the present invention may be used to sort out natural products of minor quality before or after a packaging step in a production environment.

Further the devices according to the present invention may be used in local navigation systems to allow autonomously or partially autonomously moving vehicles or multicopters or the like through an indoor or outdoor space. A non-limiting example may comprise vehicles moving through an automated storage for picking up objects and placing them at a different location. Indoor navigation may further be used in shopping malls, retail stores, museums, airports, or train stations, to track the location of mobile goods, mobile devices, baggage, customers or employees, or to supply users with a location specific information, such as the current position on a map, or information on goods sold, or the like. Further, the devices according to the present invention may be used in a manufacturing environment for picking up objects such as with a robot arm and placing them somewhere else, such as on a conveyor belt. As a nonlimiting example a robot arm in combination with one or more devices according to the present invention may pick up a screw from a box and screw it into a specific position of an object transported on a conveyor belt.

Further, the devices according to the present invention may be used to ensure safe driving of motorcycles such as driving assistance for motorcycles by monitoring speed, inclination, upcoming obstacles, unevenness of the road, or curves or the like. Further, the devices according to the present invention may be used in trains or trams to avoid collisions.

Further, the devices according to the present invention may be used in handheld devices, such as for scanning packaging or parcels to optimize a logistics process. Further, the devices according to the present invention may be used in further handheld devices such as personal shopping devices, RFID-readers, handheld devices for use in hospitals or health environments such as for medical use or to obtain, exchange or record patient or patient health related information, smart badges for retail or health environments, or the like.

As outlined above, the devices according to the present invention may further be used in manufacturing, quality control or identification applications, such as in product identification or size identification (such as for finding an optimal place or package, for reducing waste etc.). Further, the devices according to the present invention may be used in logistics applications. Thus, the devices according to the present invention may be used for optimized loading or packing containers or vehicles. Further, the devices according to the present invention may be used for monitoring or controlling of surface damages in the field of manufacturing, for monitoring or controlling rental objects such as rental vehicles, and/or for insurance applications, such as for assessment of damages. Further, the devices according to the present invention may be used for identifying a size of material, object or tools, such as for optimal material handling, especially in combination with robots. Further, the devices according to the present invention may be used for process control in production, e.g. for observing filling level of tanks. Further, the devices according to the present invention may be used for maintenance of production assets like, but not limited to, tanks, pipes, reactors, tools etc. Further, the devices according to the present invention may be used for analyzing 3D-quality marks. Further, the devices according to the present invention may be used in manufacturing tailor-made goods such as tooth inlays, dental braces, prosthesis, clothes or the like. The devices according to the present invention may also be combined with one or more 3D-printers for rapid prototyping, 3D-copying or the like. Further, the devices according to the present invention may be used for detecting the shape of one or more articles, such as for anti-product piracy and for anti-counterfeiting purposes.

Preferably, for further potential details of the optical detector, the method, the human-machine interface, the entertainment device, the tracking system, the camera and the various uses of the detector, in particular with regard to the transfer device, the longitudinal optical sensors, the evaluation device and, if applicable, to the transversal optical sensor, the modulation device, the illumination source and the imaging device, specifically with respect to the potential materials, setups and further details, reference may be made to one or more of WO 2012/110924 A1, US 2012/206336 A1, WO 2014/097181 A1, and US 2014/291480 A1, the full content of all of which is herewith included by reference.

The above-described detector, the method, the human-machine interface and the entertainment device and also the proposed uses have considerable advantages over the prior art. Thus, generally, a simple and, still, efficient detector for an accurate determining a position of at least one object in space may be provided. Therein, as an example, three-dimensional coordinates of an object or a part thereof may be determined in a fast and efficient way.

As compared to devices known in the art, the detector as proposed provides a high degree of simplicity, specifically with regard to an optical setup of the detector. Thus, a single longitudinal optical sensor is sufficient for an unambiguous position detection. This high degree of simplicity, is specifically suited for machine control, such as in human-machine interfaces and, more preferably, in gaming, tracking, scanning, and a stereoscopic vision. Thus, cost-efficient entertainment devices may be provided which may be used for a large number of gaming, entertaining, tracking, scanning, and stereoscopic vision purposes.

Summarizing, in the context of the present invention, the following embodiments are regarded as particularly preferred:

### Embodiment 1

A detector for an optical detection of at least one object, comprising:
at least one longitudinal optical sensor, wherein the longitudinal optical sensor has at least one sensor region, wherein the longitudinal optical sensor is designed to generate at least one longitudinal sensor signal in a manner dependent on an illumination of the sensor region by a light beam, wherein the longitudinal sensor signal, given the same total power of the illumination, is dependent on a beam cross-section of the light beam in the sensor region,
wherein the longitudinal sensor signal is further dependent on at least one property of the longitudinal optical sensor, wherein the property of the longitudinal optical sensor is adjustable; and
at least one evaluation device, wherein the evaluation device is designed to generate at least one item of information on a longitudinal position of the object by evaluating the longitudinal sensor signal of the longitudinal optical sensor.

### Embodiment 2

The detector according to the preceding embodiment, wherein the detector comprises at least one switching device configured to exert at least one external influence and/or at least one internal influence.

### Embodiment 3

The detector according to any one of the preceding embodiments, wherein the evaluation device is designed to evaluate the longitudinal optical sensor signal unambiguously.

### Embodiment 4

The detector according to any one of the preceding embodiments, wherein the longitudinal optical sensor is operable in at least two operational modes.

### Embodiment 5

The detector according to the preceding embodiment, wherein the detector is configured to enable switching and/or changing between operational modes by adjusting the property of the longitudinal optical sensor.

### Embodiment 6

The detector according to the preceding embodiment, wherein the switching device is configured to switch between at least two operational modes of the longitudinal optical sensor.

### Embodiment 7

The detector according to any one of the three preceding embodiments, wherein in at least one positive operational mode depending on the property of the longitudinal optical sensor, an amplitude of the longitudinal sensor signal increases with decreasing cross-section of a light spot generated by the light beam in the sensor region.

### Embodiment 8

The detector according to any one of the four preceding embodiments, wherein in at least one negative operational mode depending on the property of the longitudinal optical sensor, the amplitude of the longitudinal sensor signal decreases with decreasing cross-section of a light spot generated by the light beam in the sensor region.

### Embodiment 9

The detector according to any one of the five preceding embodiments, wherein in at least one neutral operational mode depending on the property of the longitudinal sensor signal, the amplitude of the longitudinal sensor signal is essentially independent from a variation of the cross-section of a light spot generated by the light beam in the sensor region.

### Embodiment 10

The detector according to the preceding embodiment, wherein the detector is configured to enable switching and/or changing between at least two operational modes of the group consisting of: the positive operational mode; the negative operational mode; and the neutral operational mode.

### Embodiment 11

The detector according to any one of the seven preceding embodiments, wherein the evaluation device is designed to determine the operational mode of the longitudinal optical sensor.

### Embodiment 12

The detector according to the preceding embodiment, wherein the evaluation device is designed to determine the longitudinal sensor signal of one or both of sequentially or simultaneously in at least two operational modes.

### Embodiment 13

The detector according to any one of the two preceding embodiments, wherein the evaluation device is designed to resolve ambiguities by considering at least two longitudinal sensor signals determined in at least two different operational modes.

### Embodiment 14

The detector according to any one of the preceding embodiments, wherein the property of the longitudinal optical sensor is electrically and/or optically adjustable.

### Embodiment 15

The detector according to any one of the preceding embodiments, wherein the detector comprises at least one biasing device.

### Embodiment 16

The detector according to the preceding embodiments, wherein the biasing device is configured to apply at least one bias voltage to the longitudinal optical sensor.

### Embodiment 17

The detector according to the preceding embodiment, wherein the property of the longitudinal optical sensor is adjustable by using different bias voltages.

### Embodiment 18

The detector according to any one of the three preceding embodiments, wherein the longitudinal optical sensor comprises at least one photodiode driven in a photoconductive mode, wherein the photoconductive mode refers to an electrical circuit employing a photodiode, wherein the at least one photodiode is comprised in a reverse biased mode, wherein the cathode of the photodiode is driven with a positive voltage with respect to the anode.

### Embodiment 19

The detector according to any one of the preceding embodiments, wherein the property of the longitudinal optical sensor is adjustable, in particular changeable, by at least one property of the light beam.

### Embodiment 20

The detector according to the preceding claim, wherein the property of the light beam is a wavelength and/or a modulation frequency.

### Embodiment 21

The detector according to any one of the preceding embodiments, furthermore comprising at least one illumination source.

### Embodiment 22

The detector according to the preceding embodiment, wherein the illumination source is adapted to emit light in at least two different wavelengths.

### Embodiment 23

The detector according to any one of the two preceding embodiments, wherein the illumination source is configured to switch between emitting light in at least one first wavelength and emitting light in at least one second wavelength.

### Embodiment 24

The detector according to any one of the three preceding embodiments, wherein the illumination source is designed to emit at least two light beams, wherein at least one property of a first light beam is different from at least one property of a second light beam, wherein the property is selected from the group consisting of at least one wavelength, at least one modulation frequency, at least one intensity, at least one size of at least one light source.

### Embodiment 25

The detector according to the preceding embodiment, wherein the first light beam and the second light beam are emitted simultaneously or sequentially.

### Embodiment 26

The detector according to any one of the two preceding embodiments, wherein the first light beam has a first wavelength and the second light beam has a second wavelength, wherein the property of the longitudinal optical sensor is adjusted, in particular changes, by illumination with the first light beam and the second light beam.

### Embodiment 27

The detector according to any one of the six preceding embodiments, wherein the illumination source is selected from: an illumination source, which is at least partly connected to the object and/or is at least partly identical to the object; an illumination source which is designed to at least partly illuminate the object with a primary radiation.

### Embodiment 28

The detector according to the preceding embodiments, wherein the light beam is generated by a reflection of the primary radiation on the object and/or by light emission by the object itself, stimulated by the primary radiation.

### Embodiment 29

The detector according to the preceding embodiment, wherein the spectral sensitivities of the longitudinal optical sensor are covered by the spectral range of the illumination source.

### Embodiment 30

The detector according to any one of the preceding embodiments, wherein the detector furthermore has at least one modulation device for modulating the illumination.

### Embodiment 31

The detector according to any one of the preceding embodiments, wherein the light beam is a modulated light beam.

### Embodiment 32

The detector according to the preceding embodiment, wherein the detector is designed to detect at least two longitudinal sensor signals in the case of different modulations, in particular at least two sensor signals at respectively different modulation frequencies, wherein the evaluation device is designed to generate the at least one item of information on the longitudinal position of the object by evaluating the at least two longitudinal sensor signals.

### Embodiment 33

The detector according to any of the preceding embodiments, wherein the longitudinal optical sensor is furthermore designed in such a way that the longitudinal sensor signal, given the same total power of the illumination, is dependent on a modulation frequency of a modulation of the illumination.

### Embodiment 34

The detector according to the preceding embodiment, wherein the light beam is a non-modulated continuous-wave light beam.

### Embodiment 35

The detector according to any of the preceding embodiments, wherein the evaluation device is adapted to normalize the longitudinal sensor signals and to generate the information on the longitudinal position of the object independent from an intensity of the light beam.

### Embodiment 36

The detector according to any of the preceding embodiments, wherein the evaluation device is adapted to generate the at least one item of information on the longitudinal position of the object by determining a diameter of the light beam from the at least one longitudinal sensor signal.

### Embodiment 37

The detector according to the preceding embodiment, wherein the evaluation device is adapted to compare the diameter of the light beam with known beam properties of the light beam in order to determine the at least one item of information on the longitudinal position of the object, preferably from a known dependency of a beam diameter of the light beam on at least one propagation coordinate in a direction of propagation of the light beam and/or from a known Gaussian profile of the light beam.

### Embodiment 38

The detector according to any one of the preceding embodiments, wherein the sensor region comprises at least one material capable of sustaining an electrical current, wherein at least one property of the material, given the same total power of the illumination, is dependent on the beam cross-section of the light beam in the sensor region, wherein the longitudinal sensor signal is dependent on the at least one property.

### Embodiment 39

The detector according to the preceding embodiment, wherein the at least one property of the material is an electrical conductivity of the material or another material property.

### Embodiment 40

The detector according to any one of the two preceding embodiments, wherein the material capable of sustaining an electrical current comprises one or more of amorphous silicon, an alloy comprising amorphous silicon, microcrystalline silicon or cadmium telluride (CdTe).

### Embodiment 41

The detector according to the preceding embodiment, wherein the alloy comprising amorphous silicon is an amorphous alloy comprising silicon and carbon or an amorphous alloy comprising silicon and germanium.

### Embodiment 42

The detector according to any one of the two preceding embodiments, wherein the amorphous silicon is passivated by using hydrogen.

### Embodiment 43

The detector according to any one of the three preceding embodiments, wherein the longitudinal optical sensor is a photo detector having at least one first electrode, at least one second electrode, and the amorphous silicon, the alloy comprising amorphous silicon, or the microcrystalline silicon located between the first electrode and the second electrode, wherein at least one of the first electrode and the second electrode is a transparent electrode.

### Embodiment 44

The detector according to the preceding embodiment, wherein the transparent electrode comprises a transparent conducting oxide (TCO), in particular indium tin oxide (ITO).

### Embodiment 45

The detector according to any one of the two preceding embodiments, wherein the amorphous silicon, the alloy comprising amorphous silicon, or the microcrystalline silicon located between the first electrode and the second electrode is arranged as a PIN diode, wherein the PIN diode comprises an i-type semiconductor layer located between an n-type semiconductor layer and a p-type semiconductor layer.

### Embodiment 46

The detector according to the preceding embodiment, wherein the i-type semiconductor layer comprises amorphous silicon and exhibits a thickness which exceeds the thickness of each of the n-type semiconductor layer and the p-type semiconductor layer, in particular by a factor of at least 2, preferably of at least 5, more preferred of at least 10.

### Embodiment 47

The detector according to the pre-preceding embodiment, wherein the p-type semiconductor layer comprises an alloy of silicon and carbon, and exhibits a thickness from 2 nm to 20 nm, preferably from 4 nm to 10 nm.

### Embodiment 48

The detector according to the preceding embodiment, wherein the i-type semiconductor layer comprises an alloy of silicon and carbon, and exhibits a thickness from 2 nm to 20 nm, preferably from 4 nm to 10 nm.

### Embodiment 49

The detector according to any one of the preceding embodiments, further comprising at least one transversal optical sensor, the transversal optical sensor being adapted to determine a transversal position of the light beam traveling from the object to the detector, the transversal position being a position in at least one dimension perpendicular to an optical axis of the detector, the transversal optical sensor being adapted to generate at least one transversal sensor signal, wherein the evaluation device is further designed to generate at least one item of information on a transversal position of the object by evaluating the transversal sensor signal.

### Embodiment 50

The detector according to the preceding embodiment, wherein the transversal optical sensor is a photo detector having at least one first electrode, at least one second electrode and at least one photoconductive material embedded in between two separate layers of a transparent conductive oxide, wherein the transversal optical sensor has a sensor area, wherein the first electrode and the second electrode are applied to different locations of one of the layers of the transparent conductive oxide, wherein the at least one transversal sensor signal indicates a position of the light beam in the sensor area.

### Embodiment 51

The detector according to any one of the preceding embodiments, wherein the detector comprises at least one transfer device, such as an optical lens, in particular one or more refractive lenses, particularly converging thin refractive lenses, such as convex or biconvex thin lenses, and/or one or more convex mirrors, which further are arranged along a common optical axis.

### Embodiment 52

The detector according to any one of the preceding embodiments, wherein the detector comprises at least one imaging device.

### Embodiment 53

A detector system for determining a position of at least one object the detector system comprising at least one detector according to any one of the preceding embodiments, the detector system further comprising at least one beacon device adapted to direct at least one light beam towards the detector, wherein the beacon device is at least one of attachable to the object, holdable by the object and integratable into the object.

### Embodiment 54

The detector system according to the preceding embodiment, wherein the detector system comprises at least two beacon devices, wherein at least one property of a light beam emitted by a first beacon device is different from at least one property of a light beam emitted by a second beacon device.

### Embodiment 55

The detector system according to the any one of the two preceding embodiments, wherein the light beam of the first beacon device and the light beam of the second beacon device are emitted simultaneously or sequentially.

### Embodiment 56

A method for an optical detection of at least one object, in particular using a detector according to any of the preceding embodiments relating to a detector, comprising the following steps:
adjusting at least one property of the longitudinal optical sensor;
generating at least one longitudinal sensor signal by using at least one longitudinal optical sensor, wherein the longitudinal sensor signal is dependent on an illumination of a sensor region of the longitudinal optical sensor by a light beam, wherein the longitudinal sensor signal, given the same total power of the illumination, is dependent on a beam cross-section of the light beam in the sensor region, wherein the longitudinal sensor signal is further dependent on at least one property of the longitudinal optical sensor; and
evaluating the longitudinal sensor signals by using at least one evaluation device and generating at least one item of information on a longitudinal position of the object.

### Embodiment 57

The method according to the preceding embodiment, wherein the property of the longitudinal optical sensor is adjusted by a user and/or by an external influence.

### Embodiment 58

The method according to any one of the two preceding embodiments, wherein the longitudinal optical sensor signal is evaluated unambiguously.

### Embodiment 59

The method according to any one of the preceding embodiments referring to a method, wherein the longitudinal optical sensor is operated in at least two operational modes.

### Embodiment 60

The method according to the preceding embodiment, wherein at least two longitudinal sensor signals are evaluated, wherein a first longitudinal sensor signal is evaluated in a first operational mode and a second longitudinal sensor signal is evaluated in a second operational mode.

### Embodiment 61

The method according to the preceding embodiment, wherein ambiguities are resolved by comparing the first longitudinal sensor signal and the second longitudinal sensor signal.

### Embodiment 62

A human-machine interface for exchanging at least one item of information between a user and a machine, wherein the human-machine interface comprises at least one detector system according to any one of the preceding embodiments referring to a detector system, wherein the at least one beacon device is adapted to be at least one of directly or indirectly attached to the user and held by the user, wherein the human-machine interface is designed to determine at least one position of the user by means of the detector system, wherein the human-machine interface is designed to assign to the position at least one item of information.

### Embodiment 63

An entertainment device for carrying out at least one entertainment function, wherein the entertainment device comprises at least one human-machine interface according to the preceding claim, wherein the entertainment device is designed to enable at least one item of information to be input by a player by means of the human-machine interface, wherein the entertainment device is designed to vary the entertainment function in accordance with the information.

### Embodiment 64

A tracking system for tracking a position of at least one movable object, the tracking system comprising at least one detector system according to any one of the preceding embodiments referring to a detector system, the tracking system further comprising at least one track controller, wherein the track controller is adapted to track a series of positions of the object at specific points in time.

### Embodiment 65

A scanning system for determining at least one position of at least one object, the scanning system comprising at least one detector according to any of the preceding embodiments referring to a detector, the scanning system further comprising at least one illumination source adapted to emit at least one light beam configured for an illumination of at least one dot located on at least one surface of the at least one object, wherein the scanning system is designed to generate at least one item of information about the distance between the at least one dot and the scanning system by using the at least one detector.

### Embodiment 66

A stereoscopic system comprising at least one tracking system according to the pre-preceding embodiment and at least one scanning system according to the preceding embodiment, wherein the tracking system and the scanning system each comprise at least one longitudinal optical sensor which are located in a collimated arrangement in a manner that they are aligned in an orientation parallel to the optical axis of the stereoscopic system and exhibit an individual displacement in the orientation perpendicular to the optical axis of the stereoscopic system.

### Embodiment 67

A camera for imaging at least one object, the camera comprising at least one detector according to any one of the preceding embodiments referring to a detector.

### Embodiment 68

A use of the detector according to any one of the preceding embodiments relating to a detector, for a purpose of use, selected from the group consisting of: a position measurement in traffic technology; an entertainment application; a security application; a surveillance application; a safety application; a human-machine interface application; a tracking application; a photography application; a use in combination with at least one time-of-flight detector; a use in combination with a structured light source; a use in combination with a stereo camera; a machine vision application; a robotics application; a quality control application; a manufacturing application; a use in combination with a structured illumination source; a use in combination with a stereo camera.

### BRIEF DESCRIPTION OF THE FIGURES

Further optional details and features of the invention are evident from the description of preferred exemplary embodiments which follows in conjunction with the dependent claims. In this context, the particular features may be implemented alone or with several in combination. The invention is not restricted to the exemplary embodiments. The exemplary embodiments are shown schematically in the figures. Identical reference numerals in the individual figures refer to identical elements or elements with identical function, or elements which correspond to one another with regard to their functions.

Specifically, in the figures:

FIG. 1 shows an exemplary embodiment of a detector according to the present invention;

FIG. 2 shows an exemplary schematic setup of the detector of FIG. 1;

FIG. 3 shows an exemplary schematic setup of a method for an optical detection of at least one object according to the present invention;

FIGS. 4A and 4B show experimental results demonstrating the dependency of a longitudinal sensor signal on wavelength; and

FIG. 5 shows an exemplary embodiment of a detector, a detector system, a human-machine interface, an entertainment device and a tracking system according to the present invention.

### EXEMPLARY EMBODIMENTS

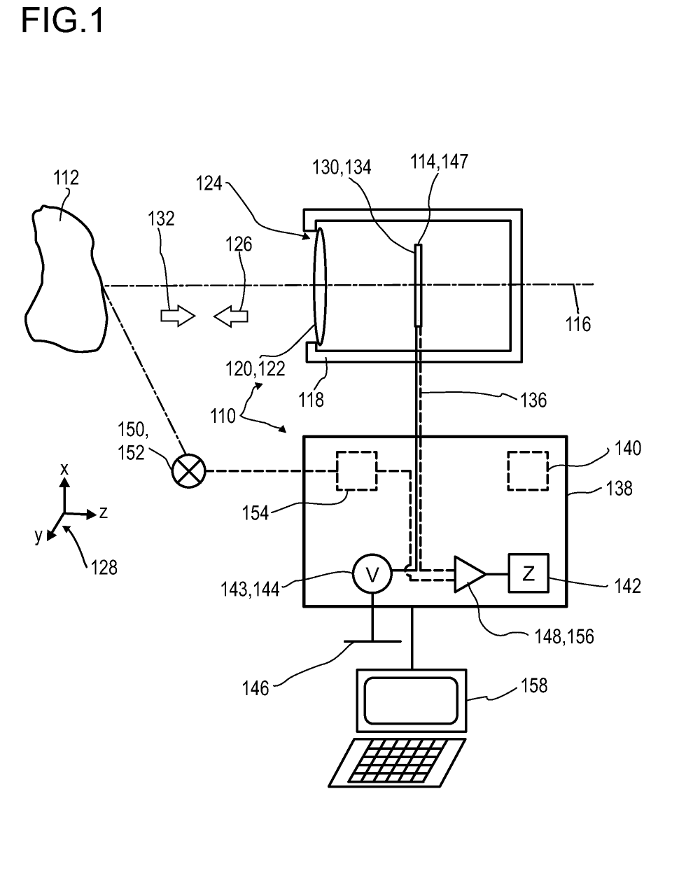

FIG. 1 illustrates, in a highly schematic fashion, an exemplary embodiment of an optical detector 110 according to the present invention, for determining a position of at least one object 112. However, other embodiments are feasible. The optical detector 110 comprises at least one longitudinal optical sensor 114, which, in this particular embodiment, is arranged along an optical axis 116 of the detector 110. Specifically, the optical axis 116 may be an axis of symmetry and/or rotation of the setup of the optical sensor 114. The optical sensor 114 may be located inside a housing 118 of the detector 110. Further, at least one transfer device 120 may be comprised, preferably a refractive lens 122. An opening 124 in the housing 118, which may, particularly, be located concentrically with regard to the optical axis 116, preferably defines a direction of view 126 of the detector 110. A coordinate system 128 may be defined, in which a direction parallel or antiparallel to the optical axis 116 is defined as a longitudinal direction, whereas directions perpendicular to the optical axis 116 may be defined as transversal directions. In the coordinate system 128, symbolically depicted in FIG. 1, a longitudinal direction is denoted by z and transversal directions are denoted by x and y, respectively. However, other types of coordinate systems 128 are feasible.

Further, the longitudinal optical sensor 114 is designed to generate at least one longitudinal sensor signal in a manner dependent on an illumination of a sensor region 130 by a light beam 132. Thus, according to the FiP effect, the longitudinal sensor signal, given the same total power of the illumination, is dependent on a beam cross-section of the light beam 132 in the respective sensor region 130, as will be outlined in further detail below.

According to the present invention, the sensor region 130 may comprise at least one photoconductive material 134, in particular amorphous silicon, an alloy comprising amorphous silicon, or microcrystalline silicon. As a result of the use of the photoconductive material 134 in the sensor region 130, an electrical conductivity of the sensor region 130, given the same total power of the illumination, may depend on the beam cross-section of the light beam 132 in the sensor region 130. Consequently, the resulting longitudinal sensor signal as provided by the longitudinal optical sensor 114 upon impingement by the light beam 132 may depend on the electrical conductivity of the photoconductive material 134 in the sensor region 130 and thus allows determining the beam cross-section of the light beam 132 in the sensor region 130. Via a longitudinal signal lead 136, the longitudinal sensor signal may be transmitted to an evaluation device 138, which will be explained in further detail below. Preferably, the sensor region 130 of the longitudinal optical sensor 114 may be transparent or translucent with respect to the light beam 132 travelling from the object 112 to the detector 110. However, this feature may not be required since the sensor region 130 of longitudinal optical sensor 114 may also be intransparent.

The longitudinal sensor signal is further dependent on at least one property of the longitudinal optical sensor 114. The property of the longitudinal optical sensor 114 is adjustable. The detector may comprise at least one switching device 140 configured to exert at least one external influence and/or at least one internal influence. For example, the switching device 140 may be part of the evaluation device 138. The property of the longitudinal optical sensor 114 may be electrically and/or optically adjustable. The property of the longitudinal optical sensor 114 may be electrically adjustable by the biasing device 140.

The evaluation device 138 is, generally, designed to generate at least one item of information on a position of the object 112 by evaluating the sensor signal of the longitudinal optical sensor 114. For this purpose, the evaluation device 138 may comprise one or more electronic devices and/or one or more software components, in order to evaluate the sensor signals, which are symbolically denoted by a longitudinal evaluation unit 142 (denoted by “z”). As will be explained below in more detail, the evaluation device 138 may be adapted to determine the at least one item of information on the longitudinal position of the object 112 by comparing more than one longitudinal sensor signals of the longitudinal optical sensor 114.

The longitudinal optical sensor 114 may be operable in at least two operational modes. The operational mode may depend on the adjustable property of the longitudinal optical sensor 114. In case the light beam 132 impinges on the longitudinal optical sensor 114, the longitudinal optical sensor 114 in a first operational mode may generate a different longitudinal sensor signal compared to the longitudinal sensor signal generated in a second operational mode. The longitudinal optical sensor 114 may be configured for optical detection of the at least one object in at least two operational modes. The detector 110 may be configured to enable switching and/or changing between operational modes by adjusting the property of the longitudinal optical sensor 114. Specifically, the switching device 140 may be configured to switch between at least two operational modes of the longitudinal optical sensor 114. The switching device 140 may be configured to switch between operational states of the FiP-based detector, in particular between an operational state, wherein the FiP may be configured to perform a FiP-based detection, and a state wherein the FiP detector is configured to perform a detection wherein the longitudinal sensor signal is essentially independent from the beam cross-section of the light beam 132 in the sensor region 130 of the at least one longitudinal optical sensor 114.

In at least one positive operational mode depending on the property of the longitudinal optical sensor 114 an amplitude of the longitudinal sensor signal may increase with decreasing cross-section of a light spot generated by the light beam 132 in the sensor region 130. The at least one longitudinal sensor signal, given the same total power of the illumination by the light beam 132, is dependent on a beam cross-section of the light beam 132 in the sensor region 130 of the at least one longitudinal optical sensor 114. In the positive operational mode, the longitudinal sensor signal, given the same total power, may exhibit at least one pronounced maximum for one or a plurality of focusings and/or for one or a plurality of specific sizes of the light spot on the sensor region 130 or within the sensor region 130.

In at least one negative operational mode depending on the property of the longitudinal optical sensor 114, the amplitude of the longitudinal sensor signal may decrease with decreasing cross-section of a light spot generated by the light beam 132 in the sensor region 130. The at least one longitudinal sensor signal, given the same total power of the illumination by the light beam 132, is dependent on a beam cross-section of the light beam 132 in the sensor region 130 of the at least one longitudinal optical sensor. In the negative operational mode, the longitudinal sensor signal, given the same total power, may exhibit at least one pronounced minimum for one or a plurality of focuses and/or for one or a plurality of specific sizes of the light spot on the sensor region 130 or within the sensor region 130.

In at least one neutral operational mode depending on the property of the longitudinal sensor 114, the amplitude of the longitudinal sensor signal may be essentially independent from a variation of the cross-section of a light spot generated by the light beam 132 in the sensor region 130. In particular, the longitudinal sensor signal may be essentially focus independent. In particular, in the neutral mode no global extremum may be observed.

The detector 110 may be configured to enable switching and/or changing between at least two operational modes of the group consisting of: positive operational mode; the negative operational mode; and the neutral operational mode. Thus, for example, the longitudinal optical sensor 114 may be in the positive operational mode. The switching device 140 may be configured to exert the at least one influence, such that the operational mode of longitudinal optical sensor 114 changes, for example to the negative operational mode or the neutral operational mode. For example, the longitudinal optical sensor 114 may be in the negative operational mode. The switching device 140 may be configured to exert at least one internal influence such that the operational mode of longitudinal optical sensor 114 changes, for example, to the positive operational mode or the neutral operational mode. For example, the longitudinal optical sensor 114 may be in the neutral operational mode. The switching device 140 may be configured to exert at least one influence such that the operational mode of longitudinal optical sensor 114 changes, for example, to the positive operational mode or the negative operational mode.

The evaluation device 138 may be designed to determine the operational mode of the longitudinal optical sensor 114. The evaluation device 138 may be configured to classify the operational mode of the longitudinal optical sensor 114. In particular, the evaluation device 138 may be configured to observe and/or to identify a global extremum, e.g. a global minimum or a global maximum. In case no extremum is observed or identified, the evaluation device 138 may classify the operational mode as neutral operational mode. The evaluation device 138 may be configured to perform an analysis of the longitudinal sensor signal, in particular a curve analysis of the longitudinal sensor signal.

The evaluation device 138 may be configured to determine the amplitude of the longitudinal sensor signal. The evaluation device 138 may be designed to determine the longitudinal sensor signal, one or both of sequentially or simultaneously in at least two operational modes. Thus, the evaluation device 138 may be configured to evaluate at least two longitudinal sensor signals simultaneously. The evaluation device 138 may be designed to resolve ambiguities by considering at least two longitudinal sensor signals determined in at least two different operational modes. Thus, at least two longitudinal sensor signals may be evaluated, wherein a first longitudinal sensor signal may be evaluated in a first operational mode and a second longitudinal sensor signal may be evaluated in a second operational mode. The evaluation device 138 may be configured to resolve ambiguities by comparing the first longitudinal sensor signal and the second longitudinal sensor signal. The evaluation device 138 may be adapted to normalize the longitudinal sensor signals and to generate the information on the longitudinal position of the object 112 independent from an intensity of the light beam 132. For example, one of the first or second longitudinal sensor signals may be selected as reference signal. For example, the longitudinal sensor signal evaluated in the neutral operational mode may be selected as reference signal. For example, at least one of the longitudinal sensor signals evaluated in the positive operational mode or the negative operational mode may be selected as reference signal. By comparison of the selected reference signal and the other longitudinal signal, ambiguities may be eliminated. The longitudinal sensor signals may be compared in order to gain information on the total power and/or intensity of the light beam 132 and/or in order to normalize the longitudinal sensor signals and/or the at least one item of information on the longitudinal position of the object 112 for the total power and/or total intensity of the light beam 132. For example, the longitudinal sensor signal may be normalized by division by the selected reference longitudinal sensor signal, in particular the longitudinal sensor signal evaluated in the neutral operational mode, thereby generating a normalized longitudinal optical sensor signal which, then, may be transformed by using the above-mentioned known relationship, into the at least one item of longitudinal information on the object. Thus, the transformation may be independent from the total power and/or intensity of the light beam 132. For example, at least one longitudinal sensor signal evaluated in one of the positive operational mode or the negative operational mode may be divided by the longitudinal sensor signal evaluated in the other one of the positive operational mode or the negative operational mode. Thus, by division, ambiguities may be eliminated.

As explained above, the longitudinal sensor signal as provided by the longitudinal optical sensor 114 upon impingement by the light beam 132 may depend on the electrical conductivity of the photoconductive material 134 in the sensor region 130. In order to determine a variation of the electrical conductivity of the photoconductive material 134 it may, as schematically depicted in FIG. 1, therefore be advantageous to measure a current, which may also be denominated a “photocurrent”, through the longitudinal optical sensor 114. For this purpose, the detector may comprise at least one biasing device 143 configured to apply at least one bias voltage to the longitudinal optical sensor 114. The biasing device 143 may comprise a bias voltage source 144. The bias voltage source 144 may be configured to provide a bias voltage above ground 146. The switching device 140 may be adapted to exert an influence on the bias voltage source 144 in order to set the bias voltage. The property of the longitudinal optical sensor 114 may be adjustable by using different bias voltages. The longitudinal optical sensor 114 may comprise at least one photodiode 147 driven in a photoconductive mode, wherein the photoconductive mode refers to an electrical circuit employing a photodiode, wherein the at least one photodiode is comprised in a reverse biased mode, wherein the cathode of the photodiode is driven with a positive voltage with respect to the anode. The property of the longitudinal optical sensor 114 may be electrically adjustable by applying different bias voltages to the photodiode 147. The biasing device 143 may be configured to apply at least two different bias voltages to the photodiode 147 such that it may be possible to switch between operational modes of the longitudinal optical sensor 114. For example, a zero bias may be used, such that the photodiode 147 may be unbiased and in a photovoltaic mode. Under this condition, the longitudinal optical sensor may be in the neutral operational mode. For example, a non-zero bias voltage may be applied to the photodiode 147, specifically a reverse bias, e.g. a positive voltage may be applied to the cathode. Under this condition, the longitudinal optical sensor 114 may be in a positive or a negative operational mode. Further, the longitudinal sensor signal as provided by the longitudinal optical sensor 114 may first be amplified by application of an amplifier 148 before supplying it to the longitudinal evaluation unit 142.

The light beam 132 for illumining the sensor region 130 of the longitudinal optical sensor 114 may be generated by a light-emitting object 112. Alternatively or in addition, the light beam 132 may be generated by a separate illumination source 150, which may include an ambient light source and/or an artificial light source, such as at least one laser source and/or at least one incandescent lamp and/or at least one semiconductor light source, for example, at least one light-emitting diode, in particular an organic and/or inorganic light-emitting diode, being adapted to illuminate the object 112 that the object 112 may be able to reflect at least a part of the light generated by the illumination source 150 in a manner that the light beam 132 may be configured to reach the sensor region 130 of the longitudinal optical sensor 114, preferably by entering the housing 118 of the optical detector 110 through the opening 124 along the optical axis 116.

In a specific embodiment, the illumination source 150 may be a modulated light source 152, wherein one or more modulation properties of the illumination source 150 may be controlled by at least one optional modulation device 154. Alternatively or in addition, the modulation may be effected in a beam path between the illumination source 150 and the object 112 and/or between the object 112 and the longitudinal optical sensor 114. Further possibilities may be conceivable. In this specific embodiment, it may be advantageous taking into account one or more of the modulation properties, in particular the modulation frequency, when evaluating the sensor signal of the longitudinal optical sensor 114 for determining the at least one item of information on the position of the object 112. For this purpose, the respective property as provided by the modulation device 154 may also be supplied to the amplifier 148, which, in this specific embodiment, may be a lock-in amplifier 156. The switching device 140 may be adapted to exert an influence on the modulation device 150 in order to set the modulation frequency of the emitted light beam. The illumination source 150 may be adapted to emit at least two light beams having different modulation frequencies. In case the illumination source 150 may emit two or more light beams, the switching device 140 may be adapted to exert an influence on the modulation device 154 in order to set the modulation frequencies of the emitted light beams.

The illumination source 150 may be adapted to emit light in at least two different wavelengths. The illumination source 150 may be configured to switch between emitting light in at least one first wavelength and emitting light in at least one second wavelength. The illumination source 150 may be designed to emit at least two light beams, wherein at least one property of a first light beam may be different from at least one property of a second light beam, wherein the property may be selected from the group consisting of wavelength, modulation frequency. In order to provide at least two light beams with different wavelengths, the illumination source 150 may comprise two light sources, in particular two artificial light sources, e.g. laser sources and/or light emitting diodes, emitting light in different wavelengths. The first light beam and the second light beam may be emitted simultaneously or sequentially. Alternatively, the illumination source 150 may comprise a single laser source adapted to generate light beams having different wavelengths. The switching device 140 may be adapted to exert an influence on the illumination source 150 in order to set the wavelength of the emitted light beam and/or the wavelengths of the emitted at least two light beams. The property of the longitudinal optical sensor 114 may be adjustable by at least one property of the light beam 132. Herein, at least one property of the light beam 132, being a wavelength and/or a modulation frequency.

Generally, the evaluation device 138 may be part of a data processing device 158 and/or may comprise one or more data processing devices 158. The evaluation device 138 may be fully or partially integrated into the housing 118 and/or may fully or partially be embodied as a separate device which is electrically connected in a wireless or wire-bound fashion to the longitudinal optical sensor 114. The evaluation device 138 may further comprise one or more additional components, such as one or more electronic hardware components and/or one or more software components, such as one or more measurement units and/or one or more evaluation units and/or one or more controlling units (not depicted in FIG. 1).

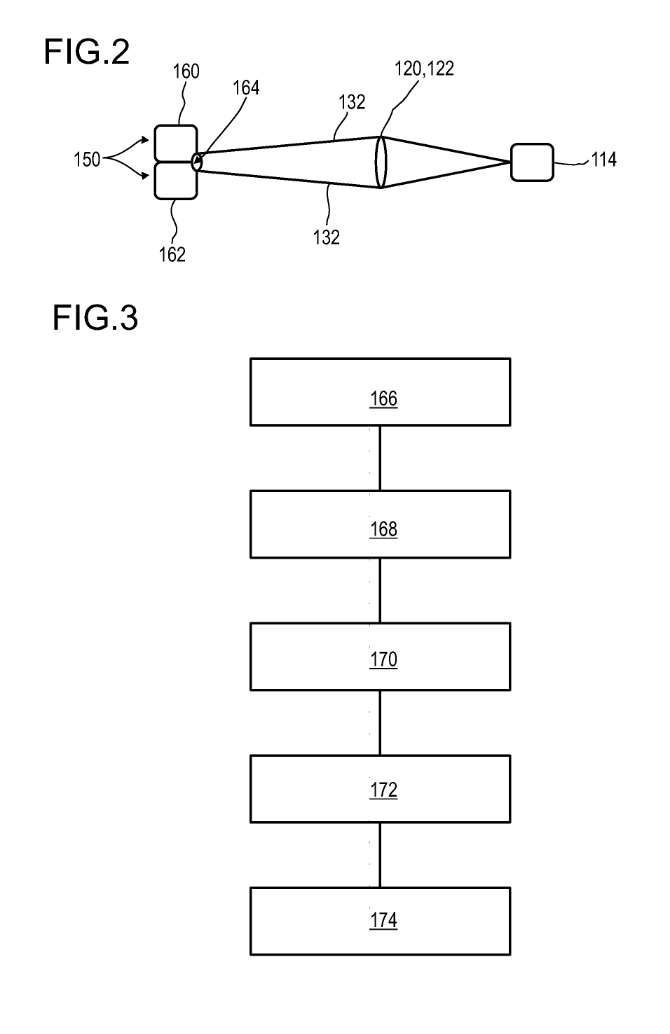

FIG. 2 shows, in a highly schematic illustration, an exemplary schematic setup of the detector 110 as shown in FIG. 1. A light beam 132 emitted by the illumination source 150 may be focussed by the transfer device 120 and may impinge on the longitudinal optical sensor 114. As outlined above, the illumination source 150 may be adapted to emit light in at least two different wavelengths. In FIG. 2, for a simplified representation, exemplary light beam 132 is depicted. For example, in order to provide at least two light beams with different wavelengths, the illumination source 150 may comprise two light sources, in particular two artificial light sources, e.g. laser sources and/or light emitting diodes, emitting light in different wavelengths. The illumination source 150 may comprise at least a first light source 160 and at least a second light source 162. The illumination source 150 may comprise at least one aperture 164 through which light may exit the illumination source 150. The first light beam and the second light beam may be emitted simultaneously or sequentially. Alternatively, the illumination source 150 may comprise a single laser source adapted to generate light beams having different wavelengths. The switching device 140 may be adapted to exert an influence on the illumination source 150 in order to set the wavelength of the emitted light beam and/or the wavelengths of the emitted at least two light beams. The first light source 160 providing the first light beam may stay switched on, while the second light source 162 may provide the second light beam. The first light beam may have a first wavelength and the second light beam may have a second wavelength, wherein the property of the longitudinal optical sensor 114 may be adjusted, in particular changes, by illumination with the first light beam and the second light beam. Illumination by the first light beam may result in adjusting the property of the longitudinal optical sensor 114 such that the longitudinal optical sensor 114 is in one of the neutral operational mode, the positive operational mode, or the negative operational mode. Illumination by the second light beam may result in adjusting the property of the longitudinal optical sensor 114 such that the longitudinal optical sensor may be in another operational mode which is different from the operational mode during illumination by the first light beam. By switching between at least two wavelengths, the property of the longitudinal optical sensor may be adjusted such that the longitudinal optical sensor 114 is operable in at least two operational modes. As outlined above, the evaluation device 138 may be designed to resolve ambiguities by considering at least two longitudinal sensor signals determined in at least two different operational modes.

FIG. 3 shows an exemplary schematic setup of a method for an optical detection of at least one object 112 according to the present invention. In the method, the detector 110 may be used. Still, other types of detectors may be used. In the exemplary embodiment shown in FIG. 2, the method steps may be as follows. Firstly, the at least one property of the longitudinal optical sensor 114 may be adjusted, denoted as reference number 166. For example, the property may be adjusted electrically by setting a bias voltage and/or the property may be adjusted by setting a property of at least one light beam. The property of the longitudinal optical sensor 114 may be adjusted by a user and/or by an external influence. Then, in a next step denoted as reference number 168, at least a first longitudinal sensor signal may be generated by using at least one longitudinal optical sensor 114, wherein the longitudinal sensor signal is dependent on an illumination of a sensor region 130 of the longitudinal optical sensor 114 by a light beam 132, wherein the longitudinal sensor signal, given the same total power of the illumination, is dependent on a beam cross-section of the light beam 132 in the sensor region 130, wherein the longitudinal sensor signal is further dependent on at least one property of the longitudinal optical sensor 114. Subsequently or simultaneously, the property of the longitudinal optical sensor 114 may be adjusted anew, denoted as reference number 170, for example, electrically by setting the bias voltage to a different value and/or by setting the property of the single light beam to a different value and/or, if using two light beams, by setting the property of a second light beam to a different value compared to the property of the first light beam. In a next step denoted as reference number 172, which may be performed subsequently or simultaneously to step 168, at least a second longitudinal sensor signal may be generated by using at least one longitudinal optical sensor 114. The first longitudinal sensor signal may be generated in a first operational mode of the longitudinal optical sensor, such as an operational mode selected from the group consisting of: the neutral operational mode, the positive operational mode and the negative operational mode. The second longitudinal sensor signal may be generated in another operation mode of the longitudinal optical sensor as the first longitudinal sensor signal. Ambiguities may be resolved by considering at least two longitudinal sensor signals determined in at least two different operational modes.

Both longitudinal sensor signals may be evaluated by using evaluation device 138 and at least one item of information on a longitudinal position of the object 112 may be generated, denoted as reference number 174. The longitudinal optical sensor signal may be evaluated unambiguously. The at least two longitudinal sensor signals may be evaluated simultaneously. Ambiguities may be resolved by comparing the first longitudinal sensor signal and the second longitudinal sensor signal. The method may furthermore comprise a comparison step, wherein the first longitudinal sensor signal and the second longitudinal sensor signal are compared. For example, in the comparison step, the longitudinal sensor signals may be normalized to generate the information on the longitudinal position of the object 112 independent from an intensity of the light beam 132. For example, one of the first or second longitudinal sensor signals may be selected as reference signal. For example, the longitudinal sensor signal evaluated in the neutral operational mode may be selected as reference signal. For example, at least one of the longitudinal sensor signals evaluated in the positive operational mode or the negative operational mode may be selected as reference signal. By comparison of the selected reference signal and the other longitudinal signal, ambiguities may be eliminated. The longitudinal sensor signals may be compared, in order to gain information on the total power and/or intensity of the light beam and/or in order to normalize the longitudinal sensor signals and/or the at least one item of information on the longitudinal position of the object for the total power and/or total intensity of the light beam. For example, the longitudinal sensor signal may be normalized by division by the selected reference longitudinal sensor signal, in particular the longitudinal sensor signal evaluated in the neutral operational mode, thereby generating a normalized longitudinal optical sensor signal which, then, may be transformed by using the above-mentioned known relationship, into the at least one item of longitudinal information on the object. Thus, the transformation may be independent from the total power and/or intensity of the light beam 132. For example, at least one longitudinal sensor signal evaluated in one of the positive operational mode or the negative operational mode may be divided by the longitudinal sensor signal evaluated in the other one of the positive operational mode or the negative operational mode. Thus, by division ambiguities may be eliminated.

The method may further comprise determining and/or classifying the operational mode of the longitudinal optical sensor 114. Thus, the method may comprise an analysis step, in which the longitudinal signal may be analyzed. In particular, curve characteristics and progression may be determined, more specifically a global extremum, e.g. a global minimum or a global maximum, may be determined. In case no extremum is observed or identified, the operational mode may be classified as neutral operational mode. For example, the amplitude of the longitudinal sensor signal may be determined.

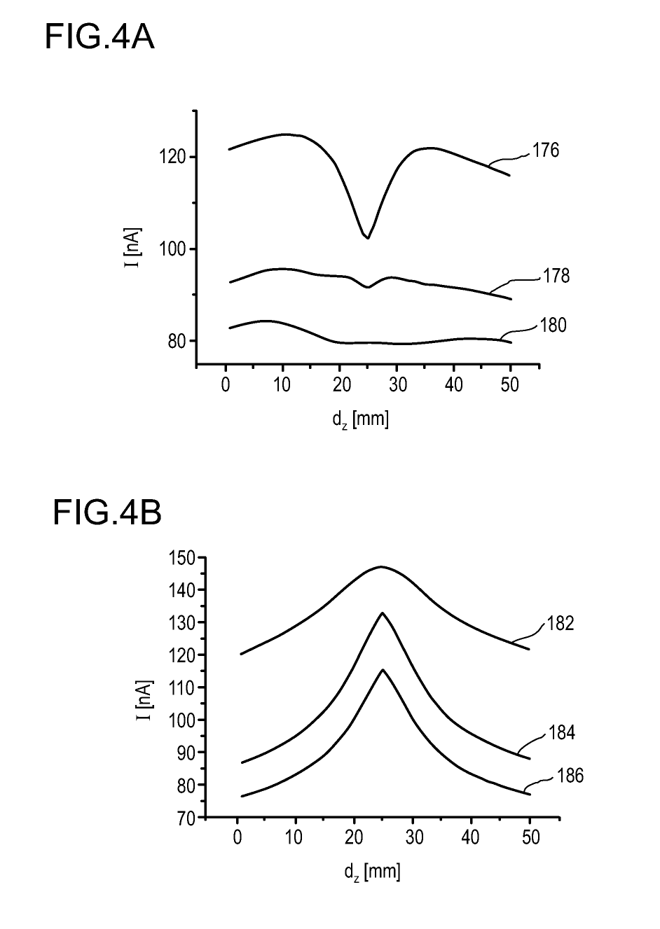

FIGS. 4A and 4B show experimental results demonstrating the dependency of a longitudinal sensor signal on wavelength. The longitudinal optical sensor 114 was placed in front of the transfer device 120 with a distance of 50 mm. In both figures the dependency of the longitudinal sensor signal I in nA on a distance d_{z} in mm is depicted.

In FIG. 4A, the illumination source may be driven at a current of 367 mA and may emit a light beam having a wavelength of 405 nm. In this particular experiment, the illumination source 150 was modulated with different modulation frequencies by using the modulation device 154. For measurement curves 176, 178 and 180, the frequency of the light beam amounted to 27 Hz, 375 Hz and 2177 Hz, respectively. As a result, measurement curve 176 exhibits the negative FiP effect, whereas measurement curve 180 shows an essential flat curve shape and, thus, is essentially focus independent. Thus, wavelength 405 nm combined with high frequencies, in particular curve 180, may be selected as reference.

In FIG. 4B, the illumination source may be driven at a current of 367 mA and may emit a light beam having a wavelength of 530 nm. In this particular experiment, the illumination source 150 was modulated with different modulation frequencies by using the modulation device 154. For measurement curves 182, 184 and 186, the frequency of the light beam may amount to 27 Hz, 375 Hz and 2177 Hz, respectively. As a result, measurement curves 182, 184 and 186 exhibit the positive FiP effect.

Thus, the first wavelength may be a short wavelength compared to the second wavelength. In particular the first wavelength may be in the visible spectral range, preferably in the range of 380 to 450 nm, more preferably in the range of 390 to 420 nm, most preferably in the range of 400 to 410 nm. For example, the second wavelength may be in the visible spectral range as well, preferably in the range of 500 to 560 nm, more preferably in the range of 510 to 550 nm, most preferably in the range of 520 to 540 nm.

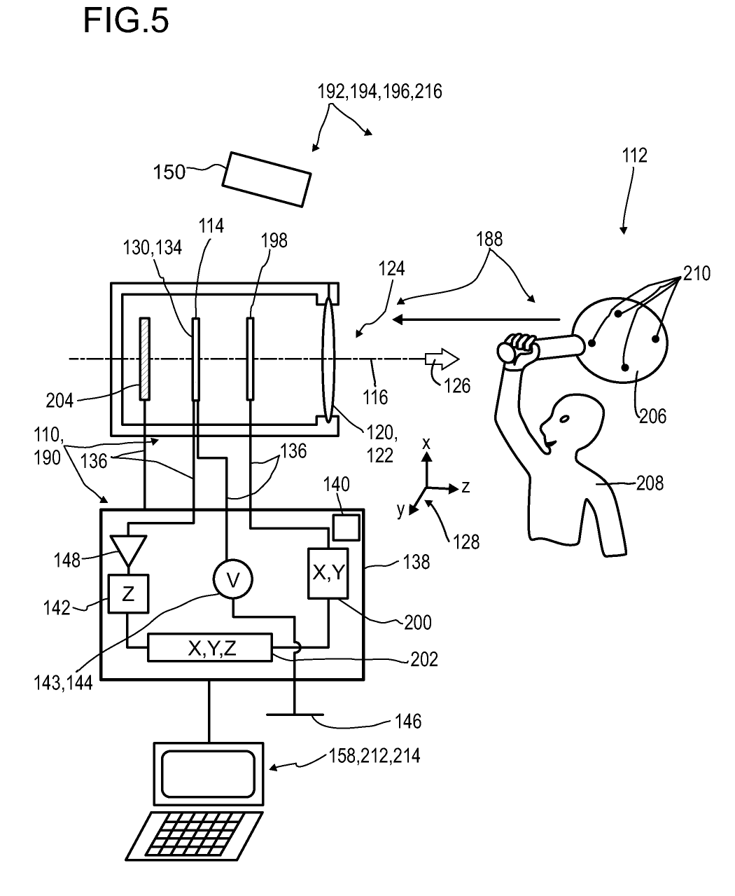

As an example, FIG. 5 shows an exemplary embodiment of a detector system 188, comprising at least one optical detector 110, such as the optical detector 110 as disclosed in one or more of the embodiments shown in FIGS. 1 to 2. Herein, the optical detector 110 may be employed as a camera 190, specifically for 3D imaging, which may be made for acquiring images and/or image sequences, such as digital video clips. Further, FIG. 5 shows an exemplary embodiment of a human-machine interface 192, which comprises the at least one detector 110 and/or the at least one detector system 188, and, further, an exemplary embodiment of an entertainment device 194 comprising the human-machine interface 192. FIG. 5 further shows an embodiment of a tracking system 196 adapted for tracking a position of at least one object 112, which comprises the detector 110 and/or the detector system 188.

With regard to the optical detector 110 and to the detector system 188, reference may be made to the full disclosure of this application. Basically, all potential embodiments of the detector 110 may also be embodied in the embodiment shown in FIG. 5. The evaluation device 138 may be connected to at least one longitudinal optical sensor 114, in particular, by the signal leads 136. For example, a use of two or, preferably, three longitudinal optical sensors 114 may be possible. The evaluation device 138 may further be connected to at least one optional transversal optical sensor 198, in particular, by the signal leads 136. By way of example, the signal leads 136 may be provided and/or one or more interfaces, which may be wireless interfaces and/or wire-bound interfaces. Further, the signal leads 136 may comprise one or more drivers and/or one or more measurement devices for generating sensor signals and/or for modifying sensor signals. Further, again, the at least one transfer device 120 may be provided, in particular as the refractive lens 122 or convex mirror. The optical detector 110 may further comprise the at least one housing 118 which, as an example, may encase one or more of components 114, 198.

Further, the evaluation device 138 may fully or partially be integrated into the optical sensors 114, 198 and/or into other components of the optical detector 110. The evaluation device 138 may also be enclosed into housing 118 and/or into a separate housing. The evaluation device 138 may comprise one or more electronic devices and/or one or more software components, in order to evaluate the sensor signals, which are symbolically denoted by the longitudinal evaluation unit 142 (denoted by “z”) and a transversal evaluation unit 200 (denoted by “xy”). By combining results derived by these evolution units 142, 200, a position information 202, preferably a three-dimensional position information, may be generated (denoted by “x, y, z”). Similar to the embodiment according to FIG. 1, a bias voltage source 144 may be provided, configured to provide a bias voltage above ground 146. Further, the longitudinal sensor signals as provided by the longitudinal optical sensors 114 may first be amplified by means of an amplifier 148 before supplying it to the longitudinal evaluation unit 142.

Further, the optical detector 110 and/or to the detector system 188 may comprise an imaging device 204 which may be configured in various ways. Thus, as depicted in FIG. 5, the imaging device 204 can, for example, be part of the detector 110 within the detector housing 118. Herein, the imaging device signal may be transmitted by one or more imaging device signal leads 136 to the evaluation device 138. Alternatively, the imaging device 204 may be separately located outside the detector housing 118. The imaging device 204 may be fully or partially transparent or intransparent. The imaging device 204 may be or may comprise an organic imaging device or an inorganic imaging device. Preferably, the imaging device 204 may comprise at least one matrix of pixels, wherein the matrix of pixels may particularly be selected from the group consisting of: an inorganic semiconductor sensor device such as a CCD chip and/or a CMOS chip; an organic semiconductor sensor device.

In the exemplary embodiment as shown in FIG. 5, the object 112 to be detected, as an example, may be designed as an article of sports equipment and/or may form a control element 206, the position and/or orientation of which may be manipulated by a user 208. Thus, generally, in the embodiment shown in FIG. 5 or in any other embodiment of the detector system 188, the human-machine interface 192, the entertainment device 194 or the tracking system 196, the object 112 itself may be part of the named devices and, specifically, may comprise the at least one control element 206, specifically, wherein the at least one control element 206 has one or more beacon devices 210, wherein a position and/or orientation of the control element 206 preferably may be manipulated by user 208. As an example, the object 112 may be or may comprise one or more of a bat, a racket, a club or any other article of sports equipment and/or fake sports equipment. Other types of objects 112 are possible. Further, the user 208 may be considered as the object 112, the position of which shall be detected. As an example, the user 208 may carry one or more of the beacon devices 210 attached directly or indirectly to his or her body.

The optical detector 110 may be adapted to determine at least one item on a longitudinal position of one or more of the beacon devices 210 and, optionally, at least one item of information regarding a transversal position thereof, and/or at least one other item of information regarding the longitudinal position of the object 112 and, optionally, at least one item of information regarding a transversal position of the object 112. Particularly, the optical detector 110 may be adapted for identifying colors and/or for imaging the object 112, such as different colors of the object 112, more particularly, the color of the beacon devices 210 which might comprise different colors. The opening 124 in the housing 118, which, preferably, may be located concentrically with regard to the optical axis 116 of the detector 110, may preferably define a direction of a view 126 of the optical detector 110.

The optical detector 110 may be adapted for determining the position of the at least one object 112. Additionally, the optical detector 110, specifically an embodiment including the camera 190, may be adapted for acquiring at least one image of the object 112, preferably a 3D-image. As outlined above, the determination of a position of the object 112 and/or a part thereof by using the optical detector 110 and/or the detector system 188 may be used for providing a human-machine interface 192, in order to provide at least one item of information to a machine 212. In the embodiments schematically depicted in FIG. 5, the machine 212 may be or may comprise at least one computer and/or a computer system comprising the data processing device 158. Other embodiments are feasible. The evaluation device 138 may be a computer and/or may comprise a computer and/or may fully or partially be embodied as a separate device and/or may fully or partially be integrated into the machine 212, particularly the computer. The same holds true for a track controller 214 of the tracking system 196, which may fully or partially form a part of the evaluation device 138 and/or the machine 212.

Similarly, as outlined above, the human-machine interface 192 may form part of the entertainment device 194. Thus, by means of the user 208 functioning as the object 112 and/or by means of the user 208 handling the object 112 and/or the control element 206 functioning as the object 112, the user 208 may input at least one item of information, such as at least one control command, into the machine 212, particularly the computer, thereby varying the entertainment function, such as controlling the course of a computer game.

FIG. 5 further shows an exemplary embodiment of a scanning system 216 for determining at least one position of the at least one object 112. The scanning system 216 comprises the at least one detector 110 and, further, at least one illumination source 150 adapted to emit at least one light beam 132 configured for an illumination of at least one dot (e.g. a dot located on one or more of the positions of the beacon devices 210) located on at least one surface of the at least one object 112. The scanning system 216 is designed to generate at least one item of information about the distance between the at least one dot and the scanning system 216, specifically the detector 110, by using the at least one detector 110.

### LIST OF REFERENCE NUMBERS

110 detector
112 Object
114 Longitudinal optical sensor
116 Optical axis
118 Housing
120 Transfer device
122 Refractive lens
124 Opening
126 Direction of view
128 Coordinate system
130 Sensor region
132 Light beam
134 Photoconductive material
136 Signal leads
138 Evaluation device
140 Switching device
142 Longitudinal evaluation unit
143 Biasing device
144 Bias voltage source
146 Ground
147 Photodiode
148 Amplifier
150 Illumination source
152 Modulated illumination source
154 Modulation device
156 Lock-in amplifier
158 Data processing device
160 First light source
162 Second light source
164 Aperture
166 Adjusting
168 Next step
170 Adjusting
172 Next step
174 Evaluating
176 Measurement curve
178 Measurement curve
180 Measurement curve
182 Measurement curve
184 Measurement curve
186 Measurement curve
188 Detector system
190 Camera
192 Human-machine interface
194 Entertaining device
196 Tracking system
198 Transversal optical detector
200 Transversal evaluation unit
202 Position information
204 Imaging device
206 Control element
208 user
210 Beacon device
212 machine
214 Track controller
216 Scanning system

1. A detector for an optical detection of at least one object, the detector comprising:
at least one longitudinal optical sensor, wherein the longitudinal optical sensor has at least one sensor region, wherein the longitudinal optical sensor is designed to generate at least one longitudinal sensor signal in a manner dependent on an illumination of the sensor region by a light beam, wherein the longitudinal sensor signal, given the same total power of the illumination, is dependent on a beam cross-section of the light beam in the sensor region, wherein the longitudinal sensor signal is further dependent on at least one property of the longitudinal optical sensor and wherein the property of the longitudinal optical sensor is adjustable; and
at least one evaluation device, wherein the evaluation device is designed to generate at least one item of information on a longitudinal position of the object by evaluating the longitudinal sensor signal of the longitudinal optical sensor.

2-4. (canceled)

5. The detector according to claim 1, further comprising:
a switching device configured to switch between at least two operational modes of the longitudinal optical sensor.

6. The detector according to claim 5, wherein in at least one positive operational mode depending on the property of the longitudinal optical sensor an amplitude of the longitudinal sensor signal increases with decreasing cross-section of a light spot generated by the light beam in the sensor region.

7. The detector according to claim 5, wherein in at least one negative operational mode depending on the property of the longitudinal optical sensor an amplitude of the longitudinal sensor signal decreases with decreasing cross-section of a light spot generated by the light beam in the sensor region.

8. The detector according to claim 5, wherein in at least one neutral operational mode depending on the property of the longitudinal sensor signal the amplitude of the longitudinal sensor signal is essentially independent from a variation of cross-section of a light spot generated by the light beam in the sensor region.

9-10. (canceled)

11. The detector according to claim 5, wherein evaluation device is designed to determine the longitudinal sensor signal one or both of sequentially or simultaneously in the at least two operational modes.

12. The detector according to claim 11, wherein the evaluation device is designed to resolve ambiguities by considering at least two longitudinal sensor signals determined in at least two different operational modes.

13. The detector according to claim 1, wherein the property of the longitudinal optical sensor is electrically and/or optically adjustable.

14-15. (canceled)

16. The detector according to claim 1, wherein the property of the longitudinal optical sensor is adjustable by using different bias voltages.

17. The detector according to claim 16, further comprising:
at least one photodiode driven in a photoconductive mode, wherein the photoconductive mode refers to an electrical circuit employing the at least one photodiode, wherein the at least one photodiode is comprised in a reverse biased mode, and wherein a cathode of the at least one photodiode is driven with a positive voltage with respect to the anode.

18. (canceled)

19. The detector according to claim 1, wherein the property of the longitudinal optical sensor is adjustable by wavelength and/or modulation frequency of the light beam.

20-22. (canceled)

23. The detector according to claim 1, further comprising:
at least one illumination source designed to emit at least two light beams, wherein at least one property of a first light beam is different from at least one property of a second light beam, and wherein the property is selected from the group consisting of at least one wave-length, at least one modulation frequency, and at least one size of at least one light source.

24-26. (canceled)

27. The detector according to claim 1, wherein the light beam is a modulated light beam.

28-29. (canceled)

30. The detector according to claim 1, wherein the evaluation device is adapted to normalize the longitudinal sensor signals and to generate the information on the longitudinal position of the object independent from an intensity of the light beam.

31. The detector according to claim 1, wherein the evaluation device is adapted to generate the at least one item of information on the longitudinal position of the object by determining a diameter of the light beam from the at least one longitudinal sensor signal.

32. The detector according to claim 1, wherein the sensor region comprises at least one material capable of sustaining an electrical current, wherein at least one property of the material, given the same total power of the illumination, is dependent on the beam cross-section of the light beam in the sensor region, and wherein the longitudinal sensor signal is dependent on the at least one property.

33. (canceled)

34. The detector 4 according to claim 32, wherein the material capable of sustaining an electrical current comprises one or more of amorphous silicon, an alloy comprising amorphous silicon, microcrystalline silicon or cadmium telluride.

35. The detector according to claim 34, wherein the material comprises the alloy comprising amorphous silicon, which is an amorphous alloy comprising silicon and carbon or an amorphous alloy comprising silicon and germanium.

36-37. (canceled)

38. The detector according to claim 1, further comprising:
at least one transversal optical sensor the transversal optical sensor being adapted to determine a transversal position of the light beam traveling from the object to the detector, the transversal position being a position in at least one dimension perpendicular to an optical axis of the detector, the transversal optical sensor being adapted to generate at least one transversal sensor signal, wherein the evaluation device is further designed to generate at least one item of information on a transversal position of the object by evaluating the transversal sensor signal.

39. (canceled)

40. The detector according to claim 1, further comprising:
at least one imaging device.

41. A detector system for determining a position of at least one object the detector system, comprising
at least one detector according to claim 1, and
at least one beacon device adapted to direct at least one light beam towards the detector, wherein the beacon device is at least one of attachable to the object, holdable by the object and integratable into the object.

42. The detector system according to claim 41, comprising:
at least two beacon devices,
wherein at least one property of a light beam emitted by a first beacon device is different from at least one property of a light beam emitted by a second beacon device.

43-56. (canceled)
